(19) United States
(12) Patent Application Publication
(10) Pub. No.: US 2010/0323303 A1
(43) Pub. Date: Dec. 23, 2010

(54) LIQUID IMMERSION MEMBER, EXPOSURE APPARATUS, EXPOSING METHOD, AND DEVICE FABRICATING METHOD

(75) Inventor: Hiroyuki NAGASAKA, Kumagaya-shi (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/779,590

(22) Filed: May 13, 2010

Related U.S. Application Data
(60) Provisional application No. 61/213,196, filed on May 15, 2009.
(60) Provisional application No. 61/272,638, filed on Oct. 14, 2009.

(51) Int. Cl. G03F 7/20; G03B 27/52

(52) U.S. Cl. 430/325; 355/30

(57) ABSTRACT

An exposure apparatus including: an optical system, which has an emergent surface; a first surface, which is disposed at least partly around an optical path of exposure light from the emergent surface; a second surface, which is disposed at least partly around the first surface; a third surface, which is disposed at least partly around the second surface; a first supply port, which is disposed at least partly around the first surface such that the first supply port is directed in an outward radial direction with respect to an optical axis of the optical system, that supplies a first liquid to the second surface; and a second supply port, which is disposed at least partly around the second surface such that the second supply port is directed in an outward radial direction with respect to the optical axis, that supplies a second liquid to the third surface.

### CROSS-REFERENCE TO RELATED APPLICATION

This application is a non-provisional application claiming priority to and the benefit of U.S. Provisional Application No. 61/213,196, filed May 15, 2009, U.S. Provisional Application No. 61/272,638, filed Oct. 14, 2009. The entire contents of which are incorporated herein by reference.

### BACKGROUND

The present invention relates to a liquid immersion member, an exposure apparatus, an exposing method, and a device fabricating method.

In exposure apparatuses used in photolithographic processes, an immersion exposure apparatus that uses a liquid immersion member to form an immersion space such that an optical path of exposure light radiated to a substrate is filled with a liquid and that exposes the substrate with the exposure light emerging from a projection optical system and transiting the liquid of the immersion space, as disclosed in, for example, U.S. Patent Application Publication No. 2005/259234, is known.

### SUMMARY

In an immersion exposure apparatus, if an object is moved at a high speed in a state wherein the immersion space is formed between the liquid immersion member and an object (i.e., the substrate), then the liquid might leak, a film, a drop, or the like of the liquid might remain on the object, or the like. As a result, exposure failures might occur or defective devices be produced. Moreover, if, to satisfactorily hold the liquid, the movement velocity of the object is lowered, then throughput might decline.

It is an object of the present invention to provide a liquid immersion member, an exposure apparatus, and an exposing method that can prevent liquid from remaining on an object. It is another object of the present invention to provide a device fabricating method that can prevent defective devices from being produced while preventing a decline in throughput.

A first aspect of the invention provides an exposure apparatus that comprises: an optical system, which has an emergent surface wherefrom exposure light emerges; a first surface, which is disposed at least partly around an optical path of the exposure light from the emergent surface; a second surface, which is disposed at least partly around the first surface; a third surface, which is disposed at least partly around the second surface; a first supply port, which is disposed at least partly around the first surface such that the first supply port is directed in an outward radial direction with respect to an optical axis of the optical system, that supplies a first liquid to the second surface; and a second supply port, which is disposed at least partly around the second surface such that the second supply port is directed in an outward radial direction with respect to the optical axis, that supplies a second liquid to the third surface; and wherein, during at least part of an exposure of a substrate, a front surface of the substrate opposes the emergent surface, the first surface, the second surface, and the third surface; and the substrate is exposed with the exposure light that emerges from the emergent surface and transits a third liquid between the emergent surface and the front surface of the substrate.

A second aspect of the invention provides a device fabricating method that comprises the steps of: exposing a substrate using an exposure apparatus according to the first aspect of the invention; and developing the exposed substrate.

A third aspect of the invention provides an exposing method that comprises the steps of causing a substrate to oppose a first surface, which is disposed at least partly around an optical path of exposure light from an emergent surface of an optical system, a second surface, which is disposed at least partly around the first surface, and a third surface, which is disposed at least partly around the second surface; supplying, at least partly around the first surface, a first liquid via a first supply port, which is disposed such that it is directed in an outward radial direction with respect to the optical axis of the optical system, to the second surface; supplying, at least partly around the second surface, a second liquid via a second supply port, which is disposed such that it is directed in an outward radial direction with respect to the optical axis, to the third surface; forming an immersion space with a third liquid between at least part of the emergent surface, the first surface, the second surface, and the third surface and a front surface of the substrate such that the third liquid is supplied via third supply ports, which are different than the first supply port and the second supply port, and the optical path of the exposure light between the emergent surface and the substrate is filled with the third liquid; and exposing the substrate with the exposure light that emerges from the emergent surface and transits the third liquid between the emergent surface and the substrate.

A fourth aspect of the invention provides a device fabricating method that comprises the steps of exposing a substrate using an exposing method according to the third aspect of the invention; and developing the exposed substrate.

A first aspect of the invention provides a liquid immersion member that comprises: a first surface, which is disposed at least partly around an optical path of exposure light radiated to an object and is capable of opposing the object; a second surface, which is disposed at least partly around the first surface; a prescribed member that has a third surface and a fourth surface, which faces a direction opposite that faced by the third surface, and that is disposed such that the third surface opposes the second surface; a first supply port, which is disposed at least partly around the first surface such that it is directed in an outward radial direction with respect to the optical path, that supplies a first liquid; and a passageway that is provided such that it connects a first space, which is faced by the third surface, and a second space, which is faced by the fourth surface, and such that at least some of the first liquid supplied via the first supply port to the first space flows to the second space; wherein, during at least part of the radiation of the exposure light to the object, an immersion space is formed by holding a second liquid between the liquid immersion member and the object such that the optical path is filled with the second liquid.

A sixth aspect of the invention provides a liquid immersion member that comprises: a first surface, which is disposed at least partly around an optical path of exposure light radiated to an object and is capable of opposing the object; a second surface, which is disposed at least partly around the first surface; a prescribed member, which is disposed in the first surface and has an outer surface at least part of which faces a different direction from that faced by the first surface and follows along radial a direction with respect to the optical path; and a first supply port, which is disposed in the prescribed member such that the first supply port is directed in an outward radial direction, that supplies a first liquid to the second surface; wherein, during at least part of the radiation of the exposure light to the object, an immersion space is formed by holding a second liquid between the liquid immersion member and the object such that the optical path is filled with the second liquid.

A seventh aspect of the invention provides an exposure apparatus that comprises: an optical system, which has an emergent surface wherefrom exposure light emerges; and a liquid immersion member according to the fifth or sixth aspects that, during at least part of an exposure of a substrate, forms an immersion space by holding a second liquid between the liquid immersion member and the substrate such that an optical path of the exposure light between the emergent surface and the substrate is filled with the second liquid.

An eighth aspect of the invention provides a device fabricating method that comprises the steps of: exposing a substrate using an exposure apparatus according to the seventh aspect; and developing the exposed substrate.

A ninth aspect of the invention provides an exposing method that comprises the steps of: supplying a first liquid via a first supply port, which is disposed at least partly around a first surface (disposed at least partly around an optical path of exposure light from an emergent surface of an optical system) such that the first supply port is directed in an outward radial direction with respect to an optical axis of the optical system, to a first space, which is faced by a third surface of a prescribed member opposing a second surface that is disposed at least partly around the first surface; flowing at least some of the first liquid, which is supplied via the first supply port to the first space, to a second space via a passageway, which connects the first space and the second space, which is faced by a fourth surface of the prescribed member that faces a direction opposite that faced by the third surface; causing the first surface, the second surface, and the fourth surface on one side and the substrate on the other side to oppose one another; and exposing the substrate with the exposure light that emerges from the emergent surface and transits a second liquid between the emergent surface and a front surface of the substrate.

A tenth aspect of the invention provides an exposing method that comprises the steps of: causing a first surface, which is disposed at least partly around an optical path of exposure light from an emergent surface of an optical system, and a second surface, which is disposed at least partly around the first surface, to oppose one another; supplying a first liquid, which is supplied to the second surface via a first supply port disposed such that the first supply port is directed in an outward radial direction, to a prescribed member, which has an outer surface disposed such that at least part of the outer surface faces a direction different from that faced by the first surface and such that the outer surface follows along a radial direction with respect to an optical axis of the optical system; and exposing the substrate with the exposure light that emerges from the emergent surface and transits a second liquid between the emergent surface and the substrate.

An eleventh aspect of the invention provides a device fabricating method that comprises the steps of: exposing a substrate using an exposing method according to the ninth or tenth aspects; and developing the exposed substrate.

According to some aspects of the present invention, it is possible to prevent exposure failures from occurring while preventing throughput from declining. In addition, according to the present invention, it is possible to prevent defective devices from being produced while preventing throughput from declining.

### BRIEF DESCRIPTION OF THE DRAWINGS

FIG. 1 is a schematic block diagram that shows one example of an exposure apparatus according to a first embodiment.

FIG. 2 is a partial enlarged view of the exposure apparatus according to the first embodiment.

FIG. 3 shows a liquid immersion member according to the first embodiment, viewed from above.

FIG. 4 shows the liquid immersion member according to the first embodiment, viewed from below.

FIG. 5 shows the vicinity of the liquid immersion member according to the first embodiment.

FIG. 6 is a schematic drawing that shows the liquid immersion member according to a comparative example.

FIG. 7 is a schematic drawing that shows the liquid immersion member according to the first embodiment.

FIG. 8 shows the vicinity of the liquid immersion member according to a second embodiment.

FIG. 9 shows the vicinity of the liquid immersion member according to a second embodiment.

FIG. 10 shows the vicinity of a liquid immersion member according to a third embodiment.

FIG. 11 shows the vicinity of the liquid immersion member according to the third embodiment.

FIG. 12 shows the vicinity of the liquid immersion member according to the third embodiment.

FIG. 13 shows the vicinity of the liquid immersion member according to the third embodiment.

FIG. 14 shows the vicinity of the liquid immersion member according to a fourth embodiment.

FIG. 15 is a side view that shows the liquid immersion member according to a fifth embodiment.

FIG. 16 shows the liquid immersion member according to the fifth embodiment, viewed from below.

FIG. 17 is a schematic block diagram that shows one example of an exposure apparatus according to a sixth embodiment.

FIG. 18 is a side cross sectional view that shows the vicinity of a liquid immersion member according to the sixth embodiment.

FIG. 19 shows a liquid immersion member according to the sixth embodiment, viewed from above.

FIG. 20 shows the liquid immersion member according to the sixth embodiment, viewed from below.

FIG. 21 is a side cross sectional view that shows part of the liquid immersion member according to the sixth embodiment.

FIG. 22 is a side cross sectional view that shows part of the liquid immersion member according to the sixth embodiment.

FIG. 23 shows part of the liquid immersion member according to the sixth embodiment, viewed from below.

FIG. 24 is a side view that shows part of the liquid immersion member according to the sixth embodiment.

FIG. 25 is a schematic drawing that shows one example of the state of a liquid of an immersion space.

FIG. 26 is a schematic drawing that shows one example of the state of the liquid of the immersion space.

FIG. 27 is a schematic drawing for explaining one example of the action of the liquid immersion member according to the sixth embodiment.

FIG. 28 is a schematic drawing for explaining one example of the action of the liquid immersion member according to the sixth embodiment.

FIG. 29 shows one example of a porous member disposed in a recovery port.

FIG. 30 is a side view that shows part of the liquid immersion member according to the sixth embodiment.

FIG. 31 shows the liquid immersion member according to the sixth embodiment, viewed from below.

FIG. 32 is a side cross sectional view that shows part of the liquid immersion member according to the sixth embodiment.

FIG. 33 is a side cross sectional view that shows part of the liquid immersion member according to the sixth embodiment.

FIG. 34 is a side cross sectional view that shows part of the liquid immersion member according to the sixth embodiment.

FIG. 35 shows the liquid immersion member according to the sixth embodiment, viewed from below.

FIG. 36 shows the liquid immersion member according to the sixth embodiment, viewed from below.

FIG. 37 is a side cross sectional view that shows part of the liquid immersion member according to a seventh embodiment.

FIG. 38 shows part of the liquid immersion member according to the seventh embodiment, viewed from below.

FIG. 39 is a side cross sectional view that shows part of the liquid immersion member according to the seventh embodiment.

FIG. 40 shows part of the liquid immersion member according to the seventh embodiment, viewed from below.

FIG. 41 is a side cross sectional view that shows part of the liquid immersion member according to the seventh embodiment.

FIG. 42 shows part of the liquid immersion member according to the seventh embodiment, viewed from below.

FIG. 43 is a flow chart for explaining one example of a microdevice fabricating process.

### DESCRIPTION OF EMBODIMENTS

The following text explains the embodiments of the present invention, referencing the drawings; however, the present invention is not limited thereto. The explanation below defines an XYZ orthogonal coordinate system, and the positional relationships among parts are explained referencing this system. Prescribed directions within the horizontal plane are the X axial directions, directions orthogonal to the X axial directions in the horizontal plane are the Y axial directions, and directions orthogonal to the X axial directions and the Y axial directions are the Z axial directions (i.e., the vertical directions). In addition, the rotational (i.e., inclinational) directions around the X, Y, and Z axes are the θX, θY, and θZ directions, respectively.

### First Embodiment

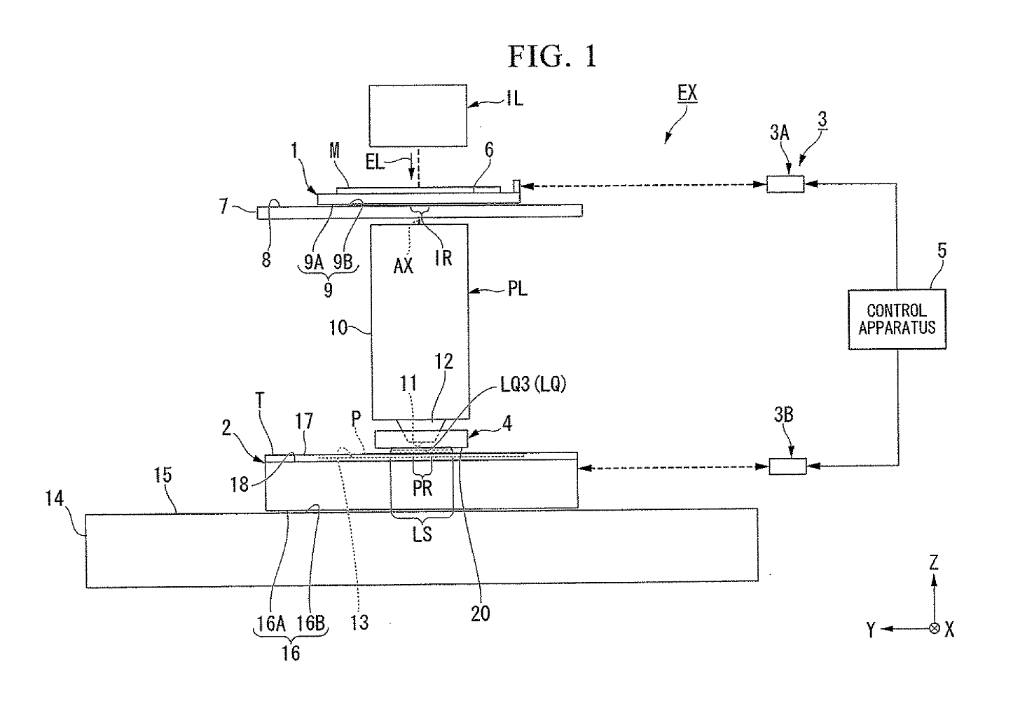

A first embodiment will now be explained. FIG. 1 is a schematic block diagram that shows one example of an exposure apparatus EX according to the first embodiment. The exposure apparatus EX of the present embodiment is an immersion exposure apparatus that exposes a substrate P with exposure light EL that transits a liquid. Furthermore, in the present embodiment as discussed below, a first liquid LQ1, a second liquid LQ2, and a third liquid LQ3 serve as the liquid and the exposure light EL is radiated to the substrate P through the third liquid LQ3.

In FIG. 1, the exposure apparatus EX comprises: a movable mask stage 1 that holds a mask M; a movable substrate stage 2 that holds the substrate P; an interferometer system 3 that optically measures the positions of the mask stage 1 and the substrate stage 2; an illumination system IL that illuminates the mask M with the exposure light EL; a projection optical system PL that projects an image of a pattern of the mask M, which is illuminated by the exposure light EL, to the substrate P; a liquid immersion member 4, which is capable of forming an immersion space LS such that at least part of the optical path of the exposure light EL is filled with the third liquid LQ3; and a control apparatus 5 that controls the operation of the entire exposure apparatus EX.

The mask M may be, for example, a reticle wherein a device pattern that is projected onto the substrate P is formed. The mask M comprises a transmissive mask that comprises a transparent plate, such as a glass plate, and the pattern, which is formed on the transparent plate using a shielding material, such as chrome. Furthermore, the mask M may alternatively be a reflective mask.

The substrate P is a substrate for fabricating devices. The substrate P comprises a base material (e.g., a semiconductor wafer) and a multilayer film that is formed thereon. The multilayer film is a film wherein a plurality of films, including at least a photosensitive film, is layered. The photosensitive film is a film that is formed from a photosensitive material. In addition, the multilayer film may include, for example, an antireflection film and a protective film (i.e., a topcoat film) that protects the photosensitive film.

The illumination system IL radiates the exposure light EL to a prescribed illumination area IR. The illumination area IR includes a position whereto the exposure light EL that emerges from the illumination system IL can be radiated. The illumination system IL illuminates at least part of the mask M disposed in the illumination area IR with the exposure light EL, which has a uniform luminous flux intensity distribution. Examples of light that can be used as the exposure light EL emitted from the illumination system IL include: deep ultraviolet (DUV) light, such as a bright line (g-line, h-line, or i-line) light emitted from, for example, a mercury lamp, and KrF excimer laser light (with a wavelength of 248 nm); and vacuum ultraviolet (VLM) light, such as ArF excimer laser light (with a wavelength of 193 nm) and F₂ laser light (with a wavelength of 157 nm). In the present embodiment, ArF excimer laser light, which is ultraviolet light (e.g., vacuum ultraviolet light), is used as the exposure light EL.

The mask stage 1 comprises a mask holding part 6, which releasably holds the mask M, and is capable of moving on a guide surface 8 of a first base plate 7 in the state wherein the mask stage 1 holds the mask M. The mask stage 1 is capable of holding and moving the mask M with respect to the illumination area IR by the operation of a drive system 9. The drive system 9 comprises a planar motor that comprises sliders 9A, which are disposed on the mask stage 1, and stators 9B, which are disposed on the first base plate 7. A planar motor that is capable of moving the mask stage 1 is disclosed in, for example, U.S. Pat. No. 6,452,292. The mask stage 1 is capable of moving in six directions, namely, the X axial, Y axial, Z axial, θX, θY, and θZ directions, by the operation of the drive system 9.

The projection optical system PL radiates the exposure light EL to a prescribed projection area PR. The projection optical system PL projects an image of the pattern of the mask M to at least part of the substrate P, which is disposed in the projection area PR, with a prescribed projection magnification. A holding member 10 (i.e., a lens barrel) holds a plurality of optical elements of the projection optical system PL. In the present embodiment, an optical axis AX of the projection optical system PL is parallel to the Z axis. In the projection optical system PL, the exposure light EL advances in the −direction from the object plane side to the image plane side of the projection optical system PL.

In the explanation below, the travel direction of the exposure light EL in the projection optical system PL, which is parallel to the optical axis AX of the projection optical system PL, is called downward (i.e., in the down direction) where appropriate, and the reverse of the travel direction of the exposure light EL in the projection optical system PL is called upward (i.e., in the upward direction) where appropriate. In the present embodiment, downward is the −Z direction and upward is the +Z direction.

The projection optical system PL of the present embodiment is a reduction system that has a projection magnification of, for example, ¼, ⅕, or ⅛. Furthermore, the projection optical system PL may also be a unity magnification system or an enlargement system. In addition, the projection optical system PL may be a dioptric system that does not include catoptric elements, a catoptric system that does not include dioptric elements, or a catadioptric system that includes both catoptric and dioptric elements. In addition, the projection optical system PL may form either an inverted or an erect image.

The projection optical system PL has an emergent surface 11 wherefrom the exposure light EL emerges and travels toward the image plane of the projection optical system PL. A last optical element 12, which is the optical element among the plurality of optical elements of the projection optical system PL that is closest to the image plane of the projection optical system PL, has the emergent surface 11. The projection area PR includes a position whereto the exposure light EL that emerges from the emergent surface 11 can be radiated. In the present embodiment, the emergent surface 11 faces the −Z direction (i.e., downward) and is parallel to the XY plane. Furthermore, the emergent surface 11, which faces the −Z direction, may be a convex surface or a concave surface.

In the present embodiment, the optical axis AX in the vicinity of the image plane of the projection optical system PL, namely, the optical axis AX of the last optical element 12, is substantially parallel to the Z axis. Furthermore, the optical axis defined by the optical element adjacent to the last optical element 12 may be regarded as the optical axis of the last optical element 12. In addition, in the present embodiment, the image plane of the projection optical system PL is substantially parallel to the XY plane, which includes the X axis and the Y axis. In addition, in the present embodiment, the image plane is substantially horizontal. However, the image plane does not have to be parallel to the XY plane and may be a curved surface.

The substrate stage 2 comprises a substrate holding part 13, which releasably holds the substrate P, and is capable of moving on a guide surface 15 of a second base plate 14. The substrate stage 2 is capable of holding and moving the substrate P with respect to the projection area PR by the operation of a drive system 16. The drive system 16 comprises a planar motor that comprises sliders 16A, which are disposed on the substrate stage 2, and stators 16B, which are disposed on the second base plate 14. A planar motor that is capable of moving the substrate stage 2 is disclosed in, for example, U.S. Pat. No. 6,452,292. The substrate stage 2 is capable of moving in six directions, namely, the X axial, Y axial, Z axial, OX, 0Y, and OZ directions, by the operation of the drive system 16.

The substrate stage 2 has an upper surface 17, which is disposed around the substrate holding part 13 and is capable of opposing the emergent surface 11. In the present embodiment, as disclosed in U.S. Patent Application Publication No. 2007/0177125, the substrate stage 2 comprises a plate member holding part 18, which is disposed at least partly around the substrate holding part 13 and releasably holds a lower surface of a plate member T. In the present embodiment, the upper surface 17 of the substrate stage 2 includes an upper surface of the plate member T. The upper surface 17 is flat.

In the present embodiment, the substrate holding part 13 is capable of holding the substrate P such that the front surface thereof is substantially parallel to the XY plane. The plate member holding part 18 can hold the plate member T such that the upper surface 17 of the plate member T is substantially parallel to the XY plane.

Furthermore, the plate member holding part 18 does not have to be provided. Namely, the upper surface 17 of the substrate stage 2 does not have to be provided to the releasable member (T).

The interferometer system 3 comprises a first interferometer unit 3A, which is capable of optically measuring the position of the mask stage 1 (i.e., the mask M) within the XY plane, and a second interferometer unit 3B, which is capable of optically measuring the position of the substrate stage 2 (i.e., the substrate P) within the XY plane. When an exposing process or a prescribed measuring process is performed on the substrate P, the control apparatus 5 controls the positions of the mask stage 1 (i.e., the mask M) and the substrate stage 2 (i.e., the substrate P) by operating the drive systems 9, 16 based on the measurement results of the interferometer system 3.

The liquid immersion member 4 is disposed at least partly around the optical path of the exposure light EL. In the present embodiment, at least part of the liquid immersion member 4 is disposed at least partly around the last optical element 12. The liquid immersion member 4 has a lower surface 20, which is capable of opposing a front surface of an object that is disposed at a position at which the front surface opposes the emergent surface 11. The liquid immersion member 4 forms the immersion space LS such that the optical path of the exposure light EL between the emergent surface 11 and the object, which is disposed at a position at which it opposes the emergent surface 11, is filled with the third liquid LQ3. The third liquid LQ3 is held between at least part of the lower surface 20 and the front surface (i.e., the upper surface) of the object, and the immersion space LS is thereby formed.

The immersion space LS is a portion (i.e., space or area) that is filled with the third liquid LQ3. In the present embodiment, the object includes the substrate stage 2 (i.e., the plate member T) or the substrate P, which is held by the substrate stage 2, or both. During an exposure of the substrate P, the liquid immersion member 4 forms the immersion space LS such that the optical path of the exposure light EL between the last optical element 12 and the substrate P is filled with the third liquid LQ3.

The exposure apparatus EX of the present embodiment is a scanning type exposure apparatus (i.e., a so-called scanning stepper) that projects the image of the pattern of the mask M to the substrate P while synchronously moving the mask M and the substrate P in prescribed scanning directions. When the substrate P is to be exposed, the control apparatus 5 controls the mask stage 1 and the substrate stage 2 so as to move the mask M and the substrate P in the prescribed scanning directions within the XY plane, which intersects the optical axis AX (i.e., the optical path of the exposure light EL). In the present embodiment, the scanning directions (i.e., the synchronous movement directions) of both the substrate P and the mask M are the Y axial directions. The control apparatus 5 radiates the exposure light EL to the substrate P through the projection optical system PL and the third liquid LQ3 of the immersion space LS on the substrate P while both moving the substrate P in one of the Y axial directions with respect to the projection area PR of the projection optical system PL and moving the mask Min the other Y axial direction with respect to the illumination area IR of the illumination system IL synchronized to the movement of the substrate P. Thereby, the image of the pattern of the mask M is projected to the substrate P, which is thereby exposed by the exposure light EL.

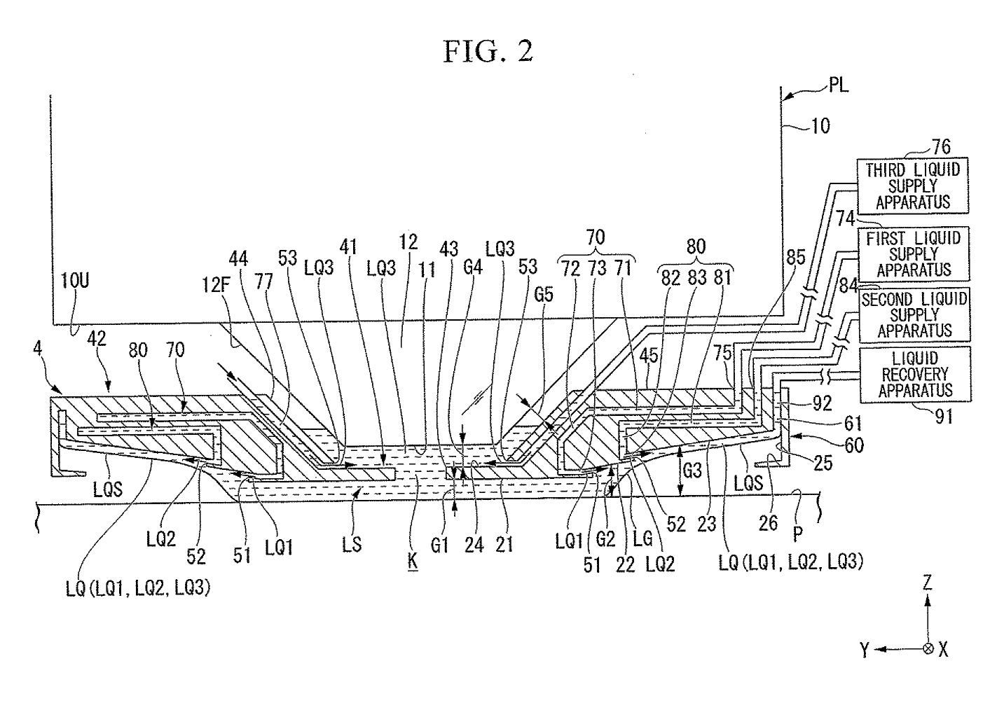

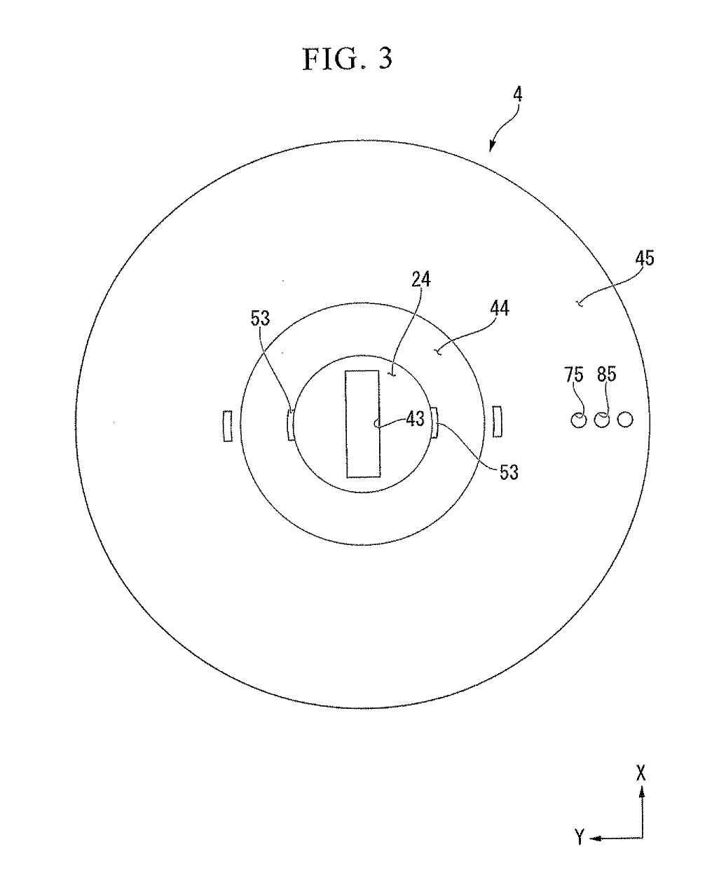

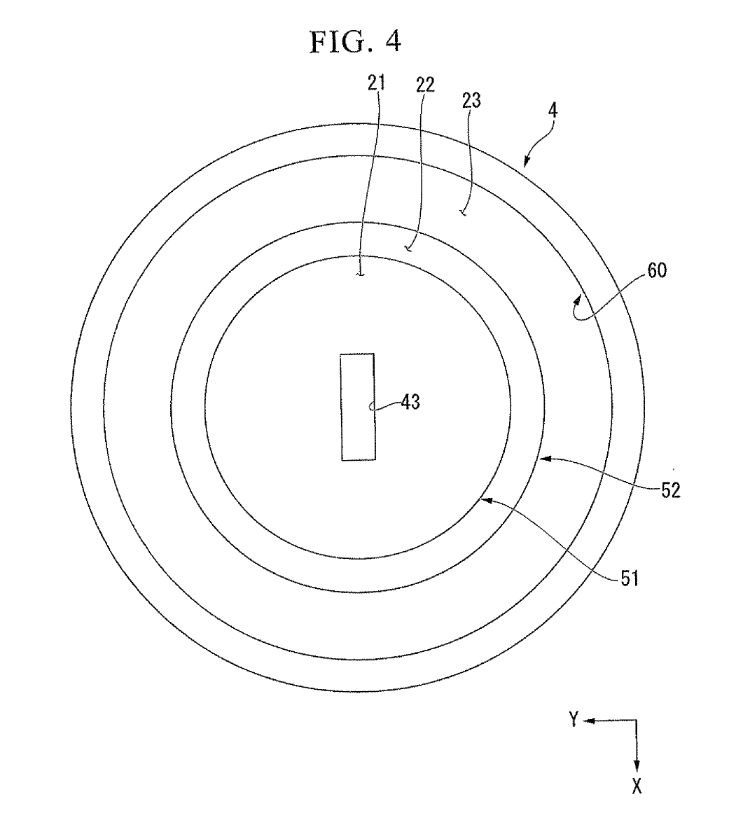

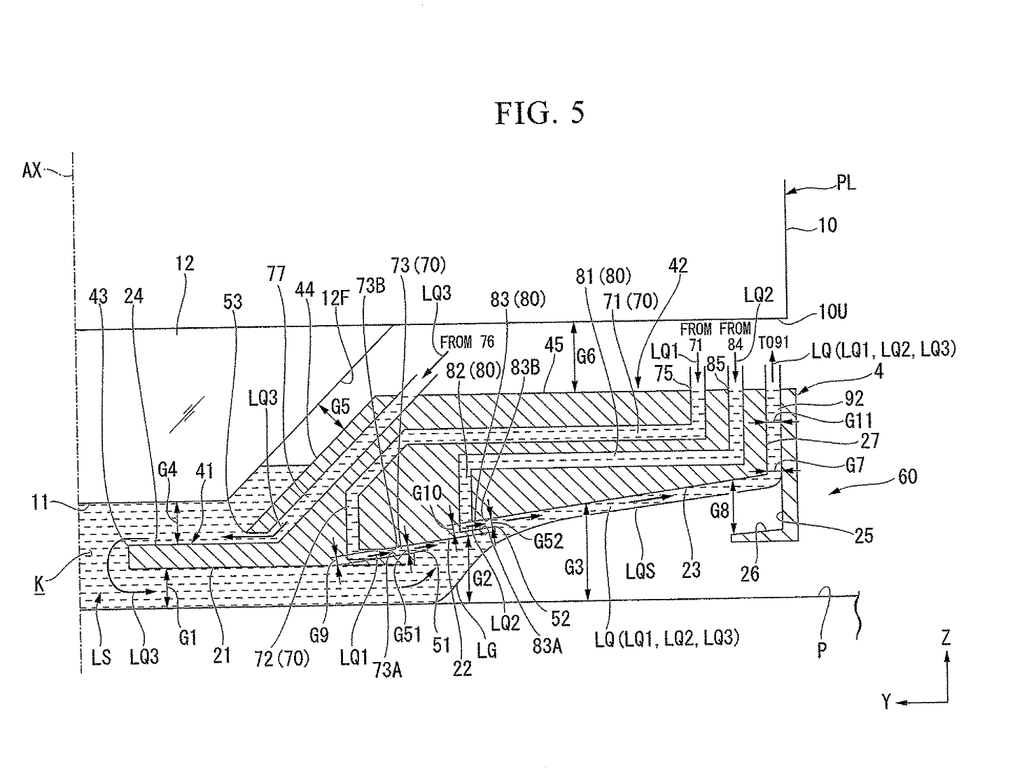

The following text explains the liquid immersion member 4, referencing FIG. 2 through FIG. 5. FIG. 2 is a side cross sectional view that shows the vicinity of the liquid immersion member 4, FIG. 3 is a view from above that shows the liquid immersion member 4, FIG. 4 is a view from below that shows the liquid immersion member 4, and FIG. 5 is a partial enlarged view of FIG. 2.

In the present embodiment, the liquid immersion member 4 is an annular member. As shown in FIG. 3 and FIG. 4, in the present embodiment, the external shape of the liquid immersion member 4 within the XY plane is a circle. Furthermore, the external shape of the liquid immersion member 4 may be some other shape (e.g., a rectangle).

In the present embodiment, the liquid immersion member 4 comprises a plate part 41, at least part of which is disposed such that it opposes the emergent surface 11, and a main body part 42, at least part of which is disposed around the last optical element 12.

The liquid immersion member 4 comprises: a first surface 21, which is disposed at least partly around an optical path K of the exposure light EL that emerges from the emergent surface 11 of the projection optical system PL; a second surface 22, which is disposed at least partly around the first surface 21; a third surface 23, which is disposed at least partly around the second surface 22; a first supply port 51, which is disposed at least partly around the first surface 21 such that the first supply port 51 faces the outer side in radial directions (or is directed in an outward radial direction) with respect to the optical axis AX of the projection optical system PL, that supplies the first liquid LQ1 to the second surface 22; and a second supply port 52, which is disposed at least partly around the second surface 22 such that the second supply port 52 faces the outer side in radial directions (or is directed in an outward radial direction) with respect to the optical axis AX, that supplies the second liquid LQ2 to the third surface 23. In the present embodiment, the lower surface 20 of the liquid immersion member 4 comprises the first surface 21, the second surface 22, and the third surface 23.

In addition, in the present embodiment, the liquid immersion member 4 has third supply ports 53, which supply the third liquid LQ3 to the optical path K of the exposure light EL that emerges from the emergent surface 11.

In the present embodiment, the third liquid LQ3 is the same type of liquid as the first liquid LQ1 or the second liquid LQ2, or both. In the present embodiment, the first liquid LQ1, the second liquid LQ2, and the third liquid LQ3 are the same type of liquid. In the present embodiment, water (i.e., pure water) is used for the first liquid LQ1, the second liquid LQ2, and the third liquid LQ3. In the explanation below, the first liquid LQ1, the second liquid LQ2, and the third liquid LQ3 are generically called a liquid LQ where appropriate.

In the present embodiment, the first surface 21 is disposed continuously around the optical path K of the exposure light EL that emerges from the emergent surface 11. The second surface 22 is disposed continuously around the first surface 21. The third surface 23 is disposed continuously around the second surface 22. In the present embodiment, the external shapes of the first surface 21, the second surface 22, and the third surface 23 within the XY plane are circles. Namely, an outer side edge of the first surface 21 that defines the external shape of the first surface 21, an outer side edge of the second surface 22 that defines the external shape of the second surface 22, and an outer side edge of the third surface 23 that defines the external shape of the third surface 23 are circular. In addition, an inner side edge of the second surface 22 and an inner side edge of the third surface 23 within the XY plane are both circular. In the present embodiment, at least part of the first surface 21 is disposed on the plate part 41, and the second surface 22 and the third surface 23 are disposed on the main body part 42.

In addition, the plate part 41 of the liquid immersion member 4 has a fourth surface 24, which faces a direction opposite that of the first surface 21 and is disposed around the optical path K of the exposure light EL such that at least part of the fourth surface 24 opposes the emergent surface 11.

The plate part 41 of the liquid immersion member 4 has an opening 43 wherethrough the exposure light EL that emerges from the emergent surface 11 can pass. The first surface 21 and the fourth surface 24 are disposed around the opening 43. During an exposure of the substrate P, the exposure light EL that emerges from the emergent surface 11 is radiated to the front surface of the substrate P through the opening 43. As shown in FIG. 3 and FIG. 4, in the present embodiment, the opening 43 is long in the X axial directions, which intersect the scanning directions of the substrate P (i.e., the Y axial directions).

The emergent surface 11, the first surface 21, the second surface 22, and the third surface 23 are capable of opposing the front surface (i.e., the upper surface) of the object disposed below the liquid immersion member 4. During at least part of the exposure of the substrate P, the front surface of the substrate P opposes the emergent surface 11, the first surface 21, the second surface 22, and the third surface 23. Furthermore, the state wherein the first surface 21 and the front surface of the substrate P are opposed includes the state wherein the third liquid LQ3 is present between the front surface of the substrate P and at least part of the first surface 21. In addition, the state wherein the second surface 22 and the front surface of the substrate P are opposed includes the state wherein the liquid LQ is present between the front surface of the substrate P and at least part of the second surface 22. In addition, the state wherein the third surface 23 and the front surface of the substrate P are opposed includes the state wherein the liquid LQ is present between the front surface of the substrate P and at least part of the third surface 23. In addition, the state wherein the second surface 22 and the front surface of the substrate P are opposed includes the state wherein the flow of the liquid LQ (i.e., a liquid surface LQS discussed below) is present between the substrate P and at least part of the second surface 22. In addition, the state wherein the third surface 23 and the substrate P are opposed includes the state wherein the flow of the liquid LQ (i.e., the liquid surface LQS discussed below) is generated between the substrate P and at least part of the third surface 23.

The first surface 21 is capable of opposing the front surface of the object (i.e., the front surface of the substrate P, the upper surface of the plate member T, and the like) across a gap G1. The second surface 22 is capable of opposing the front surface of the object across a gap G2. The third surface 23 is capable of opposing the front surface of the object across a gap G3. The fourth surface 24 opposes the emergent surface 11 across a gap G4.

In the present embodiment, the second surface 22 is disposed above the first surface 21. In addition, the third surface 23 is disposed above the second surface 22. Namely, in the present embodiment, the gap G2 is larger than the gap G1. The gap G3 is larger than the gaps G1, G2.

In the present embodiment, the first surface 21 is substantially parallel to the XY plane, which is perpendicular to the optical axis AX. The second surface 22 is inclined with respect to the XY plane, which is perpendicular to the optical axis AX. The third surface 23 is inclined with respect to the XY plane, which is perpendicular to the optical axis AX.

In the present embodiment, the second surface 22 is inclined upward toward the outer side in radial directions with respect to the optical axis AX. In addition, the third surface 23 is inclined upward toward the outer side in radial directions with respect to the optical axis AX. Namely, the second surface 22 and the third surface 23 are inclined with respect to the first surface 21. In addition, the fourth surface 24 is substantially parallel to the first surface 21. In the present embodiment, the fourth surface 24 and the emergent surface 11 are substantially parallel.

In the present embodiment, the inclination angle of the second surface 22 with respect to the XY plane and the inclination angle of the third surface 23 with respect to the XY plane are substantially equal. Namely, the second surface 22 and the third surface 23 are substantially parallel. Furthermore, the inclination angle of the second surface 22 with respect to the XY plane and the inclination angle of the third surface 23 with respect to the XY plane may be different. Namely, the second surface 22 and the third surface 23 may be nonparallel.

The main body part 42 of the liquid immersion member 4 has: an inner side surface 44, which opposes at least part of a side surface 12F of the last optical element 12 across a gap G5; and an upper surface 45, which opposes a lower surface 10U of the holding member 10 across a gap G6. The side surface 12F is a surface that differs from the emergent surface 11 and wherethrough the exposure light EL does not pass. The side surface 12F is disposed around the emergent surface 11. Furthermore, at least part of the inner side surface 44 may oppose part of the holding member 10. Alternatively, at least part of the upper surface 45 may oppose part of the last optical element 12.

The first supply port 51 supplies the first liquid LQ1 such that the first liquid LQ1 flows on the second surface 22 toward the outer side in radial directions with respect to the optical axis AX. The first supply port 51 supplies the first liquid LQ1 such that the first liquid LQ1 flows along the second surface 22 toward the outer side in radial directions with respect to the optical axis AX while contacting the second surface 22.

The second supply port 52 supplies the second liquid LQ2 such that the second liquid LQ2 flows on the third surface 23 toward the outer side in radial directions with respect to the optical axis AX. The second supply port 52 supplies the second liquid LQ2 such that the second liquid LQ2 flows along the third surface 23 toward the outer side in radial directions with respect to the optical axis AX while contacting the third surface 23

In the present embodiment, the first supply port 51 is disposed between the outer side edge of the first surface 21 and the inner side edge of the second surface 22. Namely, in the present embodiment, the first supply port 51 is disposed above the first surface 21 and below the second surface 22.

In the present embodiment, the second supply port 52 is disposed between the outer side edge of the second surface 22 and the inner side edge of the third surface 23. Namely, in the present embodiment, the second supply port 52 is disposed above the second surface 22 and below the third surface 23.

Namely, in the present embodiment, the second supply port 52 is disposed above the first supply port 51.

In the present embodiment, the first supply port 51 is a slit opening that is formed such that it surrounds the optical path of the exposure light EL. The first supply port 51 is disposed such that it follows along the inner side edge of the second surface 22. A size G51 (i.e., a slit width, a gap) of the first supply port 51 in the Z axial directions is sufficiently small. The size G51 of the first supply port 51 is smaller than, for example, the gap G1 during an exposure of the substrate P.

In the present embodiment, the second supply port 52 is a slit opening that is formed such that it surrounds the optical path of the exposure light EL. The second supply port 52 is disposed such that it follows along the inner side edge of the third surface 23. A size G52 (i.e., a slit width) of the second supply port 52 in the Z axial directions is sufficiently small. The size G52 of the second supply port 52 is smaller than, for example, the gap G1 during an exposure of the substrate P.

Thus, the second supply port 52 is spaced apart from the optical axis AX more than the first supply port 51 is. In addition, in the present embodiment, the first supply port 51 and the second supply port 52 are each a slit opening that is formed such that it surrounds the optical path (i.e., the optical axis AX). Accordingly, in the present embodiment, the entire first supply port 51 and the entire second supply port 52 are disposed at the same position in circumferential directions with respect to the optical axis AX.

In addition, in the present embodiment, the first supply port 51 supplies the first liquid LQ1 along all radial directions with respect to the optical axis AX. In other words, the first supply port 51 supplies the first liquid LQ1 to the second surface 22 such that substantially the entire area of the second surface 22, which is disposed such that it surrounds the optical axis AX, is wetted with the first liquid LQ1.

Similarly, the second supply port 52 supplies the second liquid LQ2 along all radial directions with respect to the optical axis AX. In other words, the second supply port 52 supplies the second liquid LQ2 to the third surface 23 such that substantially the entire area of the third surface 23, which is disposed such that it surrounds the optical axis AX, is wetted with the second liquid LQ2.

In addition, the first supply port 51 supplies the first liquid LQ1 along the second surface 22 such that the first liquid LQ1 contacts the second liquid LQ2 that is supplied via the second supply port 52.

In the present embodiment, a flow velocity V1 of the first liquid LQ1 supplied via the first supply port 51 is lower than a flow velocity V2 of the second liquid LQ2 supplied via the second supply port 52.

In the present embodiment, the flow velocity V1 includes the flow velocities (velocity components) of the first liquid LQ1 in radial directions with respect to the optical axis AX and in directions along the second surface 22. In addition, the flow velocity V2 includes flow velocities (i.e., velocity components) of the second liquid LQ2 in radial directions with respect to the optical axis AX and in directions along the third surface 23.

Furthermore, the flow velocity V1 may be the flow velocities (i.e., velocity components) of the first liquid LQ1 in radial directions with respect to the optical axis AX and in directions along the XY plane, which is perpendicular to the optical axis AX. In addition, the flow velocity V2 may be flow velocities (i.e., velocity components) of the second liquid LQ2 in radial directions with respect to the optical axis AX and in directions along the XY plane, which is perpendicular to the optical axis AX.

The flow velocity V1 includes either the flow velocity of the first liquid LQ1 immediately after the first liquid LQ1 is supplied via the first supply port 51 to the second surface 22 or the flow velocity of the first liquid LQ1 immediately before it is supplied via the first supply port 51 to the second surface 22 and contacts the second liquid LQ2 supplied via the second supply port 52, or both. In addition, the flow velocity V2 includes the flow velocity of the second liquid LQ2 immediately after the second liquid LQ2 is supplied via the second supply port 52 to the third surface 23.

In the present embodiment, the first liquid LQ1 is supplied via the first supply port 51 at a first angle θ1 with respect to the XY plane, which is perpendicular to the optical axis AX, and the second liquid LQ2 is supplied via the second supply port 52 at a second angle θ2 with respect to the XY plane, which is perpendicular to the optical axis AX.

In the present embodiment, the first supply port 51 supplies the first liquid LQ1 upward and toward the outer side in radial directions with respect to the optical axis AX. The second supply port 52 supplies the second liquid LQ2 upward and toward the outer side in radial directions with respect to the optical axis AX. In the present embodiment, the first angle θ1 is equal to the second angle θ2.

In addition, in the present embodiment, the first angle θ1 is substantially equal to the inclination angle of the second surface 22 with respect to the XY plane. The second angle θ2 is substantially equal to the inclination angle of the third surface 23 with respect to the XY plane.

Furthermore, the first angle θ1 may be different from the second angle θ2. For example, the first angle θ1 may be smaller than the second angle θ2. In addition, the first angle θ1 may be larger than the second angle θ2.

In addition, the first angle θ1 may be different from the inclination angle of the second surface 22 with respect to the XY plane. For example, the first angle θ1 may be smaller than or larger than the inclination angle of the second surface 22 with respect to the XY plane. Similarly, the second angle θ2 may be different from the inclination angle of the third surface 23 with respect to the XY plane. For example, the second angle θ2 may be smaller than or larger than the inclination angle of the third surface 23 with respect to the XY plane.

Furthermore, the first supply port 51 may supply the first liquid LQ1 toward the outer side in radial directions with respect to the optical axis AX and substantially parallel to the XY plane, which is perpendicular to the optical axis AX. In addition, the second supply port 52 may supply the second liquid LQ2 toward the outer side in radial directions with respect to the optical axis AX and substantially parallel to the XY plane, which is perpendicular to the optical axis AX.

The third supply ports 53 supply the third liquid LQ3 to a gap between the liquid immersion member 4 and the last optical element 12. In the present embodiment, the third supply ports 53 are disposed at prescribed regions of the liquid immersion member 4 such that they face the optical path K of the exposure light EL that emerges from the emergent surface 11. In the present embodiment, the third supply ports 53 supply the third liquid LQ3 to the space between the emergent surface 11 and the fourth surface 24. In the present embodiment, the third supply ports 53 are disposed in the inner side surface 44. As shown in FIG. 3, in the present embodiment, the third supply ports 53 are disposed on the +Y side and the Y side of the opening 43 (i.e., the optical path of the exposure light EL), one on each side. Furthermore, the third supply ports 53 may be disposed on the +X side and the −X side of the opening 43 (i.e., the optical path of the exposure light EL), one on each side. In addition, the number of the third supply ports 53 is not limited to two. The third supply ports 53 may be disposed at three or more positions around the optical path of the exposure light EL.

The third liquid LQ3 that is supplied via the third supply ports 53 is supplied to the optical path of the exposure light EL that emerges from the emergent surface 11. Thereby, the optical path of the exposure light EL is filled with the third liquid LQ3. In addition, during at least part of the exposure of the substrate P, the front surface of the substrate P opposes the emergent surface 11, the first surface 21, the second surface 22, and the third surface 23. During at least part of the exposure of the substrate P, at least some of the third liquid LQ3 supplied via the third supply ports 53 to the space between the emergent surface 11 and the fourth surface 24 is supplied via the opening 43 to the space between the first surface 21 and the front surface of the substrate P, and thereby the optical path of the exposure light EL between the emergent surface 11 and the front surface of the substrate P is filled with the third liquid LQ3. In addition, at least some of the third liquid LQ3 is held between the first surface 21 and the front surface of the substrate P. The substrate P is exposed with the exposure light EL that emerges from the emergent surface 11 and transits the third liquid LQ3 between the emergent surface 11 and the front surface of the substrate P.

In the present embodiment, part of the immersion space LS is formed from the third liquid LQ3 held between the first surface 21 and the object. In the present embodiment, when the substrate P is irradiated with the exposure light EL, the immersion space LS is already formed such that part of the area of the front surface of the substrate P that includes the projection area PR is covered with the third liquid LQ3. The exposure apparatus EX of the present embodiment adopts a local liquid immersion system.

For the sake of simplicity, the following text explains an exemplary case wherein: the substrate P is disposed at a position at which it opposes the emergent surface 11, the first surface 21, the second surface 22, and the third surface 23; the third liquid LQ3 is held between the liquid immersion member 4 and the substrate P; and thereby the immersion space LS is formed. Furthermore, as discussed above, at least part of the immersion space LS can be formed between the emergent surface 11 and the liquid immersion member 4 on one side and another member (e.g., the plate member T of the substrate stage 2) on the other side.

In the present embodiment, the immersion space LS is formed between the front surface of the substrate P and at least part of the emergent surface 11, the first surface 21, the second surface 22, and the third surface 23 with at least some of the third liquid LQ3 supplied via the third ports 53 such that the optical path of the exposure light EL between the emergent surface 11 and the substrate P is filled with the third liquid LQ3.

In FIG. 2 and FIG. 5, an air-liquid interface LG (i.e., a meniscus or edge) of the liquid LQ of the immersion space LS is formed between the front surface of the substrate P and at least part of the second surface 22 and the third surface 23. In FIG. 2 and FIG. 5, the first supply port 51 supplies the first liquid LQ1 in the state wherein the supply port 51 is immersed in the third liquid LQ3 of the immersion space LS. In addition, in FIG. 2 and FIG. 5, the second supply port 52 supplies the second liquid LQ2 in the state wherein the second supply port 52 is immersed in the third liquid LQ3 or the first liquid LQ1, or both.

The second surface 22 is preferably lyophilic with respect to the first liquid LQ1. In the present embodiment, the contact angle of the first liquid LQ1 with respect to the second surface 22 is less than 90°. In the present embodiment, the second surface 22 is made of titanium and is lyophilic (i.e., hydrophilic) with respect to the first liquid LQ1. In the present embodiment, the second surface 22 is preferably more lyophilic than the front surface of the object (e.g., the substrate P) that opposes the second surface 22. Furthermore, a film that is formed from a material that is lyophilic with respect to the first liquid LQ1 may be disposed on at least part of the lower surface 20 of the liquid immersion member 4, and the second surface 22 may be made lyophilic with respect to the first liquid LQ1. In addition, the second surface 22 does not have to be lyophilic with respect to the first liquid LQ1.

The third surface 23 is preferably lyophilic with respect to the second liquid LQ2. In the present embodiment, the contact angle of the second liquid LQ2 with respect to the third surface 23 is less than 90°. In the present embodiment, the third surface 23 is made of titanium and is lyophilic (i.e., hydrophilic) with respect to the second liquid LQ2. In the present embodiment, the third surface 23 is preferably more lyophilic than the front surface of the object (e.g., the substrate P) that opposes the third surface 23. Furthermore, a film that is formed from a material that is lyophilic with respect to the second liquid LQ2 may be disposed on at least part of the lower surface 20 of the liquid immersion member 4, and the third surface 23 may be made lyophilic with respect to the second liquid LQ2. In addition, the third surface 23 does not have to be lyophilic with respect to the second liquid LQ2.

In addition, the third surface 23 is preferably more lyophilic with respect to the liquid LQ than the second surface 22 is; however, the third surface 23 and the second surface 22 may be substantially equally lyophilic with respect to the liquid LQ, or the second surface 22 may be more lyophilic with respect to the liquid LQ than is the third surface 23.

In the present embodiment, the operations of supplying the first liquid LQ1 via the first supply port 51, the second liquid LQ2 via the second supply port 52, and the third liquid LQ3 via the third supply ports 53 are performed in parallel. Namely, the first liquid LQ1 is supplied via the first supply port 51 to the second surface 22 and the second liquid LQ2 is supplied via the second supply port 52 to the third surface 23 in the state wherein the immersion space LS of the third liquid LQ3 is formed. The first liquid LQ1 flows from the first supply port 51 on the second surface 22 toward the outer side in radial directions with respect to the optical axis AX. In addition, at least some of the third liquid LQ3 of the immersion space LS flows, together with the first liquid LQ1 supplied via the first supply port 51, on the second surface 22 toward the outer side in radial directions with respect to the optical axis AX. In addition, at least some of the first and third liquids LQ1, LQ3 that flow on the second surface 22 toward the outer side in radial directions with respect to the optical axis AX flows—together with the second liquid LQ2 supplied via the second supply port 52—on the third surface 23 toward the outer side in radial directions with respect to the optical axis AX.

Thereby, on the outer side of the air-liquid interface LG of the immersion space LS in radial directions with respect to the optical axis AX, the liquid LQ (i.e., at least some of the first liquid LQ1, the second liquid LQ2, and the third liquid LQ3) flows on the third surface 23 toward the outer side in radial directions with respect to the optical axis AX without contacting the front surface of the substrate P (i.e., the object). Namely, on the outer side of the air-liquid interface LG of the immersion space LS in radial directions with respect to the optical axis AX, a gas space is formed between the surface of the liquid LQ (i.e., the liquid surface LQS) that flows on the second surface 23 and the front surface of the substrate P (i.e., the object) that opposes such.

In addition, the liquid immersion member 4 comprises a recovery part 60, which is disposed on the outer side of the third surface 23 in radial directions with respect to the optical axis AX and recovers at least some of the liquid LQ (i.e., at least some of the first liquid LQ1, the second liquid LQ2, and the third liquid LQ3) on the third surface 23. The recovery part 60 is capable of recovering the first and third liquids LQ1, LQ3, which flow on the third surface 23, together with the second liquid LQ2, which is supplied via the second supply port 52 and flows on the third surface 23. Namely, in the present embodiment, the first liquid LQ1 supplied via the first supply port 51, the second liquid LQ2 supplied via the second supply port 52, and the third liquid LQ3 supplied via the third supply ports 53 are recovered by the recovery part 60.

In the present embodiment, the recovery part 60 has a fifth surface 25, which is disposed such that it intersects the third surface 23. A gap G7 is formed between an outer side edge of the third surface 23 and the fifth surface 25. The recovery part 60 recovers at least some of the liquid LQ that flows from the third surface 23 into the gap G7.

In addition, in the present embodiment, at least part of the fifth surface 25 is disposed lower than the outer side edge of the third surface 23 such that the fifth surface 25 faces the optical axis AX. In the present embodiment, the fifth surface 25 is disposed substantially parallel to the optical axis AX.

In addition, in the present embodiment, the recovery part 60 has a sixth surface 26, which is connected to a lower end of the fifth surface 25 and is disposed such that the sixth surface 26 opposes a circumferential edge area of the third surface 23 across a gap G8. The sixth surface 26 is disposed below the circumferential edge area of the third surface 23 such that the sixth surface 26 faces upward.

In the present embodiment, the fifth surface 25 is disposed annularly around the third surface 23. In addition, the sixth surface 26 is annular within the XY plane.

In the present embodiment, the gap G7 between the outer side edge of the third surface 23 and the fifth surface 25 has a recovery port 61 of the recovery part 60 that is capable of recovering at least some of the liquid LQ on the third surface 23. In the present embodiment, the shape of the recovery port 61 within the XY plane is annular. Furthermore, multiple recovery ports 61 may be disposed within the XY plane at prescribed intervals around the optical path of the exposure light EL. Furthermore, in the present embodiment, the sixth surface 26, which prevents the liquid LQ from falling from the vicinity of the recovery port 61 onto the front surface of the substrate P (i.e., the object), is provided, but may be omitted.

As shown in FIG. 2, the first supply port 51 is connected to a first liquid supply apparatus 74 via a supply passageway. The supply passageway that is connected to the first supply port 51 comprises an internal passageway 70 of the liquid immersion member 4 and a supply pipe passageway, which connects the internal passageway 70 and the first liquid supply apparatus 74. The first liquid supply apparatus 74 can supply the first liquid LQ1, which is clean and temperature adjusted, to the first supply port 51.

In the present embodiment, an inflow port 75 of the internal passageway 70 is disposed in the upper surface 45 of the liquid immersion member 4. The first liquid LQ1 supplied from the first liquid supply apparatus 74 flows into the internal passageway 70 via the inflow port 75. The internal passageway 70 comprises a first portion 71, which extends from the inflow port 75 toward the inner side in radial directions, a second portion 72, which is connected to the first portion 71 and at least part of which is bent, and a third portion 73, which extends from the lower end of the second portion 72 toward the outer side in radial directions such that the third portion 73 connects the second portion 72 and the first supply port 51. In the present embodiment, the internal passageway 70, which comprises the first portion 71, the second portion 72, and the third portion 73, is formed such that the internal passageway 70 surrounds the optical axis AX.

As shown in FIG. 5, the third portion 73 is formed between a lower surface 73A and an upper surface 73B, which opposes the lower surface 73A across a gap G9. In the present embodiment, the lower surface 73A and the upper surface 73B are inclined with respect to the XY plane. In the present embodiment, the lower surface 73A and the upper surface 73B are inclined upward toward the outer side in radial directions with respect to the optical axis AX in accordance with the second surface 22. In the present embodiment, the lower surface 73A and the upper surface 73B are substantially parallel. The gap G9 is substantially equal to the size G51.

Furthermore, the lower surface 73A and the upper surface 73B do not have to be parallel. For example, an angle of either the lower surface 73A or the upper surface 73B with respect to the other may be set such that the size G51 is smaller than the gap G9.

The first liquid LQ1 that flows from the inflow port 75 into the internal passageway 70 spreads and flows in the first portion 71 such that the first liquid LQ1 surrounds the optical axis AX and then flows into the third portion 73 via the second portion 72. The first liquid LQ1 that flows into the third portion 73 flows therethrough toward the outer side in radial directions and is supplied to the first supply port 51. The first supply port 51 supplies the first liquid LQ1 from the third portion 73 to the second surface 22 such that the first liquid LQ1 flows on the second surface 22 toward the outer side in radial directions.

As shown in FIG. 2, the second supply port 52 is connected to a second liquid supply apparatus 84 via a supply passageway. The supply passageway connected to the second supply port 52 comprises an internal passageway 80 of the liquid immersion member 4 and a supply pipe passageway, which connects the internal passageway 80 and the second liquid supply apparatus 84. The second liquid supply apparatus 84 can supply the second liquid LQ2, which is clean and temperature adjusted, to the second supply port 52.

In the present embodiment, an inflow port 85 of the internal passageway 80 is disposed in the upper surface 45 of the liquid immersion member 4. The second liquid LQ2 supplied from the second liquid supply apparatus 84 flows into the internal passageway 80 via the inflow port 85. The internal passageway 80 comprises a fourth portion 81, which extends from the inflow port 85 toward the inner side in radial directions, a fifth portion 82, which is connected to the fourth portion 81 and at least part of which is bent, and a sixth portion 83, which extends from a lower end of the fifth portion 82 toward the outer side in radial directions such that the sixth portion 83 connects the fifth portion 82 and the second supply port 52. In the present embodiment, the internal passageway 80, which comprises the fourth portion 81, the fifth portion 82, and the sixth portion 83, is formed such that the internal passageway 80 surrounds the optical axis AX.

As shown in FIG. 5, the sixth portion 83 is formed between a lower surface 83A and an upper surface 83B, which opposes the lower surface 83A across a gap G10. In the present embodiment, the lower surface 83A and the upper surface 83B are inclined with respect to the XY plane. In the present embodiment, the lower surface 83A and the upper surface 83B are inclined upward toward the outer side in radial directions with respect to the optical axis AX in accordance with the third surface 23. In the present embodiment, the lower surface 83A and the upper surface 83B are substantially parallel. The gap G10 is substantially equal to the size G52.

Furthermore, the lower surface 83A and the upper surface 83B do not have to be parallel. For example, an angle of either the lower surface 83A or the upper surface 83B with respect to the other may be set such that the size G52 is smaller than the gap G10.

The second liquid LQ2 that flows from the inflow port 85 into the internal passageway 80 spreads and flows in the fourth portion 81 such that the second liquid LQ2 surrounds the optical axis AX and then flows into the sixth portion 83 via the fifth portion 82. The second liquid LQ2 that flows into the sixth portion 83 flows therethrough toward the outer side in radial directions and is supplied to the second supply port 52. The second supply port 52 supplies the second liquid LQ2 from the sixth portion 83 to the third surface 23 such that the second liquid LQ2 flows on the third surface 23 toward the outer side in radial directions.

In addition, as shown in FIG. 2, the third supply ports 53 are connected to a third liquid supply apparatus 76 via supply passageways. Each of the supply passageways that connect to the third supply ports 53 comprises an internal passageway 77 of the liquid immersion member 4 and a supply pipe passageway, which connects the internal passageway 77 and the third liquid supply apparatus 76. The third liquid supply apparatus 76 can supply the third liquid LQ3, which is clean and temperature adjusted, to the third supply ports 53.

In addition, as shown in FIG. 2, the recovery port 61 is connected to a liquid supply apparatus 91 via a recovery passageway. In the present embodiment, the recovery passageway that is connected to the recovery port 61 comprises an internal passageway 92 of the liquid immersion member 4 and a recovery pipe passageway, which connects the internal passageway 92 and the liquid recovery apparatus 91. Returning to FIG. 5, at least part of the internal passageway 92 is formed between the fifth surface 25 and a seventh surface 27, which opposes the fifth surface 25 across a gap G11. The liquid recovery apparatus 91 comprises a vacuum system (such as a valve that controls the connection state between a vacuum source and the recovery port 61) and is capable of recovering the liquid LQ via the recovery port 61 by suctioning the liquid LQ.

The following explains a method of using the exposure apparatus EX that has the abovementioned configuration to expose the substrate P.

The control apparatus 5 causes the first surface 21, the second surface 22, and the third surface 23 on one side and the front surface of the substrate P (or the upper surface 17 of the substrate stage 2) on the other side to oppose one another. The first surface 21 and the front surface of the substrate P oppose one another across the gap G1, the second surface 22 and the front surface of the substrate P oppose one another across the gap G2, and the third surface 23 and the front surface of the substrate P oppose one another across the gap G3. In addition, the immersion space LS is formed with the third liquid LQ3 between the front surface of the substrate P and at least part of the emergent surface 11, the first surface 21, the second surface 22, and the third surface 23 such that the optical path of the exposure light EL between the emergent surface 11 and the substrate P is filled with the third liquid LQ3.

The control apparatus 5 supplies the third liquid LQ3 from the third liquid supply apparatus 76 in the state wherein the first surface 21, the second surface 22, and the third surface 23 on one side and the front surface of the substrate P on the other side are caused to oppose one another.

The third liquid LQ3 supplied from the third liquid supply apparatus 76 is supplied via the third supply ports 53 to the space between the emergent surface 11 and the fourth surface 24 and is supplied to the optical path of the exposure light EL that emerges from the emergent surface 11. Thereby, the optical path of the exposure light EL is filled with the third liquid LQ3.

In addition, at least some of the third liquid LQ3 supplied via the third supply ports 53 is supplied via the opening 43 to the space between the first surface 21 and the front surface of the substrate P and is held therebetween. In addition, at least some of the third liquid LQ3 is held between the second surface 22 and the front surface of the substrate P. Thereby, the third liquid LQ3 supplied via the third supply ports 53 forms the immersion space LS between at least part of the emergent surface 11, the first surface 21, the second surface 22, and the third surface 23 on one side and the front surface of the substrate P on the other side such that the optical path of the exposure light EL between the emergent surface 11 and the substrate P is filled with the third liquid LQ3.

In addition, the control apparatus 5 supplies the first liquid LQ1 from the first liquid supply apparatus 74. In addition, the control apparatus 5 supplies the second liquid LQ2 from the second liquid supply apparatus 84. In addition, the control apparatus 5 operates the liquid recovery apparatus 91.

The first liquid LQ1 supplied from the first liquid supply apparatus 74 is supplied to the first supply port 51 via the supply passageway that is connected to the first supply port 51. The first supply port 51 supplies the first liquid LQ1 to the second surface 22. The first supply port 51 supplies the first liquid LQ1 along the second surface 22 such that the first liquid LQ1 contacts the second supply port 52.

The second liquid LQ2 supplied from the second liquid supply apparatus 84 is supplied to the second supply port 52 via the supply passageway that is connected to the second supply port 52. The second supply port 52 supplies the second liquid LQ2 to the third surface 23.

In the present embodiment, the first liquid LQ1 from the first supply port 51 is supplied along the second surface 22 such that the first liquid LQ1 contacts the second liquid LQ2 that is supplied via the second supply port 52.

The control apparatus 5 controls the first liquid supply apparatus 74, the second liquid supply apparatus 84, and the third liquid supply apparatus 76 such that the operations of supplying the first liquid LQ1 via the first supply port 51, the second liquid LQ2 via the second supply port 52, and the third liquid LQ3 via the third supply ports 53 are performed in parallel. Namely, the control apparatus 5 supplies the first liquid LQ1 via the first supply port 51 and the second liquid LQ2 via the second supply port 52 in the state wherein the immersion space LS is formed with the third liquid LQ3 supplied via the third supply ports 53.

The first supply port 51 supplies the first liquid LQ1 diagonally upward. The first supply port 51 supplies the first liquid LQ1 diagonally upward at the first angle θ1 with respect to the XY plane, which is perpendicular to the optical axis AX. When the first liquid LQ1 is supplied via the first supply port 51, it flows on the second surface 22 toward the outer side in radial directions with respect to the optical axis AX; in addition, at least some of the third liquid LQ3 of the immersion space LS flows, together with the first liquid LQ1 supplied via the first supply port 51, on the second surface 22 toward the outer side in radial directions with respect to the optical axis AX.

The second supply port 52 supplies the second liquid LQ2 diagonally upward. The second supply port 52 supplies the second liquid LQ2 diagonally upward at the second angle θ2 with respect to the XY plane, which is perpendicular to the optical axis AX. When the second liquid LQ2 is supplied via the second supply port 52, it flows on the third surface 23 toward the outer side in radial directions with respect to the optical axis AX and at least some of the first liquid LQ1 and the third liquid LQ3 that flowed on the second surface 22 toward the outer side in radial directions with respect to the optical axis AX flows, together with the second liquid LQ2 supplied via the second supply port 52, on the third surface 23 toward the outer side in radial directions with respect to the optical axis AX.

In the present embodiment, the control apparatus 5 controls the first liquid supply apparatus 74 or the second liquid supply apparatus 84, or both, such that the flow velocity V1 of the first liquid LQ1 supplied via the first supply port 51 is lower than the flow velocity V2 of the second liquid LQ2 supplied via the second supply port 52.

The control apparatus 5 supplies the first liquid LQ1 via the first supply port 51 and the second liquid LQ2 via the second supply port 52 such that the gas space is formed between the surface (i.e., the liquid surface LQS) of the liquid LQ that flows on the second surface 22 and the front surface of the substrate P (i.e., the object). Thereby, the liquid surface LQS of the liquid LQ, which flows toward the outer side in radial directions with respect to the optical axis AX, is formed on the outer side of the second surface 22 in radial directions with respect to the optical axis AX on the outer side of the air-liquid interface LG of the immersion space LS). The liquid LQ (i.e., the first, second, and third liquids LQ1, LQ2, LQ3) that flows on the third surface 23 toward the outer side in radial directions with respect to the optical axis AX is recovered by the recovery part 60. At least some of the liquid LQ that flows on the third surface 23 is recovered via the recovery port 61.

While flowing the liquid LQ on the third surface 23 by performing the operations of supplying the first liquid LQ1 via the first supply port 51, the second liquid LQ2 via the second supply port 52, and the third liquid LQ3 via the third supply ports 53 in parallel with the recovery of the liquid LQ by the recovery part 60 (i.e., the recovery port 61), the control apparatus 5 forms the immersion space LS such that the optical path of the exposure light EL between the emergent surface 11 and the substrate P is filled with the third liquid LQ3.

While supplying the third liquid LQ3 via the third supply ports 53 in parallel with the operations of supplying the first liquid LQ2 via the first supply port 51 and the second liquid LQ1 via the second supply port 52, the control apparatus 5 starts the exposure of the substrate P in the state wherein the immersion space LS is formed such that part of the front surface of the substrate P is locally covered with the third liquid LQ3.

The control apparatus 5 illuminates the mask M with the exposure light EL by causing the illumination system IL to emit the exposure light EL. The exposure light EL that emerges from the mask M emerges from the emergent surface 11 of the projection optical system PL. The control apparatus 5 exposes the substrate P with the exposure light EL that emerges from the emergent surface 11 and transits the third liquid LQ3 between the emergent surface 11 and the substrate P. Thereby, the image of the pattern of the mask M is projected to the substrate P, which is thereby exposed with the exposure light EL. During the exposure of the substrate P as well, the operations of supplying the liquid LQ1 via the first supply port 51, the second liquid LQ2 via the second supply port 52, and the third liquid LQ3 via the third supply ports 53 are performed in parallel.

As discussed above, the exposure apparatus EX of the present embodiment is a scanning type exposure apparatus wherein the substrate P is moved in prescribed directions within the XY plane in the state wherein the third liquid LQ3 is held between the emergent surface 11 and the substrate P (i.e., in the state wherein the immersion space LS is formed) during at least part of the exposure of the substrate P. For example, during the radiation of the exposure light EL to the substrate P (i.e., during the scanning exposure), the substrate P moves in the Y axial directions with respect to the last optical element 12 and the liquid immersion member 4. In addition, if multiple shot regions on the substrate P are sequentially exposed, then, when a second shot region is to be exposed after the exposure of a first shot region, the substrate P is moved (i.e., stepped) in, for example, one of the X axial directions with respect to the last optical element 12 and the liquid immersion member 4 or a direction that is inclined with respect to the X axis within the XY plane. In addition, the movement during a scanning exposure is not limited to a stepping motion; for example, it is also possible for the substrate P to move under various movement conditions in the state wherein the third liquid LQ3 is held between the substrate P and the emergent surface 11.

The movement conditions of the substrate P include at least a movement velocity and an acceleration (or a deceleration) in a prescribed direction (e.g., the −Y direction) within the XY plane and a movement distance (i.e., when moving from a first position to a second position within the XY plane).

In the present embodiment, the first liquid LQ1 supplied via the first supply port 51 flows on the second surface 22 toward the outer side in radial directions with respect to the optical axis AX; therefore, even if, for example, the substrate P moves at a high speed or a high acceleration, it is possible to prevent the third liquid LQ3 from, for example, leaking out of the space between the liquid immersion member 4 and the substrate P or forming a film, a drop, or the like and remaining on the substrate P.

In addition, in the present embodiment, the second liquid LQ2 supplied via the second supply port 52 flows on the third surface 23 toward the outer side in radial directions with respect to the optical axis AX, which makes it possible to prevent the third liquid LQ3 (a film, a drop, or the like) from remaining on the substrate P.

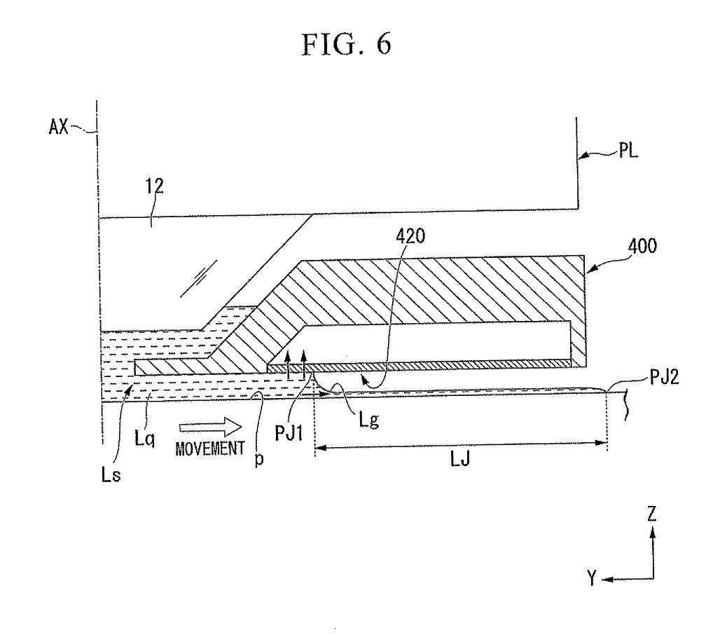

FIG. 6 is a schematic drawing that shows the behavior of the immersion space Ls (i.e., the liquid Lq) when a liquid immersion member 400 according to a comparative example is used. The first and second supply ports (51, 52) are not provided to the liquid immersion member 400. If the substrate p is moved at high speed in the −Y direction in the state wherein the liquid Lq is held between the last optical element 12 and the liquid immersion member 400 on one side and the front surface of the substrate p on the other side, then there is an increased possibility that at least some of the liquid Lq that forms the immersion space Ls will form a film on the substrate p. Namely, in the comparative example shown in FIG. 6, there is a possibility that the movement of the substrate p in the −Y direction will increase a distance LJ (i.e., an amount of deviation) between a position PE of an upper end of an air-liquid interface Lg of the liquid Lq (i.e., the intersection between the air-liquid interface Lg and a lower surface 420 of the liquid immersion member 400) and a position PJ2 of a lower end of the air-liquid interface Lg (i.e., the intersection between the air-liquid interface Lg and the front surface of the substrate p) in radial directions with respect to the optical axis AX. As a result, there is an increased possibility that the liquid Lq will, for example, leak out of the space between the liquid immersion member 400 and the front surface of the substrate p or form a film, a drop, or the like and remain on the substrate p.

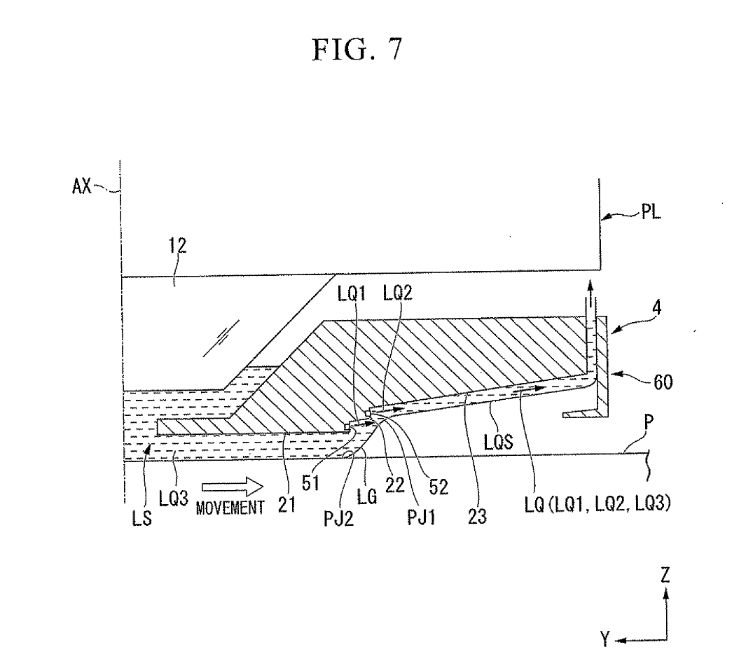

FIG. 7 is a schematic drawing for explaining the behavior of the immersion space LS (i.e., the liquid LQ) in the case wherein the liquid immersion member 4 according to the present embodiment is used. The first supply port 51 and the second supply port 52, which face toward the outer side in radial directions with respect to the optical axis AX, are provided, and the liquid LQ flows on the second surface 22 and the third surface 23 toward the outer side in the radial directions with respect to the optical axis AX, which prevents at least some of the third liquid LQ3 that forms the immersion space LS from, for example, leaking out of the space between the liquid immersion member 4 and the front surface of the substrate P or forming a film, a drop, or the like and remaining on the substrate P.

Namely, the liquid surface LQS of the liquid LQ that flows toward the outer side in radial directions with respect to the optical axis AX is formed on the outer side of the air-liquid interface LG in radial directions with respect to the optical axis AX, and therefore it is possible to prevent the third liquid LQ3 from remaining on the front surface of the substrate P, which opposes the liquid surface LQS. For example, even if the position PJ2 at the lower end of the air-liquid interface LG of the third liquid LQ3 moves in the −Y direction by the movement of the substrate P in the −Y direction, the liquid LQ flows in the −Y direction on the second surface 22 and the third surface 23, and the position PJ1 at the upper end of the air-liquid interface LG formed by the liquid. LQ (i.e., the first liquid LQ1, the second liquid LQ2, the third liquid LQ3, or any combination thereof) is also displaced smoothly in the −Y direction, which makes it possible to prevent the distance LJ (i.e., the amount of deviation) between the position PJ1 at the upper end of the air-liquid interface LG of the liquid LQ and the position PJ2 at the lower end of the air-liquid interface LG from increasing. Accordingly, even if the substrate P moves, the formation of a thin film of the third liquid LQ3 on the substrate P is prevented. Accordingly, it is also possible to prevent the third liquid LQ3 from leaking out, remaining behind, or the like.

In addition, in the present embodiment, the second supply port 52 is provided and the first and third liquids LQ1, LQ3 that flow on the second surface 22 can flow smoothly on the third surface 23 toward the outer side (i.e., the recovery part 60) in radial directions with respect to the optical axis AX because of the force of the flow of the second liquid LQ2 supplied via the second supply port 52. Namely, supplying the second liquid LQ2 via the second supply port 52 makes it possible for the second liquid LQ2 to smoothly move the first and third liquids LQ1, LQ3, which move from the second surface 22 onto the third surface 23, to the recovery part 60. Thereby, the liquid LQ that moves from the second surface 22 onto the third surface 23 can be recovered by the recovery part 60 while preventing that liquid LQ from falling onto the substrate P.

In the present embodiment, the second liquid LQ2 is supplied via the second supply port 52, which makes it possible to increase the liquid surface LQS in radial directions with respect to the optical axis AX without increasing the flow velocity of the first liquid LQ1 supplied via the first supply port 51. Accordingly, even in a case wherein, for example, the substrate P moves a long distance, it is possible to effectively prevent the formation of a thin film of the third liquid LQ3 on the substrate P.

In addition, in the present embodiment, the flow velocity V1 of the first liquid LQ1 supplied via the first supply port 51 is lower than the flow velocity V2 of the second liquid LQ2 supplied via the second supply port 52. Thereby, it is also possible to more effectively prevent the third liquid LQ3 from leaking out, remaining behind, and the like.

For example, if the flow velocity V1 of the first liquid LQ1 supplied via the first supply port 51 is too high, then, because of the phenomenon wherein the pressure around the first liquid LQ1 supplied via the first supply port 51 drops due to Bernoulli's law, a strong upward flow might be generated in the third liquid LQ3 of the immersion space LS in the vicinity of the first supply port 51 and, as shown in FIG. 6, the shape of the air-liquid interface LG might fluctuate and a thin film of the third liquid LQ3 might be formed on the substrate P.

In the present embodiment, the flow velocity V1 of the first liquid LQ1 supplied via the first supply port 51 is low, which makes it possible to increase the distance L1 (i.e., amount of deviation) between the position PJ1 and the position PJ2 while preventing the occurrence of the phenomenon discussed above. Accordingly, even if the substrate P moves, it is possible to prevent a thin film of the third liquid LQ3 from forming on the substrate P. Accordingly, it is also possible to prevent the third liquid LQ3 from leaking out, remaining behind, and the like.

In addition, in the present embodiment, the second liquid LQ2 is supplied via the second supply port 52, which makes it possible, even if the flow velocity V1 of the first liquid LQ1 supplied via the first supply port 51 is low, to smoothly move the first and third liquids LQ1, LQ3 to the recovery part 60 by the force of the flow of the second liquid LQ2.

In addition, in the present embodiment, the flow velocity V2 of the second liquid LQ2 supplied via the second supply port 52 is higher than the flow velocity V1 of the first liquid LQ1 supplied via the first supply port 51, which makes it possible to more smoothly move the first and third liquids LQ1, LQ3 to the recovery part 60 by the force of the flow of the second liquid LQ2. Accordingly, the liquid LQ that flows on the third surface 23 can be recovered by the recovery part 60 while preventing that liquid LQ from falling onto the substrate P.

In the present embodiment, the first supply port 51 supplies the first liquid LQ1 in accordance with the movement conditions of the substrate P, which opposes the emergent surface 11. In addition, the second supply port 52 supplies the second liquid LQ2 in accordance with supply conditions of the first liquid LQ1 supplied via the first supply port 51.

The control apparatus 5 adjusts the supply conditions of the first liquid LQ1 supplied via the first supply port 51 in accordance with the movement conditions of the substrate P. In addition, the control apparatus 5 adjusts the supply conditions of the second liquid LQ2 supplied via the second supply port 52 in accordance with the supply conditions of the first liquid LQ1 supplied via the first supply port 51.

As discussed above, the movement conditions of the substrate P include either a movement velocity and an acceleration (or a deceleration) in a prescribed direction (e.g., the −Y direction) within the XY plane or a movement distance (i.e., when moving from a first position to a second position within the XY plane), or both. The supply conditions of the first liquid LQ1 include either the flow velocity V1 of the first liquid LQ1 supplied via the first supply port 51 or the supply direction of the first liquid LQ1, or both. The supply conditions of the second liquid LQ2 include either the flow velocity V2 of the second liquid LQ2 supplied via the second supply port 52 or the supply direction of the second liquid LQ2, or both.

For example, the control apparatus 5 adjusts—in accordance with the movement velocity of the substrate P in the prescribed direction (e.g., one of the Y axial directions) within the XY plane—the flow velocity V1 of the first liquid LQ1 that is supplied via the first supply port 51.

For example, if the substrate P is moved at high velocity in the −Y direction, then the control apparatus 5 increases the flow velocity V1 of the first liquid LQ1 that is supplied in the −Y direction via the first supply port 51. The control apparatus 5 can adjust the flow velocity V1 of the first liquid LQ1 by, for example, adjusting the amount of the first liquid LQ1 that is supplied per unit of time by the first liquid supply apparatus 74. The amount of deviation LJ between the position PH and the position PJ2 can be decreased by adjusting the flow velocity V1 of the first liquid LQ1 in accordance with the movement velocity of the substrate P.

In addition, if the flow velocity V1 of the first liquid LQ1 supplied in the −Y direction increases, then the control apparatus 5 increases the flow velocity V2 of the second liquid LQ2 supplied in the −Y direction. The control apparatus 5 can adjust the flow velocity V2 of the second liquid LQ2 by, for example, adjusting the amount of the second liquid LQ2 that is supplied per unit of time by the second liquid supply apparatus 84. The liquid LQ on the third surface 23 can be smoothly moved to the recovery part 60 by adjusting the flow velocity V2 of the second liquid LQ2 in accordance with the flow velocity V1 of the first liquid LQ1.

In addition, the control apparatus 5 can adjust the flow velocity V1 of the first liquid LQ1, which is supplied substantially parallel to the Y axial directions via the first supply port 51, in accordance with the acceleration of the substrate P in the prescribed direction (e.g., one of the Y axial directions) within the XY plane. For example, if the substrate P is moved with a high acceleration in the −Y direction, then the control apparatus 5 can increase the flow velocity V1 of the first liquid LQ1 that is supplied in the −Y direction via the first supply port 51. In so doing, it is possible to reduce the amount of deviation LJ. In addition, the control apparatus 5 can smoothly move the liquid LQ on the third surface 23 to the recovery part 60 by adjusting the flow velocity V2 of the second liquid LQ2 supplied substantially parallel to the Y axial directions via the second supply port 52 in accordance with the flow velocity V1 of the second liquid LQ1.

In addition, the control apparatus 5 can adjust the flow velocity V1 of the first liquid LQ1, which is supplied substantially parallel to the Y axial directions via the first supply port 51, in accordance with the linear movement distance of the substrate P in the prescribed direction (e.g., one of the Y axial directions) within the XY plane. In addition, the control apparatus 5 can adjust the second liquid LQ2, which is supplied substantially parallel to the Y axial directions via the second supply port 52, in accordance with the flow velocity V1 of the first liquid LQ1.

Thus, it is possible to reduce the amount of deviation LJ between the position PJ1 and the position PJ2 and to prevent the third liquid LQ3 from leaking out, remaining behind, and the like by adjusting, in accordance with the movement conditions of the substrate P, the supply conditions of the first liquid LQ1 supplied via the first supply port 51 in the same direction as the movement direction of the substrate P (i.e., the −Y direction). In addition, the liquid LQ on the third surface 23 can be smoothly recovered by adjusting, in accordance with the supply conditions of the first liquid LQ1, the supply conditions of the second liquid LQ2 supplied via the second supply port 52.

Furthermore, the supply conditions of the first liquid LQ1 supplied via the first supply port 51 do not have to be adjusted in accordance with the movement conditions of the substrate P. In addition, the supply conditions of the second liquid LQ2 supplied via the second supply port 52 do not have to be adjusted in accordance with changes in the supply conditions of the first liquid LQ1 supplied via the first supply port 51.

Furthermore, the above explained a case wherein the immersion space LS of the third liquid LQ3 is formed on the substrate P, but the same also applies to cases wherein the immersion space LS of the third liquid LQ3 is formed on the substrate stage 2 (i.e., the plate member T) or wherein the immersion space LS spans the substrate stage 2 (i.e., the plate member T) and the substrate P.

As explained above, the present embodiment provides the first supply port 51, which is disposed such that it faces the outer side in radial directions (such that it is directed in an outward radial direction) with respect to the optical axis AX and supplies the first liquid LQ1 to the second surface 22 of the liquid immersion member 4, and the second supply port 52, which is disposed such that it faces the outer side in radial directions (such that it is directed in an outward radial direction) with respect to the optical axis AX and supplies the second liquid LQ2 to the third surface 23 of the liquid immersion member 4, which makes it possible to prevent, for example, the third liquid LQ3 from leaking out or remaining on the front surface of the object (the substrate P and the like) that opposes the second surface 22 and the third surface 23. Accordingly, it is possible to prevent exposure failures from occurring while preventing a drop in throughput.

In addition, according to the present embodiment, the recovery part 60 has the fifth surface 25, which makes it possible to prevent the liquid LQ from leaking off of the third surface 23 and to satisfactorily recover the liquid LQ from the third surface 23 via the recovery port 61. In addition, the sixth surface 26 is provided, which makes it possible to prevent the liquid LQ in the circumferential edge area of the third surface 23 from falling onto the substrate P and the like. Furthermore, a porous member, such as mesh, may be disposed in the recovery port 61.

### Second Embodiment

The following text explains a second embodiment. In the explanation below, constituent parts that are identical or equivalent to those in the embodiment discussed above are assigned identical symbols, and the explanations thereof are therefore abbreviated or omitted.

In the present embodiment, the second surface 22 is not inclined upward. In the present embodiment, the second surface 22 is substantially horizontal. In addition, in the present embodiment, the first liquid LQ1 supplied via a first supply port 51B is supplied parallel to the XY plane, which is perpendicular to the optical axis AX.

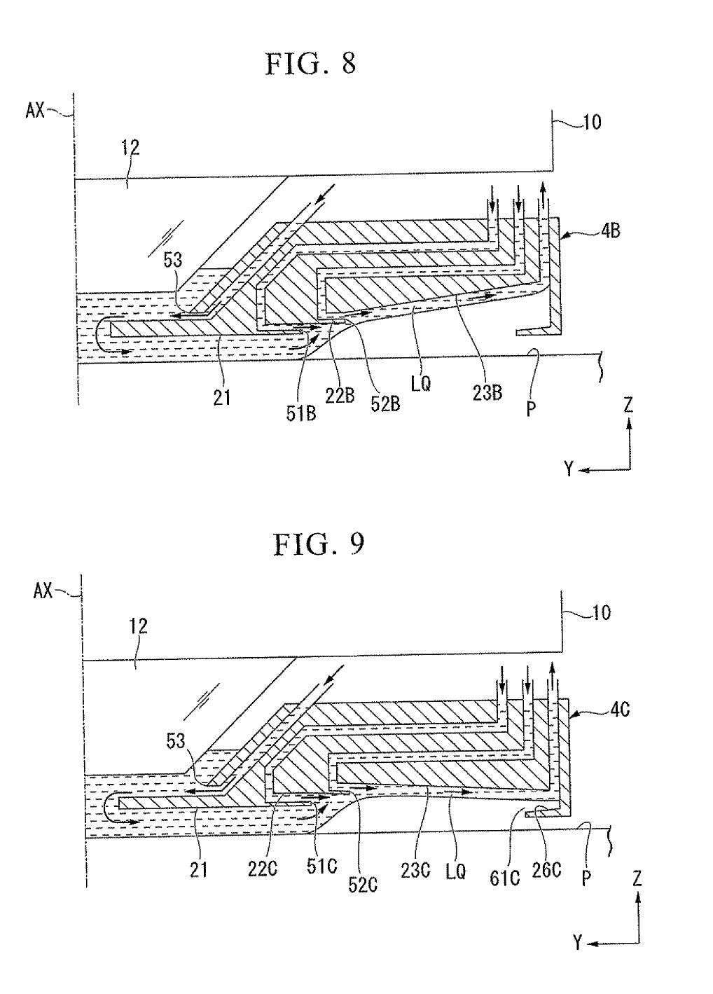

FIG. 8 shows one example of a liquid immersion member 4B according to the second embodiment. In FIG. 8, the liquid immersion member 4B has the first surface 21, a second surface 22B, and a third surface 23B. In the present embodiment, the first surface 21 and the second surface 22B are substantially parallel. The second surface 22B is substantially parallel to the XY plane. The third surface 23B is inclined upward toward the outer side in radial directions with respect to the optical axis AX.

In addition, the liquid immersion member 4B comprises the first supply port 51B, which supplies the first liquid LQ1 substantially parallel to the XY plane, and a second supply port 52B, which supplies the second liquid LQ2 upward toward the outer side in radial directions with respect to the optical axis AX.

At least during the exposure of the substrate P, the first liquid LQ1 is supplied via the first supply port 51B substantially parallel to the XY plane, which is perpendicular to the optical axis AX, and the second liquid LQ2 is supplied diagonally upward via the second supply port 52B.

In the present embodiment as well, it is possible to prevent the third liquid LQ3 of the immersion space LS from leaking out, remaining behind, and the like.

In addition, as in a liquid immersion member 4C shown in FIG. 9, a third surface 23C may be inclined downward toward the outer side in radial directions with respect to the optical axis AX. In addition, a second surface 22C may be inclined downward toward the outer side in radial directions with respect to the optical axis AX or may be parallel to the XY plane.

A first supply port 51C shown in FIG. 9 supplies the first liquid LQ1 substantially parallel to the XY plane. A second supply port 52C supplies the second liquid LQ2 downward toward the outer side in radial directions with respect to the optical axis AX.

Furthermore, the second surface 22C and the third surface 23C may be substantially parallel to the XY plane. In addition, the first supply port 51C may supply the first liquid LQ1 substantially parallel to the XY plane, and the second supply port 52C may supply the second liquid LQ2 substantially parallel to the XY plane.

Furthermore, in the example shown in FIG. 9, a sixth surface 26C is proximate to a circumferential edge of the third surface 23C, and a recovery port 61C is formed between the sixth surface 26C and the third surface 23C. Thus, the recovery port 61C, wherethrough the liquid LQ is recovered from the third surface 23C, may face the optical axis AX. Namely, the recovery port 61C, wherethrough the liquid LQ is recovered from the third surface 23C, does not have to be oriented downward (i.e., in the −Z direction) as in the first embodiment.

### Third Embodiment

The following text explains a third embodiment. In the explanation below, constituent parts that are identical or equivalent to those in the embodiments discussed above are assigned identical symbols, and the explanations thereof are therefore abbreviated or omitted.

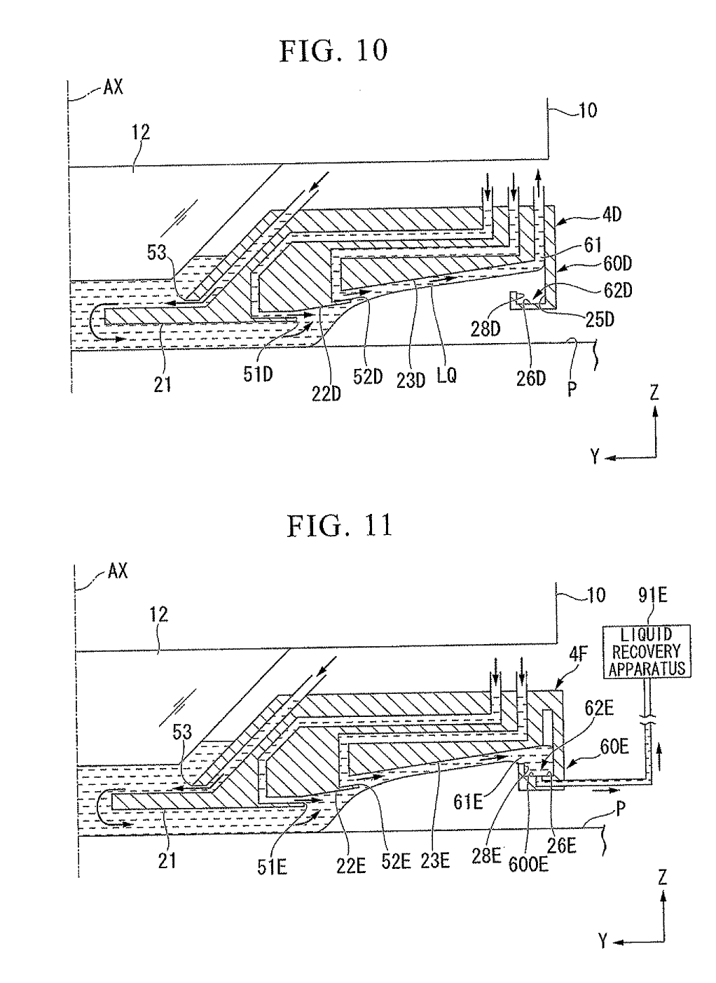

FIG. 10 is a view that shows one example of a liquid immersion member 4D according to the third embodiment. In FIG. 10, the liquid immersion member 4D has a first supply port 51D, which supplies the first liquid LQ1 to a second surface 22D, a second supply port 52D, which supplies the second liquid LQ2 to a third surface 23D, and a recovery part 60D, which recovers at least some of the liquid LQ on the third surface 23D. In the present embodiment, the recovery part 60D has a recessed part 62D, which is disposed below a circumferential edge area of the third surface 23D such that the recessed part 62D is oriented upward. The recessed part 62D is defined by a lower end of a fifth surface 25D, a sixth surface 26D, and an eighth surface 28D, which is disposed such that the eighth surface 28D opposes the fifth surface 25D. The recessed part 62D is annular within the XY plane.

Because the recessed part 62D is provided, the liquid LQ on the third surface 23D is prevented from leaking out, falling onto the substrate P, and the like.

A recovery part 60E shown in FIG. 11 is a modified example of the recovery part 60D shown in FIG. 10. In FIG. 11, a liquid immersion member 4E has a first supply port 51E, which supplies the first liquid LQ1 to a second surface 22E, a second supply port 52E, which supplies the second liquid LQ2 to a third surface 23E, and the recovery part 60E, which recovers at least some of the liquid LQ on the third surface 23E. The recovery part 60E has a recovery port 61E between an upper end of an eighth surface 28E and the third surface 23E. In addition, a discharge port 600E, which discharges the liquid LQ that flows into a recessed part 62E from the third surface 23E, is provided on the inner side of the recessed part 62E. The recessed part 62E can accumulate the liquid LQ. The liquid LQ on the third surface 23E can flow into the recessed part 62E via the recovery port 61E. The recovery part 60E recovers at least some of the liquid LQ that flows into the recessed part 62E by discharging that liquid LQ via the discharge port 600E disposed in the recessed part 62E. In the example shown in FIG. 11, the recovery port 61E faces the optical axis AX, and the discharge port 600E is disposed in a sixth surface 26E, which faces upward. The discharge port 600E is connected to a liquid recovery apparatus 91E via a recovery passageway. The liquid recovery apparatus 91E recovers at least some of the liquid LQ that flows into the recessed part 62E via the discharge port 600E and the recovery passageway.

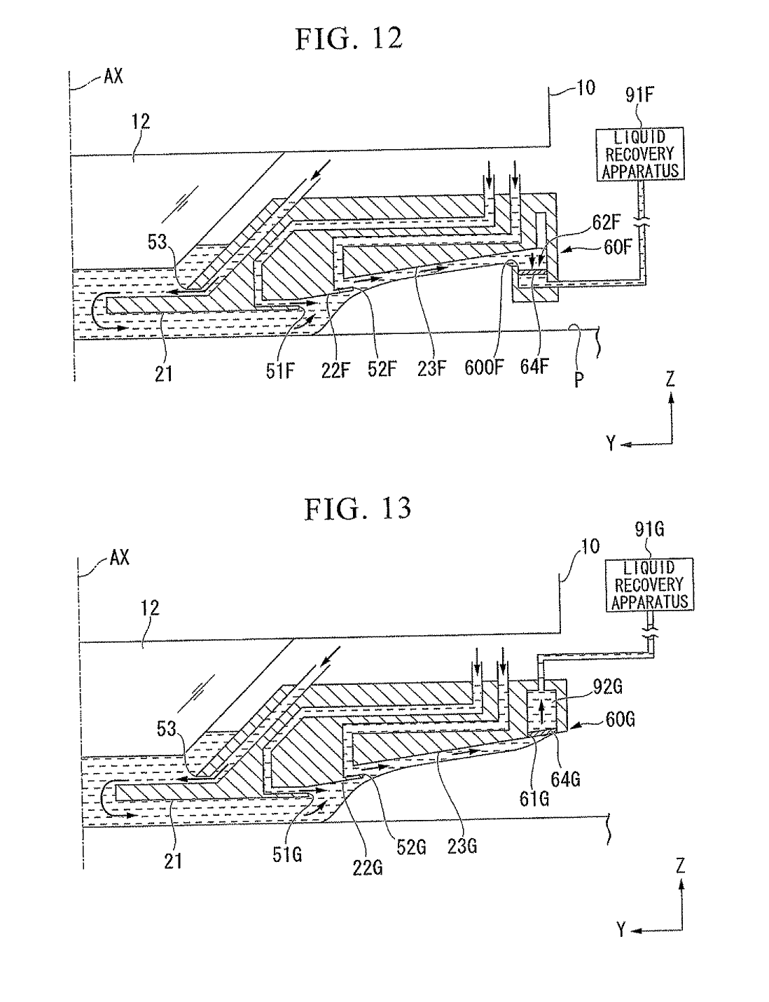

A recovery part 60F shown in FIG. 12 is a modified example of the recovery part 60E shown in FIG. 11. In FIG. 12, a liquid immersion member 4F has a first supply port 51F, which supplies the first liquid LQ1 to a second surface 22F, a second supply port 52F, which supplies the second liquid LQ2 to a third surface 23F, and a recovery part 60F, which recovers at least part of the liquid LQ on the third surface 23F. The recovery part 60F has a discharge port 600F, which is disposed on the inner side of a recessed part 62F and is capable of discharging at least some of the liquid LQ on the third surface 23F, and comprises a porous member 64F, which is disposed in the discharge port 600F. The discharge port 600F is connected to a liquid recovery apparatus 91F via a recovery passageway.

By controlling the liquid recovery apparatus 91F, the control apparatus 5 can control the difference between a pressure in a space on the upper surface side and a pressure in a space on the lower surface side of the porous member 64F such that only the liquid LQ passes from the upper surface side space to the lower surface side space of the porous member 64F. The control apparatus 5 controls the difference between the pressure in the space on the upper surface side and the pressure in the space on the lower surface side of the porous member 64F by controlling the liquid recovery apparatus 91F such that only the liquid LQ passes from the upper surface side to the lower surface side of the porous member 64F; namely, the control apparatus 5 makes an adjustment such that only the liquid LQ is recovered from the third surface 23F via the holes of the porous member 64F and gas does not pass therethrough. The technology for adjusting the pressure differential between the one side and the other side of the porous member 64F and passing only the liquid LQ from the one side to the other side of the porous member 64F is disclosed in, for example, U.S. Pat. No. 7,292,313.

A recovery part 600 shown in FIG. 13 is a modified example of the recovery part 60 of the first embodiment. In FIG. 13, a liquid immersion member 4G has a first supply port 51G, which supplies the first liquid LQ1 to a second surface 22G, a second supply port 52G, which supplies the second liquid LQ2 to a third surface 23G, and the recovery part 60G, which recovers at least some of the liquid LQ on the third surface 23G. The recovery part 60G has a recovery port 61G, which is disposed around the third surface 23G and is oriented downward (i.e., in the −Z direction), and comprises a porous member 64G, which is disposed in the recovery port 61G. On the outer side of the recovery port 61G in radial directions with respect to the optical axis AX, the recovery part 60G does not have a surface (i.e., a wall) that extends downward (i.e., in the −Z direction) from the recovery port 61G. In the present embodiment, the porous member 64G is disposed in the recovery port 61G such that the lower surface of the porous member 64G and the third surface 23G are disposed substantially coplanarly. The recovery port 61G is connected to a liquid recovery apparatus 91G via a recovery passageway. The recovery passageway comprises an internal passageway 92G of a liquid immersion member 4G and a recovery pipe passageway, which connects the internal passageway 92G and the liquid recovery apparatus 91G. By the operation of the liquid recovery apparatus 91G, the liquid LQ from the third surface 23G that contacts the lower surface of the porous member 64G flows into the internal passageway 92G via the holes of the porous member 64G and is recovered by the liquid recovery apparatus 91G.

Furthermore, in the recovery part 60G shown in FIG. 13, the porous member 64G may be omitted.

### Fourth Embodiment

A fourth embodiment will now be explained. In the explanation below, constituent parts that are identical or equivalent to those in the embodiments discussed above are assigned identical symbols, and the explanations thereof are therefore abbreviated or omitted.

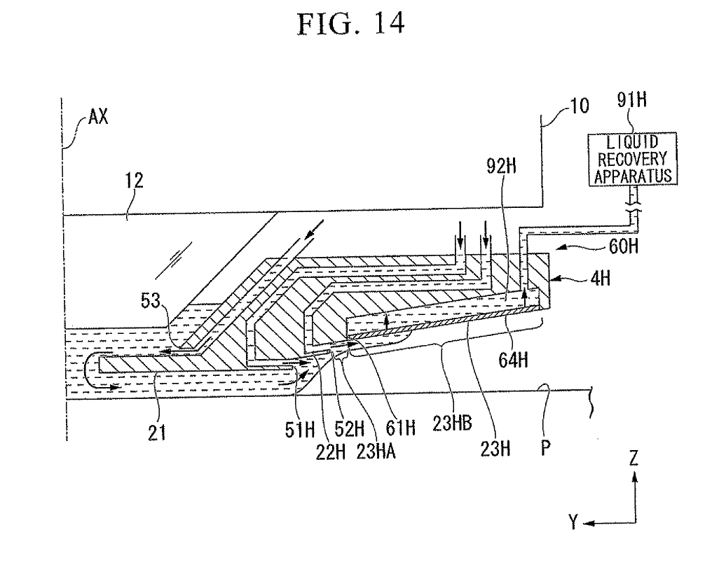

FIG. 14 is a view that shows one example of a liquid immersion member 4H according to the fourth embodiment. The first through third embodiments discussed above describe an exemplary case wherein the first surface 21, the second surface (22 and the like), and the third surface (23 and the like) are not capable of recovering the liquid LQ. In the fourth embodiment, a third surface 23H is capable of recovering the liquid LQ.

In the present embodiment, the liquid immersion member 4H has a first supply port 51H, which supplies the first liquid LQ1 to a second surface 22H, a second supply port 52H, which supplies the second liquid LQ2 to the third surface 23H, and a recovery part 60H, which recovers at least some of the liquid LQ on the third surface 23H.

The third surface 23H includes a lower surface of a porous member 64H. In the present embodiment, the third surface 23H includes a non-recovery surface 23HA, which is disposed on the outer side of the second supply port 52H in radial directions with respect to the optical axis AX, and a recovery surface 23HB, which includes the lower surface of the porous member 64H. In the present embodiment, the surface area of the recovery surface 23HB is greater than that of the non-recovery surface 23HA. Namely, the recovery surface 23HB is longer than the non-recovery surface 23HA in radial directions with respect to the optical axis AX. The recovery part 60H has a recovery port 61H, which is provided to the liquid immersion member 4H and is capable of recovering the liquid LQ. The porous member 64H is disposed in the recovery port 61H. The recovery port 61H is connected to a liquid recovery apparatus 91H via a recovery passageway. The recovery passageway comprises an internal passageway 92H of the liquid immersion member 4H and a recovery pipe passageway, which connects the internal passageway 92H and the liquid recovery apparatus 91H.

The lower surface of the porous member 64H is capable of opposing the front surface of the substrate P. The upper surface of the porous member 64H faces the internal passageway 92H.

Supplying the second liquid LQ2 via the second supply port 52H to the third surface 23H, which includes the lower surface of the porous member 64H, makes it possible to flow the liquid LQ onto the third surface 23H toward the outer side in radial directions with respect to the optical axis AX. In the present embodiment as well, it is possible to prevent the third liquid LQ3 from leaking out, remaining behind, and the like.

Furthermore, in the fourth embodiment, the suction force at the portion of the porous member 64H that is close to the second supply port 52H and the suction force at the portion that is far from the second supply port 52H may be made different (i.e., there may be a pressure differential between the upper surface and the lower surface of the porous member 64H) such that the flow of the liquid LQ (i.e., the liquid surface LQS) is generated with a prescribed length in radial directions with respect to the optical axis AX. For example, the suction force of the porous member 64H may be made stronger, in steps or continuously, toward the outer side in radial directions with respect to the optical axis AX.

Furthermore, in the fourth embodiment, the third surface 23H does not have to include the non-recovery surface 23HA.

Furthermore, in the second through fourth embodiments discussed above as well, the supply conditions of the first liquid LQ1 supplied via the first supply port (51 and the like) may be adjusted in accordance with the movement conditions of the object (i.e., the substrate P) below the liquid immersion member (4 and the like). In addition, the supply conditions of the second liquid LQ2 may be adjusted in accordance with the supply conditions of the first liquid LQ1.

In addition, in the first through fourth embodiments discussed above, the flow velocity of the first liquid LQ1 supplied via the first supply port (51 and the like) does not have to be the same in all radial directions with respect to the optical axis AX. Namely, the first liquid LQ1 may be supplied at a first flow speed in a first direction among radial directions with respect to the optical axis AX and at a second flow speed, which is different from the first flow speed, in a second direction.

In addition, in the first through fourth embodiments discussed above, the flow velocity of the second liquid LQ2 supplied via the second supply ports (53 and the like) does not have to be the same in all radial directions with respect to the optical axis AX. Namely, the second liquid LQ2 may be supplied at a third flow velocity in a third direction among radial directions with respect to the optical axis AX and at a fourth flow velocity, which is different from the third flow velocity, in a fourth direction.

### Fifth Embodiment

The following text explains a fifth embodiment. In the explanation below, constituent parts that are identical or equivalent to those in the embodiments discussed above are assigned identical symbols, and the explanations thereof are therefore abbreviated or omitted.

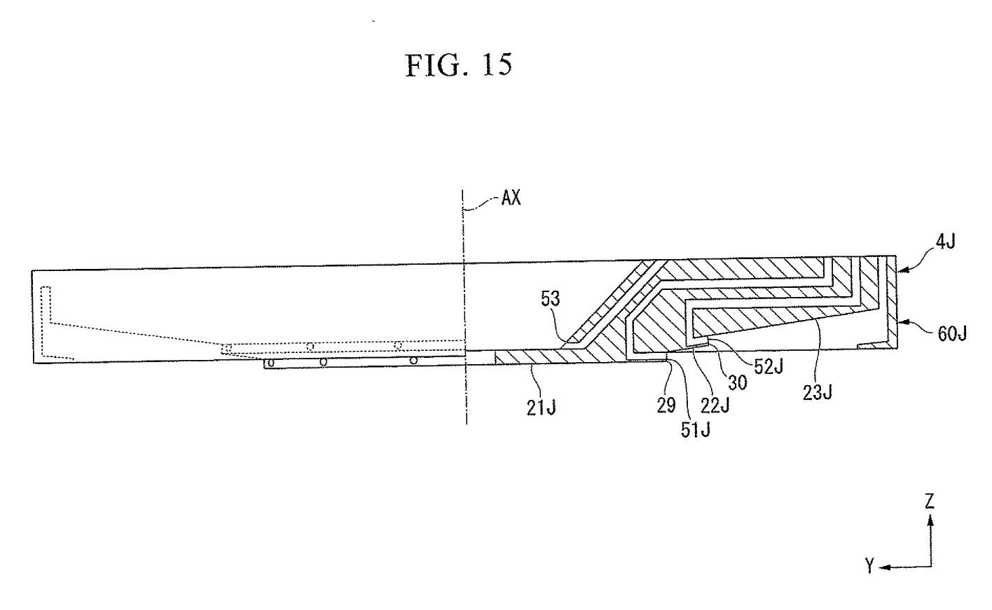

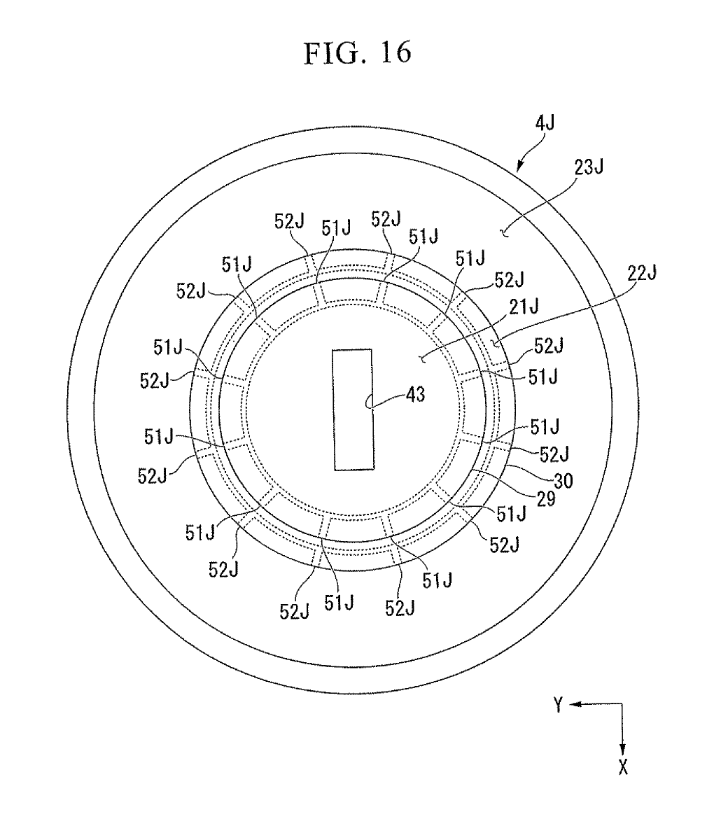

FIG. 15 is a side view that shows one example of a liquid immersion member 4J according to a fifth embodiment, wherein one part is shown in a cross sectional view. FIG. 16 shows the liquid immersion member 4J shown in FIG. 15, viewed from below.

In FIG. 15 and FIG. 16, the liquid immersion member 4J has a first surface 21J, a second surface 22J, a third surface 23J, a plurality of first supply ports 51J, which supply the first liquid LQ1 to the second surface 22J, a plurality of second supply ports 52J, which supply the second liquid LQ2 to the third surface 23J, and a recovery part 60J, which recovers at least some of the liquid LQ on the third surface 23J. In the present embodiment, the first supply ports 51J are disposed at prescribed intervals around the optical path of the exposure light EL. The second supply ports 52J are disposed at prescribed intervals around the optical path of the exposure light EL.

In the present embodiment, each of the first and second supply ports 51J, 52J is circular. Furthermore, each of the first and second supply ports 51J, 52J may have a shape other than a circle (e.g., a rectangle or slit shape). In addition, the shapes of the first and second supply ports 51J, 52J may differ from one another.

In the present embodiment, the liquid immersion member 4J has a ninth surface 29, which is disposed such that it faces the outer side in radial directions with respect to the optical axis AX, and a tenth surface 30, which is disposed such that it faces the outer side in radial directions with respect to the optical axis AX at a position spaced apart from the optical axis AX. The ninth surface 29 is formed between the outer side edge of the first surface 21J and the inner side edge of the second surface 22J. The tenth surface 30 is formed between the outer side edge of the second surface 22J and the inner side edge of the third surface 23J.

The first supply ports 51J are disposed at prescribed intervals in the ninth surface 29. The second supply ports 523 are disposed at prescribed intervals in the tenth surface 30. The second supply ports 52J are more spaced apart from the optical axis AX than the first supply ports 51J are.

In the present embodiment, the first supply ports 51J are disposed at the same positions as the second supply ports 52J in circumferential directions with respect to the optical axis AX.

Among the first supply ports 513, for example, the first supply ports 51J that face the −Y direction supply the first liquid LQ1 toward the −Y direction along prescribed radial directions with respect to the optical axis AX (i.e., Y axial directions), and the first supply ports 51J that face the +Y direction supply the first liquid LQ1 in the +Y direction along the Y axial directions. In addition, among the second supply ports 52J, for example, the second supply ports 52J that face the −Y direction supply the second liquid LQ2 toward the −Y direction along prescribed radial directions with respect to the optical axis AX (i.e., Y axial directions), and the second supply ports 52J that face the +Y direction supply the second liquid LQ2 toward the +Y direction along the Y axial directions.

In the present embodiment as well, it is possible to prevent the third liquid LQ3 from leaking out, remaining behind, and the like.

Furthermore, the positions of at least some of the first supply ports 51J may be different from the positions of the second supply ports 52J in circumferential directions with respect to the optical axis AX.

Furthermore, in the present embodiment as well, as in each of the embodiments discussed above, the supply conditions of the first liquid LQ1 supplied via the first supply ports 51J may be adjusted in accordance with the movement conditions of the object (i.e., the substrate P) below the liquid immersion member 4J, and the supply conditions of the second liquid LQ2 supplied via the second supply ports 52J may be adjusted in accordance with the supply conditions of the first liquid LQ1.

In addition, some of the first supply ports 51J of the plurality of first supply ports 51J may supply the first liquid LQ1 at a first flow velocity, while some of the other first supply ports 51J supply the first liquid LQ1 at a second flow velocity, which is different from the first flow velocity. Similarly, some of the second supply ports 52J of the plurality of second supply ports 52J may supply the second liquid LQ2 at a third flow velocity, while some of the other second supply ports 52J supply the second liquid LQ2 at a fourth flow velocity, which is different from the third flow velocity.

In addition, the supply of the first liquid LQ1 from some of the first supply ports 51J of the plurality of first supply ports 51J may be stopped. In addition, the flow velocities of the first liquid LQ1 supplied via the first supply ports 51J may differ from one another in accordance with the movement conditions (the movement velocity, the acceleration, the linear movement distance, the movement direction, and the like) of the substrate P. For example, if the substrate P moves in the −Y direction with respect to the optical path of the exposure light EL, then the supply of the first liquid LQ1 via the first supply ports 51J disposed on the +Y side with respect to the optical path of the exposure light EL may be stopped. Similarly, the supply of the second liquid LQ2 via some of the second supply ports 52J of the plurality of second supply ports 52J may be stopped. In addition, the flow velocities of the second liquid LQ2 supplied via the second supply ports 52J may differ from one another in accordance with the supply conditions of the first liquid LQ1.

In addition, in the present embodiment, the flow of the liquid LQ (i.e., the liquid surface LQS) does not have to be formed on the third surface 23 in all radial directions with respect to the optical axis AX. For example, the flow of the liquid LQ (i.e., the liquid surface LQS) may be formed only on opposite sides of the exposure light EL in the Y directions with respect to the optical path of the exposure light EL.

Furthermore, in the present embodiment, a plurality of the first supply ports 51J may be provided and just one of the second supply ports 52J may be provided and may be a slit opening as explained in the first embodiment. In addition, just one of the first supply ports 51J may be provided and may be a slit opening, and a plurality of the second supply ports 52J may be provided.

Furthermore, in each of the first through fifth embodiments discussed above, the flow velocity V1 of the first liquid LQ1 is lower than the flow velocity V2 of the second liquid LQ2, but may be equal to or higher than the flow velocity V2.

Furthermore, in the first through fifth embodiments discussed above, the second supply ports (52 and the like) face the outer side in radial directions with respect to the optical axis AX, but the orientation of the second supply ports (52 and the like) is not limited as long as the flow of the liquid LQ is formed on the third surface (23 and the like) in radial directions with respect to the optical axis AX.

In addition, in the first through fifth embodiments discussed above, the liquid surface LQS is formed by the flow of the liquid LQ on the third surface (23 and the like); however, in at least part of the third surface (23 and the like), a gas space may exist between the third surface (23 and the like) and the liquid LQ. Namely, the flow of the liquid LQ (i.e., the liquid surface LQS) toward the outer side in radial directions with respect to the optical axis AX should be formed on the outer side of the immersion space LS in radial directions with respect to the optical axis AX.

Furthermore, in the first through fifth embodiments discussed above, the first surface (21 and the like) is disposed partly around the optical path of the exposure light EL. In addition, the second surface (22 and the like) may be disposed partly around the first surface (21 and the like). In addition, the third surface (23 and the like) may be disposed partly around the second surface (22 and the like).

Furthermore, in each of the embodiments discussed above, at least part of the second surface (22 and the like) may be disposed below the first surface (21 and the like). In addition, at least part of the third surface (23 and the like) may be disposed below the first surface (21 and the like). For example, if the third surface 23C is inclined downward toward the outer side in radial directions, as with the liquid immersion member 4C shown in FIG. 9, then an edge (i.e., a circumferential edge area) on the outer side of the third surface 23C may be disposed below the first surface 21.

Furthermore, in each of the embodiments discussed above, the first supply port (51 and the like) is disposed above the second supply port (52 and the like).

Furthermore, in each of the embodiments discussed above, the first surface (21 and the like), the second surface (22 and the like), and the third surface (23 and the like) are substantially flat, but at least part of the second surface (22 and the like) may include a curved surface, and at least part of the third surface (23 and the like) may include a curved surface. In addition, at least part of the first surface (21 and the like) may include a curved surface. In addition, the first surface (21 and the like) may be inclined with respect to the XY plane. In addition, a groove that is long in radial directions (a groove that has a longitudinal axis along a radial direction) may be formed in the second surface (22 and the like), and a groove that is long in radial directions (a groove that has a longitudinal axis along a radial direction) may be formed in the third surface (23 and the like). In addition, the fourth surface 24 and the first surface (21 and the like) do not have to be parallel.

Furthermore, in each of the embodiments discussed above, the third supply ports 53 supply the second liquid LQ3 to the space between the emergent surface 11 and the fourth surface 24 of the plate part 41, but they may supply the third liquid LQ3 to the space between the side surface 12F and the inner side surface 44. In addition, the third supply ports 53 may be disposed such that they oppose the side surface 12F of the last optical element 12. Furthermore, in addition to or instead of the third supply ports 53, a supply port that supplies the third liquid LQ3 may be provided to the first surface (21 and the like).

Furthermore, in each of the embodiments discussed above, the plate part 41 may be omitted. For example, the first surface (21 and the like) may be provided at least partly around the emergent surface 11. In this case, the first surface (21 and the like) may be disposed at the same height as or above (i.e., on the +Z side of) the emergent surface 11.

Furthermore, in each of the embodiments discussed above, the liquid immersion member (4 and the like) may be capable of moving with respect to the projection optical system PL (i.e., the last optical element 12).

In addition, each of the embodiments discussed above explained an example wherein the first surface (21 and the like), the second surface (22 and the like), the third surface (23 and the like), the first supply port (51 and the like), and the second supply port (52 and the like) are disposed in the same liquid immersion member (4 and the like); however, the first surface (21 and the like) and the second surface (22 and the like) may be disposed in separate members, the second surface (22 and the like) and the third surface (23 and the like) may be disposed in separate members, the first surface (21 and the like) and the first supply port (51 and the like) may be disposed in separate members, the second surface (22 and the like) and the first supply port (51 and the like) may be disposed in separate members, the second surface (22 and the like) and the second supply port (52 and the like) may be disposed in separate members, and the third surface (23 and the like) and the second supply port (52 and the like) may be disposed in separate members. In addition, the member wherein the third surface (53 and the like) is disposed and the member wherein the recovery part (60 and the like) is disposed may be separate members. In such a case, at least some of the members of the plurality of members may be moveable with respect to the projection optical system PL (i.e., the last optical element 12).

Furthermore, in each of the embodiments discussed above, the immersion space LS is formed with the third liquid LQ3; however, the immersion space LS may be formed with the third liquid LQ3 in combination with the first liquid LQ1 or the second liquid LQ2, or both, by mixing at least some of the first liquid LQ1 and/or the second liquid LQ2 with the third liquid LQ3. In each of the embodiments discussed above, the first liquid LQ1, the second liquid LQ2, and the third liquid LQ3 are the same liquid, and therefore it does not matter whether the first liquid LQ1 or the second liquid LQ2, or both, is present in the optical path of the exposure light EL.

Furthermore, each of the embodiments discussed above explained exemplary cases wherein the first liquid LQ1, the second liquid LQ2, and the third liquid LQ3 are the same liquid, but they may be different liquids. For example, a liquid with prescribed physical properties suited to the exposure of the substrate P may be used as the third liquid LQ3, a liquid that is more lyophilic with respect to the second surface (22 and the like) than the third liquid LQ3 is may be used as the first liquid LQ1, and a liquid that is more lyophilic with respect to the third surface (23 and the like) than the third liquid LQ3 is may be used as the second liquid LQ2.

In addition, the first liquid LQ1 or the second liquid LQ2, or both, may have properties (e.g., the cleanliness level and the degree of transparency) that are inferior to those of the third liquid LQ3. In this case, it is preferable to dispose the first and second supply ports (51 and the like and 52 and the like) and to set supply conditions of the first and second liquids LQ1, LQ2 supplied via the first and second supply ports (51 and the like and 52 and the like) such that the first and second liquids LQ1, LQ2 supplied via the first and second supply ports (51 and the like and 52 and the like) do not mix with the third liquid LQ3 along the optical path of the exposure light EL.

Furthermore, in each of the embodiments discussed above, the temperature of the first liquid LQ1 supplied via the first supply port (51 and the like), the temperature of the second liquid LQ2 supplied via the second supply port (52 and the like), and the temperature of the third liquid LQ3 supplied via the third supply ports (53 and the like) are adjusted such that they are substantially the same; however, at least one temperature from the group of temperatures consisting of the temperature of the third liquid LQ3 supplied via the third supply ports (53 and the like), the temperature of the first liquid LQ1 supplied via the first supply port (51 and the like), and the temperature of the second liquid LQ2 supplied via the second supply port (52 and the like) may be different from the other temperatures. In addition, the temperature of the first liquid LQ1 and the temperature of the second liquid LQ2 may be different from one another. In addition, the temperature of the liquid immersion member (4 and the like) may be adjusted using the first and second liquids LQ1, LQ2 that flow through the internal passageway of the liquid immersion member (4 and the like).

Furthermore, in each of the embodiments discussed above, a gas supply port that supplies gas to the vicinity of the air-liquid interface LG of the third liquid LQ3 of the immersion space LS may be provided. For example, the gas may be supplied to the vicinity of the air-liquid interface LG via the gas supply port such that a gas seal is formed between the front surface of the substrate P and the third surface (23 and the like). The force of the gas supplied via the gas supply port prevents the immersion space LS from enlarging. Thereby, the force of the gas supplied via the gas supply port also prevents the third liquid LQ3 from leaking out, remaining behind, or the like.

Furthermore, in each of the embodiments discussed above, the optical path on the emergent (image plane) side of the last optical element 12 of the projection optical system PL is filled with the third liquid LQ3; however, it is possible to use a projection optical system wherein the optical path on the incident (object plane) side of the last optical element 12 is also filled with a liquid, as disclosed in, for example, PCT International Publication No. WO2004/019128. Furthermore, the liquid that fills the optical path on the incident side of the last optical element 12 may be the same type of liquid as the third liquid LQ3 or may be a different type.

Furthermore, in each of the embodiments discussed above, the first, second, and third liquids LQ1, LQ2, LQ3 are not limited to water (i.e., pure water); for example, it is also possible to use hydro-fluoro-ether (HFE), perfluorinated polyether (PFPE), Fomblin® oil, and the like.

The following text explains the embodiments of the present invention, referencing the drawings; however, the present invention is not limited thereto. The explanation below defines an XYZ orthogonal coordinate system, and the positional relationships among parts are explained referencing this system. Prescribed directions within the horizontal plane are the X axial directions, directions orthogonal to the X axial directions in the horizontal plane are the Y axial directions, and directions orthogonal to the X axial directions and the Y axial directions are the Z axial directions (i.e., the vertical directions). In addition, the rotational (i.e., inclinational) directions around the X, Y, and Z axes are the θX, θY, and θZ directions, respectively.

### Sixth Embodiment

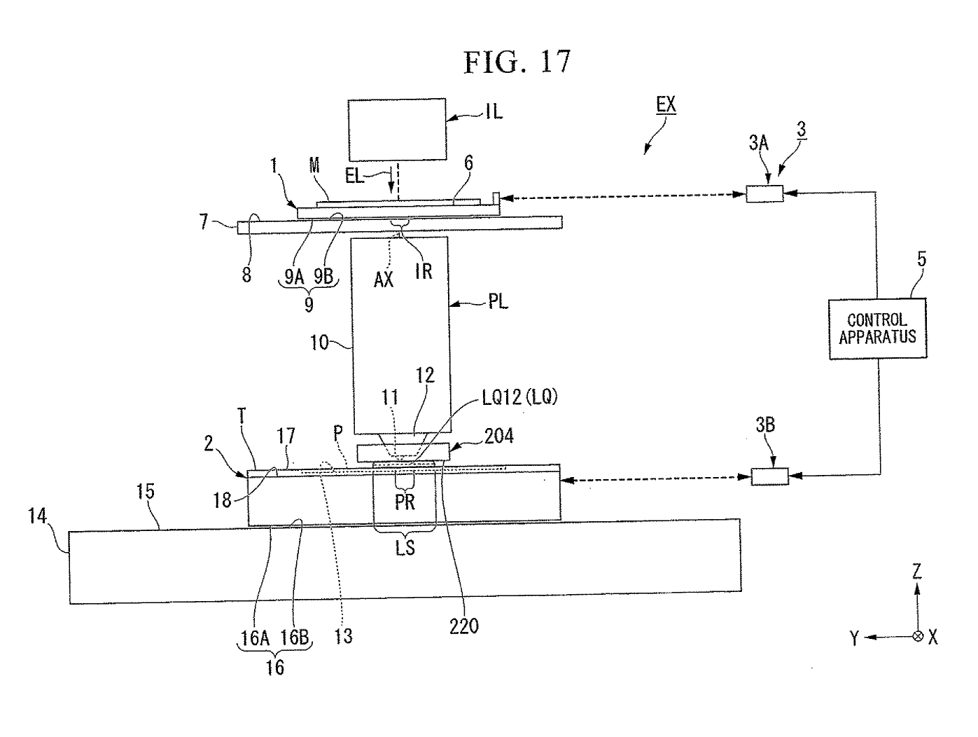

A sixth embodiment will now be explained. In the explanation below, constituent parts that are identical or equivalent to those in the embodiment discussed above are assigned identical symbols, and the explanations thereof are therefore abbreviated or omitted. FIG. 17 is a schematic block diagram that shows one example of an exposure apparatus EX according to the sixth embodiment. Furthermore, in the present embodiment as discussed below, a first liquid LQ11 and a second liquid LQ12 are used as the liquid, and the exposure light EL is radiated to the substrate P through the second liquid LQ12.

The liquid immersion member 204 is disposed at least partly around the optical path of the exposure light EL. In the present embodiment, at least part of the liquid immersion member 204 is disposed at least partly around the last optical element 12. The liquid immersion member 204 has a lower surface 220 that is capable of opposing a front surface of an object, which is disposed at a position at which it opposes the emergent surface 11. The liquid immersion member 204 forms the immersion space LS such that the optical path of the exposure light EL between the emergent surface 11 and the object, which is disposed at a position at which it opposes the emergent surface 11, is filled with the second liquid LQ12. The second liquid LQ12 is held between at least part of the lower surface 220 and the front surface (i.e., the upper surface) of the object, and the immersion space LS is thereby formed.

The immersion space LS is a portion (i.e., a space or an area) that is tilled with the second liquid LQ12. In the present embodiment, the object includes the substrate stage 2 (i.e., the plate member T) or the substrate P, which is held by the substrate stage 2, or both. During at least part of an exposure of the substrate P, the liquid immersion member 204 forms the immersion space LS such that the optical path of the exposure light EL between the last optical element 12 and the substrate P is filled with the second liquid LQ12.

The exposure apparatus EX of the present embodiment is a scanning type exposure apparatus (i.e., a so-called scanning stepper) that projects the image of the pattern of the mask M to the substrate P while synchronously moving the mask M and the substrate P in prescribed scanning directions. When the substrate P is to be exposed, the control apparatus 5 controls the mask stage 1 and the substrate stage 2 so as to move the mask M and the substrate P in the prescribed scanning directions within the XY plane that intersects the optical axis AX (i.e., the optical path of the exposure light EL). In the present embodiment, the scanning directions (i.e., the synchronous movement directions) of both the substrate P and the mask M are the Y axial directions. The control apparatus 5 radiates the exposure light EL to the substrate P through the projection optical system PL and the second liquid LQ12 of the immersion space LS on the substrate P while both moving the substrate P in one of the Y axial directions with respect to the projection area PR of the projection optical system PL and moving the mask M in the other Y axial direction with respect to the illumination area IR of the illumination system IL synchronized to the movement of the substrate P. Thereby, the image of the pattern of the mask M is projected to the substrate P, which is thereby exposed by the exposure light EL.

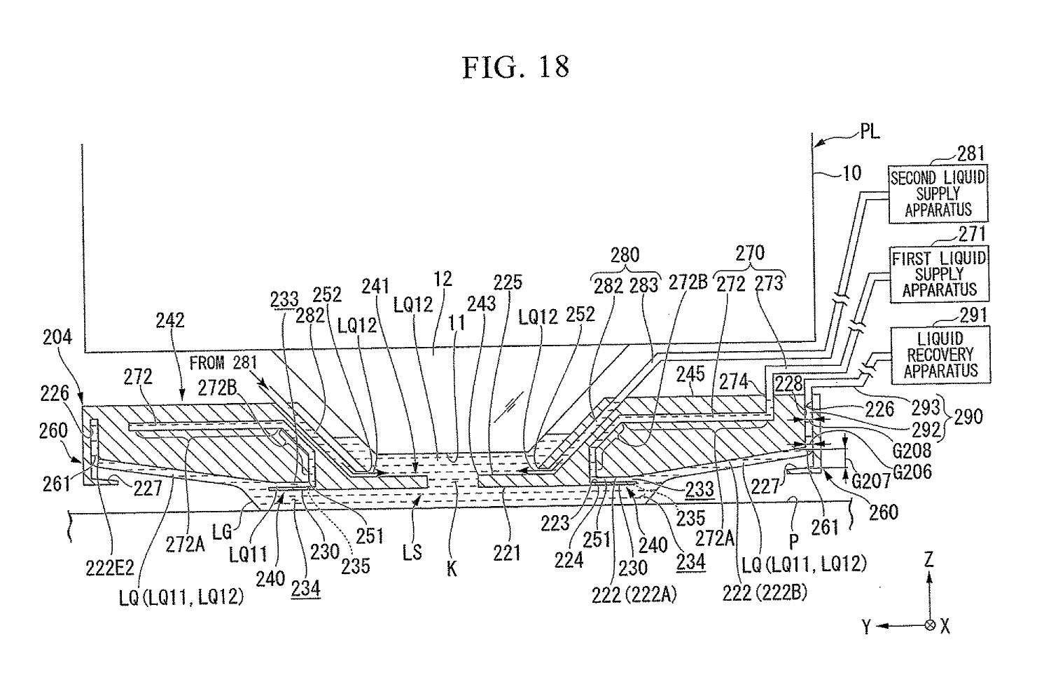

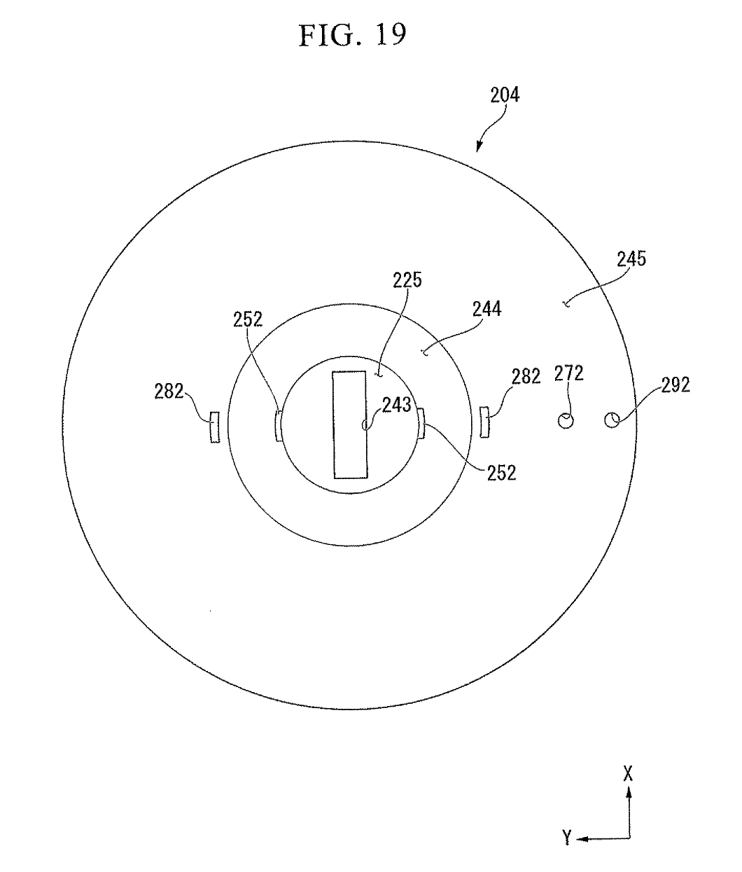

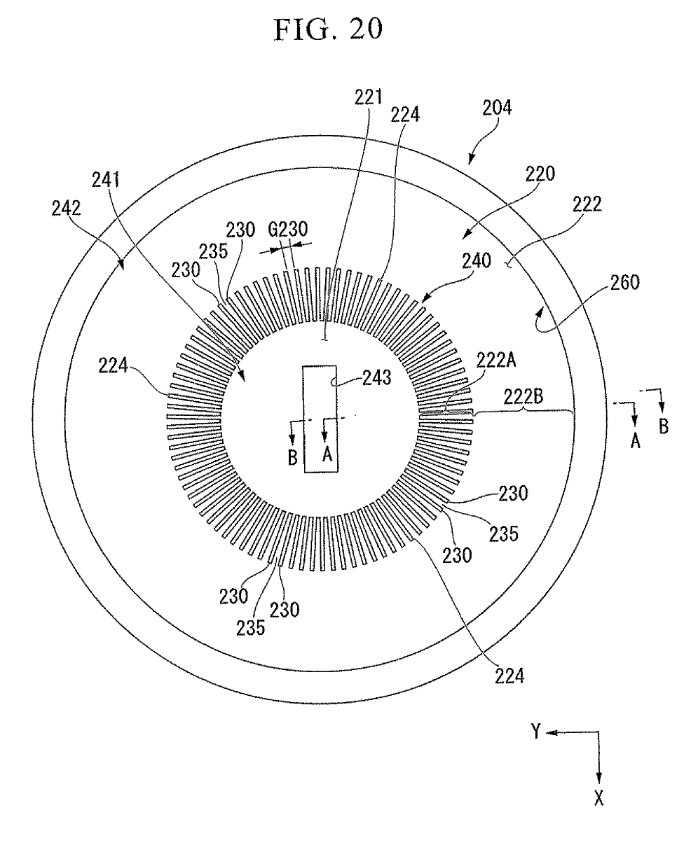

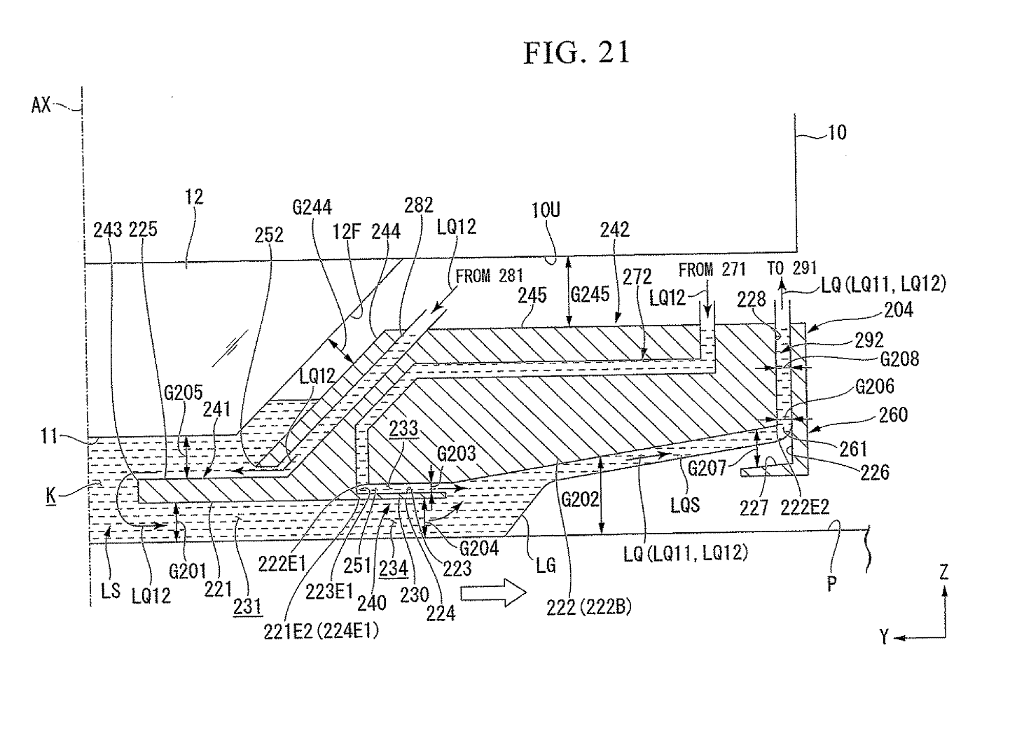

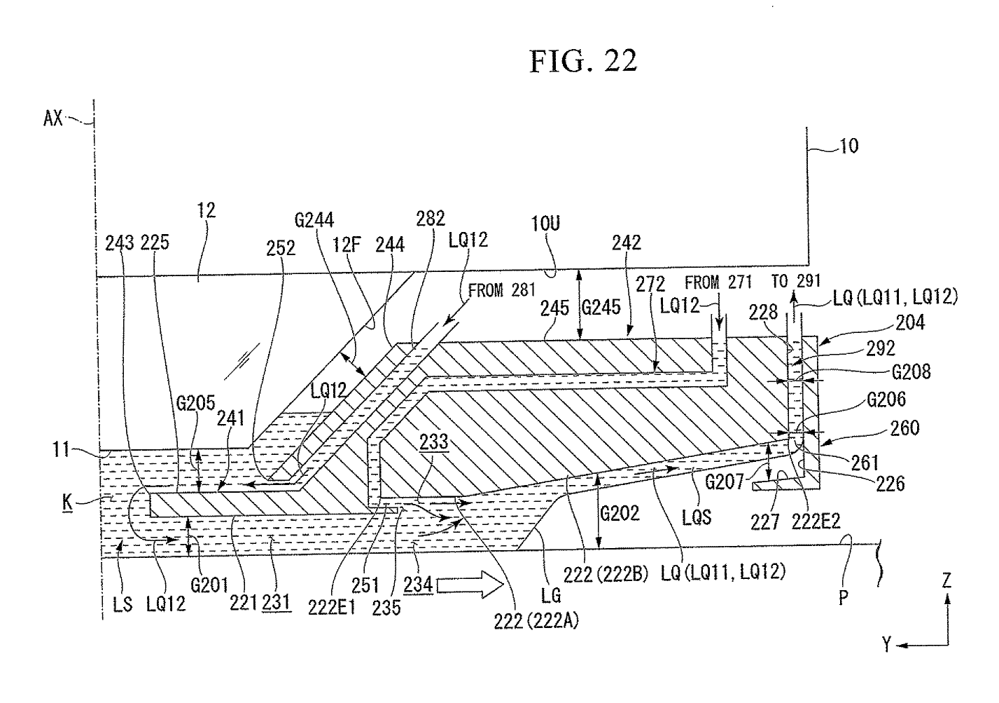

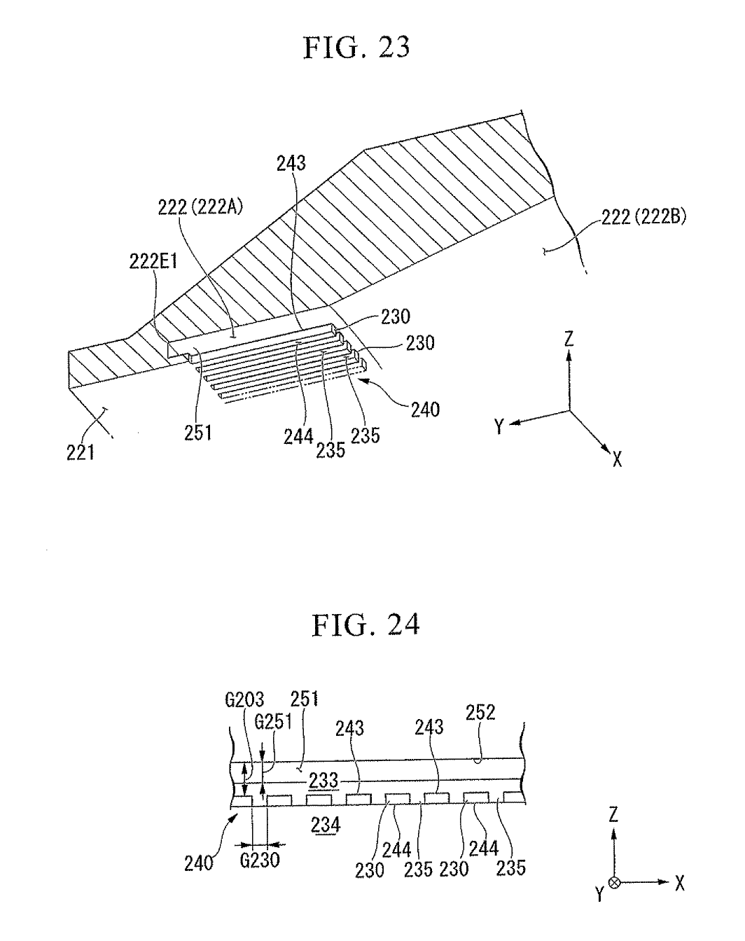

The following text explains the liquid immersion member 204, referencing FIG. 18 through FIG. 24. FIG. 18 is a side cross sectional view that shows the vicinity of the liquid immersion member 204, FIG. 19 shows the liquid immersion member 204, viewed from above, FIG. 20 shows the liquid immersion member 204, viewed from below, FIG. 21 and FIG. 22 are side cross sectional views that show part of the liquid immersion member 204, FIG. 23 shows part of the liquid immersion member 204, viewed from below, and FIG. 24 is a side view that shows part of the liquid immersion member 204. FIG. 21 is a cross sectional view taken along the A-A line in FIG. 20, and FIG. 22 is a cross sectional view taken along the B-B line in FIG. 20.

In the present embodiment, the exposure light EL advances along the Z axis. In the explanation below, the direction in which the exposure light EL advances is called a first direction where appropriate, and the direction that is the reverse of the first direction is called a second direction where appropriate. In the present embodiment, the first direction is the −Z direction and the second direction is the +Z direction. In the present embodiment, the optical path of the exposure light EL is substantially parallel to the Z axis.

In the present embodiment, the liquid immersion member 204 is an annular member. At least part of the liquid immersion member 204 is disposed around part of the optical path of the exposure light EL and around the last optical element 12. As shown in FIG. 19 and FIG. 20, in the present embodiment, the external shape of the liquid immersion member 204 within the XY plane is a circle. Furthermore, the external shape of the liquid immersion member 204 may be some other shape (e.g., a rectangle).

In the present embodiment, the liquid immersion member 204 comprises a plate part 241, at least part of which is disposed such that it opposes the emergent surface 11, a main body part 242, at least part of which is disposed around the last optical element 12, and a comb part 240, which is disposed at least partly around the plate part 241.

The liquid immersion member 204 comprises: a first surface 221, which is disposed at least partly around an optical path K of the exposure light EL that emerges from the emergent surface 11 of the projection optical system PL; a second surface 222, which is disposed at least partly around the first surface 221; rod members 230 that each have a third surface 223 and a fourth surface 224, which faces a direction opposite that of the third surface 223 and that is disposed such that the third surface 223 opposes the second surface 222; a first supply port 251, which supplies the first liquid LQ11 and is disposed at least partly around the first surface 221 such that the first supply port 251 faces the outer side in radial directions (is directed to an outward radial direction) with respect to the optical axis AX of the projection optical system PL (i.e., the optical path of the exposure light EL); and passageways 235, which are provided both such that they connect a space 233 that the third surfaces 223 face and a space 234 that the fourth surfaces 224 face and such that at least some of the first liquid LQ11 that is supplied via the first supply port 251 to the space 233 flows to the space 234. In the present embodiment, the lower surface 220 of the liquid immersion member 204 has the first surface 221, the second surface 222, and the fourth surfaces 224.

The emergent surface 11, the first surface 221, the second surface 222, and the fourth surfaces 224 are capable of opposing the front surface (i.e., the upper surface) of the object (i.e., the substrate P and the plate member T) disposed below the liquid immersion member 204. The first surface 221 is capable of opposing the front surface of the object across a gap G201. The second surface 222 is capable of opposing the front surface of the object across a gap G202. The fourth surfaces 224 are capable of opposing the front surface of the object across a gap G204.

The third surfaces 223 oppose the second surface 222 across a gap G203. The space 233 includes the gap G203. The space 234 includes the gap G204. In the present embodiment, the gap G203 is smaller than the gaps G201, G204.

In addition, in the present embodiment, the liquid immersion member 204 has second supply ports 252, which supply the second liquid LQ12 to the optical path K of the exposure light EL that emerges from the emergent surface 11.

In the present embodiment, the first liquid LQ11 and the second liquid LQ12 are the same type of liquid. In the present embodiment, water (i.e., pure water) is used for the first liquid LQ11 and the second liquid LQ12. In the explanation below, the first liquid LQ11 and the second liquid LQ12 are generically called a liquid LQ where appropriate.

In the present embodiment, the first surface 221 is disposed around the optical path K of the exposure light EL that emerges from the emergent surface 11. The second surface 222 is disposed around the first surface 221. In the present embodiment, the external shapes of the first surface 221 and the second surface 222 within the XY plane are circles. In addition, an inner side edge 222E1 of the second surface 222 within the XY plane is also circular. In the present embodiment, at least part of the first surface 221 is disposed on the plate part 241 and the second surface 222 is disposed on the main body part 242.

The rod members 230 are disposed at least partly around the first surface 221. The rod members 230 are disposed at prescribed intervals at least partly around the first surface 221. In the present embodiment, the rod members 230 are disposed equispaced around the first surface 221. Furthermore, the rod members 230 may be disposed unequally spaced around the first surface 221.

The comb part 240 comprises the plurality of the rod members 230. Namely, the plurality of the rod members 230 forms a so-called comb structure. The rod members 230 are long in radial directions (or has a longitudinal axis along a radial direction) with respect to the optical axis AX.

In the present embodiment, the passageways 235 are gaps G230 between adjacent rod members 230. The gaps G230 are long in radial directions (or has a longitudinal axis along a radial direction) with respect to the optical axis AX. At least some of the first liquid LQ11 supplied via the first supply port 251 to the space 233 flows via the gaps G230 to the space 234.

In the present embodiment, as shown in FIG. 20, the sizes of the gaps G230 are substantially uniform in radial directions with respect to the optical axis AX.

In the present embodiment, the sizes of the rod members 230 are smaller than the size of the second surface 222 in radial directions with respect to the optical axis AX. The second surface 222 includes a first area 222A, which surrounds the optical axis AX, and a second area 222B, which surrounds the first area 222A. The first area 222A is annular (i.e., zonal). The third surfaces 223 (i.e., the rod members 230) oppose the first area 222A.

In addition, the liquid immersion member 204 has a fifth surface 225, which faces a direction opposite that of the first surface 221 and is disposed at least partly around the optical path K of the exposure light EL such that at least part of the fifth surface 225 opposes the emergent surface 11. In the present embodiment, the fifth surface 225 is disposed around the optical path K. The fifth surface 225 is disposed on the plate part 241. The fifth surface 225 opposes the emergent surface 11 across a gap G205.

The plate part 241 of the liquid immersion member 204 has an opening 243 wherethrough the exposure light EL that emerges from the emergent surface 11 can pass. The first surface 221 and the fifth surface 225 are disposed around the opening 243. During an exposure of the substrate P, the exposure light EL that emerges from the emergent surface 11 is radiated to the front surface of the substrate P through the opening 243. As shown in FIG. 19 and FIG. 20, in the present embodiment, the opening 243 is long in the X axial directions, which intersect the scanning directions of the substrate P (i.e., the Y axial directions).

During at least part of the exposure of the substrate P, the emergent surface 11, the first surface 221, the second surface 222, and the fourth surfaces 224 oppose the front surface of the substrate P. Furthermore, the state wherein the first surface 221 and the front surface of the substrate P are opposed includes the state wherein the second liquid LQ12 is present between the first surface 221 and the front surface of the substrate P. In addition, the state wherein the second surface 222 and the substrate P are opposed includes the state wherein the flow of the liquid LQ (i.e., a liquid surface LQS discussed below) is generated between the second surface 222 and the substrate P.

In the present embodiment, the second surface 222 is disposed in the second direction (i.e., the +Z direction) more than the first surface 221 is. In the present embodiment, the gap G202 is larger than the gap G201.

In the present embodiment, the first surface 221 is substantially parallel to the XY plane. At least part of the second surface 222 is inclined in the second direction (i.e., the +Z direction) toward the outer side in radial directions with respect to the optical axis AX. Namely, the second surface 222 is inclined with respect to the first surface 221. In addition, the fifth surface 225 is substantially parallel to the first surface 221. In the present embodiment, the fifth surface 225 and the emergent surface 11 are substantially parallel.

In the present embodiment, the third surfaces 223 are substantially parallel to the XY plane. In addition, in the present embodiment, the third surfaces 223 and the first area 222A of the second surface 222 are substantially parallel. In the present embodiment, the second area 222B is inclined in the second direction (i.e., the +Z direction) toward the outer side in radial directions with respect to the optical axis AX.

The main body part 242 of the liquid immersion member 204 has: an inner side surface 244, which opposes at least part of a side surface 12F of the last optical element 12 across a gap G244; and an upper surface 245, which opposes a lower surface 10U of the holding member 10 across a gap G245. The side surface 12F differs from the emergent surface 11 and is wherethrough the exposure light EL does not pass. The side surface 12F is disposed around the emergent surface 11. Furthermore, at least part of the inner side surface 244 may oppose part of the holding member 10. Alternatively, at least part of the upper surface 245 may oppose part of the last optical element 12.

In the present embodiment, an outer side edge 221E2, which defines the external shape of the first surface 221, and inner side edges 224E1 of the fourth surfaces 224 are connected. In addition, in the present embodiment, the first surface 221 and the fourth surfaces 224 are disposed substantially within the same plane. Namely, in the present embodiment, the fourth surfaces 224 are substantially parallel to the XY plane.

In the present embodiment, at least part of the first supply port 251 is disposed between the inner side edge 222E1 of the second surface 222 and inner side edges 223E1 of the third surfaces 223. At least some of the first liquid LQ11 supplied via the first supply port 251 is supplied to the space between the second surface 222 and the third surfaces 223. In addition, at least some of the first liquid LQ11 supplied via the first supply port 251 is supplied via the passageways 235 (i.e., the gaps G230) to the space between the fourth surfaces 224 and the front surface of the object (i.e., the substrate P).

The first supply port 251 supplies the first liquid LQ11 such that the first liquid LQ11 flows on the second surface 222 toward the outer side in radial directions with respect to the optical axis AX. The first supply port 251 supplies the first liquid LQ11 such that the first liquid LQ11 flows along the second surface 222 toward the outer side in radial directions with respect to the optical axis AX while contacting the second surface 222.

As shown in FIG. 24 and the like, in the present embodiment, the first supply port 251 is a slit opening formed such that it surrounds the optical axis AX. The first supply port 251 is disposed such that it follows along the edge 222E1 on the inner side of the second surface 222. A size G251 (i.e., a slit width) of the first supply port 251 in the Z axial directions is sufficiently small. The size G251 of the first supply port 251 is smaller than the gap G203. The size G251 of the first supply port 251 is smaller than, for example, the gap G201 during an exposure of the substrate P.

The second supply ports 252 supply the second liquid LQ12 to a gap between the liquid immersion member 204 and the last optical element 12. In the present embodiment, the second supply ports 252 are disposed at prescribed regions of the liquid immersion member 204 such that they face the optical path K of the exposure light EL that emerges from the emergent surface 11. In the present embodiment, the second supply ports 252 supply the second liquid LQ12 to the space between the emergent surface 11 and the fifth surface 225. In the present embodiment, the second supply ports 252 are disposed in the inner side surface 244. As shown in FIG. 19, in the present embodiment, the second supply ports 252 are disposed on the +Y and −Y sides of the opening 243 (i.e., the optical path K of the exposure light EL), one on each side. Furthermore, the second supply ports 252 may be disposed on the +X and −X sides of the opening 243 (i.e., the optical path K of the exposure light EL). In addition, the number of the second supply ports 252 is not limited to two. The second supply ports 252 may be disposed at three or more positions around the optical path of the exposure light EL.

The second liquid LQ12 supplied via the second supply ports 252 is supplied to the optical path K of the exposure light EL that emerges from the emergent surface 11. Thereby, the optical path K of the exposure light EL is filled with the second liquid LQ12. In addition, during at least part of the exposure of the substrate P, the front surface of the substrate P opposes the emergent surface 11, the first surface 221, the second surface 222, and the fourth surfaces 224. During at least part of the exposure of the substrate P, at least some of the second liquid LQ12 supplied via the second supply ports 252 to a space between the emergent surface 11 and the fifth surface 225 is supplied via the opening 243 to a space 231 between the first surface 221 and the front surface of the substrate P, and thereby the optical path K of the exposure light EL between the emergent surface 11 and the front surface of the substrate P is filled with the second liquid LQ12. In addition, at least some of the second liquid LQ12 is held between the first surface 221 and the front surface of the substrate P. The substrate P is exposed with the exposure light EL that emerges from the emergent surface 11 and transits the second liquid LQ12 between the emergent surface 11 and the front surface of the substrate P.

In the present embodiment, part of the immersion space LS is formed from the second liquid LQ12 held between the first surface 221 and the object. In the present embodiment, when the substrate P is irradiated with the exposure light EL, the immersion space LS is already formed such that part of the area of the front surface of the substrate P that includes the projection area PR is covered with the second liquid LQ12. The exposure apparatus EX of the present embodiment adopts a local liquid immersion system.

For the sake of simplicity, the following text explains an exemplary case wherein the substrate P is disposed at a position at which it opposes the lower surface 220 of the liquid immersion member 204 and the second liquid LQ12 is held between the liquid immersion member 204 and the substrate P; thereby the immersion space LS is formed. Furthermore, as discussed above, the immersion space LS can be formed between the emergent surface 11 and the liquid immersion member 204 on one side and another member (e.g., the plate member T of the substrate stage 2) on the other side.

In the present embodiment, the immersion space LS is formed between at least part of the emergent surface 11 and the lower surface 221 on one side and the front surface of the substrate P on the other side with at least some of the second liquid LQ12 supplied via the second supply ports 252 such that the optical path K of the exposure light EL between the emergent surface 11 and the substrate P is filled with the second liquid LQ12.

In FIG. 18, FIG. 21, and FIG. 22, an air-liquid interface LG (i.e., a meniscus or an edge) of the second liquid LQ12 of the immersion space LS is formed between the second surface 222 and the front surface of the substrate P. The first supply port 251, the passageways 235, the space 233, and the space 234 are disposed in the immersion space LS. Namely, the immersion space LS is formed such that the first supply port 251, the passageways 235, the space 233, and the space 234 contact the second liquid LQ12 of the immersion space LS formed with the second liquid LQ12 supplied via the second supply ports 252. In FIG. 18, FIG. 21, and FIG. 22, the first liquid LQ11 is supplied via the first supply port 251 to the second surface 222 in the state wherein the first supply port 251 is immersed in the second liquid LQ12 of the immersion space LS. Namely, in the present embodiment, the first supply port 251 supplies the first liquid LQ11 in a state wherein the first supply port 251 is disposed in the immersion space LS.

In the present embodiment, the supplying of the first liquid LQ11 via the first supply port 251 and the supplying of the second liquid LQ12 via the second supply ports 252 are performed in parallel. Namely, the first liquid LQ11 is supplied via the first supply port 251 to the second surface 222 in the state wherein the immersion space LS of the second liquid LQ12 is formed, and the first liquid LQ11 supplied via the first supply port 251 flows on the second surface 222 toward the outer side in radial directions with respect to the optical axis AX. In addition, at least some of the second liquid LQ12 of the immersion space LS flows, together with the first liquid LQ11 supplied via the first supply port 251, on the second surface 222 toward the outer side in radial directions with respect to the optical axis AX. Thereby, on the outer side of the interface LG of the immersion space LS in radial directions with respect to the optical axis AX, the liquid LQ (i.e., the first liquid LQ11 or the second liquid LQ12, or both) flows on the second surface 222 toward the outer side in radial directions with respect to the optical axis AX without contacting the front surface of the substrate P (i.e., the object). Namely, on the outer side of the interface LG of the immersion space LS in radial directions with respect to the optical axis AX, a gas space exists between the surface of the liquid LQ (i.e., the liquid surface LQS) that flows on the second surface 222 and the front surface of the substrate P (i.e., the object) that opposes such.

At least some of the first liquid LQ11 supplied via the first supply port 251 flows via the passageways 235 to the space 234 between the fourth surfaces 224 (i.e., the comb part 240) and the substrate P. In addition, at least some of the second liquid LQ12 that is supplied via the second supply ports 252 and flows via the opening 243 to the space 231, which is faced by the first surface 221, flows via the space 231 to the space 234, which is faced by the fourth surfaces 224.

In the present embodiment, a flow velocity of the first liquid LQ11 supplied via the first supply port 251 is higher than a flow velocity of the second liquid LQ12 supplied via the second supply ports 252.

In the present embodiment, the flow velocity of the first liquid LQ11 that flows from the passageways 235 to the space 234 is higher than the flow velocity of the second liquid LQ12 that flows from the space 231 to the space 234.

In addition, in the present embodiment, during at least part of the exposure of the substrate P, the substrate P moves in a prescribed direction within the XY plane, which is substantially parallel to the emergent surface 11 (i.e., the first surface 221), in the state wherein the immersion space LS is formed. For example, during an exposure of a shot region on the substrate P, the substrate P moves in the Y axial directions; furthermore, when the substrate P is stepped from an exposure end position of the current shot region to an exposure start position of the next shot region, the substrate P moves in, for example, the X axial directions. In the present embodiment, the flow velocity of the first liquid LQ11 supplied via the first supply port 251 substantially parallel to the movement direction (i.e., a prescribed direction) of the substrate P is higher than a movement velocity of the substrate P in the prescribed direction.

The second surface 222 is preferably lyophilic with respect to the first liquid LQ11. In the present embodiment, the contact angle of the first liquid LQ11 with respect to the second surface 222 is less than 90°. In the present embodiment, the second surface 222 is made of titanium and is lyophilic (i.e., hydrophilic) with respect to the first liquid LQ11. In the present embodiment, the second surface 222 is preferably more lyophilic than the front surface of the object (e.g., the substrate P) that opposes the second surface 222. Furthermore, a film formed from a material that is lyophilic with respect to the first liquid LQ11 may be disposed on at least part of the lower surface 220 of the liquid immersion member 204, and the second surface 222 may be made lyophilic with respect to the first liquid LQ11. In addition, the second surface 222 does not have to be lyophilic with respect to the first liquid LQ11.

In addition, the liquid immersion member 204 comprises a recovery part 260, which is disposed on the outer side of the second surface 222 in radial directions with respect to the optical axis AX and recovers at least some of the liquid LQ (i.e., the first liquid LQ11 or the second liquid LQ12, or both) on the second surface 222. The recovery part 260 is capable of recovering the first liquid LQ11, which is supplied via the first supply port 251 and flows on the second surface 222, and the second liquid LQ12, which flows on the second surface 222 together with the first liquid LQ11.

In the present embodiment, the recovery part 260 has a sixth surface 226, which is disposed such that it intersects the second surface 222. A gap G206 is formed between an outer side edge 222E2 of the second surface 222 and the sixth surface 226. The recovery part 260 recovers at least some of the liquid LQ that flows from the second surface 222 into the gap G206.

In addition, in the present embodiment, at least part of the sixth surface 226 is disposed more in the first direction (i.e., the −Z direction) than the outer side edge 222E2 of the second surface 222 such that at least part of the sixth surface 226 faces the optical axis AX. In the present embodiment, the sixth surface 226 is disposed substantially parallel to the optical axis AX.

In addition, in the present embodiment, the recovery part 260 has a seventh surface 227, which is connected to a lower end of the sixth surface 226 and is disposed such that the seventh surface 227 opposes a circumferential edge area of the second surface 222 across a gap G207. The seventh surface 227 is disposed below the circumferential edge area of the second surface 222 such that the seventh surface 227 faces in the second direction (i.e., the +Z direction).

In the present embodiment, the sixth surface 226 is disposed annularly around the first surface 222. In addition, the seventh surface 227 is annular within the XY plane.

In the present embodiment, the gap G206 between the outer side edge 222E2 of the second surface 222 and the sixth surface 226 comprises a recovery port 261 of the recovery part 260 that is capable of recovering at least some of the liquid LQ on the second surface 222. In the present embodiment, the recovery port 261 is annular within the XY plane. Furthermore, multiple recovery ports 261 may be disposed within the XY plane at prescribed intervals around the optical path K of the exposure light EL. Furthermore, in the present embodiment, the seventh surface 227, which prevents the liquid LQ from falling from the vicinity of the recovery port 261 onto the front surface of the substrate P (i.e., the object), is provided, but the seventh surface 227 may be omitted.

As shown in FIG. 18, the first supply port 251 is connected to a first liquid supply apparatus 271 via supply a passageway 270. The supply passageway 270 comprises an internal passageway 272 of the liquid immersion member 204 and a supply pipe passageway 273, which connects the internal passageway 272 and the first liquid supply apparatus 271. The first liquid supply apparatus 271 can supply the first liquid LQ11, which is clean and temperature adjusted, to the first supply port 251.

In the present embodiment, an inflow port 274 of the internal passageway 272 is disposed in the upper surface 245 of the liquid immersion member 204. The first liquid LQ11 supplied from the first liquid supply apparatus 271 flows into the internal passageway 272 via the inflow port 274. The internal passageway 272 has a first portion 272A, which extends from the inflow port 274 toward the inner side in radial directions, and a second portion 272B, which is at least partly bent and connects the first portion 272A and the first supply port 251. A lower end of the second portion 272B extends toward the outer side in radial directions with respect to the optical axis AX. In the present embodiment, the internal passageway 272, which comprises the first portion 272A and the second portion 272B, is formed such that it surrounds the optical axis AX.

The first liquid LQ11 that flows from the inflow port 274 into the internal passageway 272 spreads and flows in the first portion 272A such that the first liquid LQ11 surrounds the optical axis AX and is supplied to the first supply port 251 via the second portion 272B. The first supply port 251 supplies the first liquid LQ11 from the second portion 272B to the second surface 222 such that the first liquid LQ11 flows on the second surface 222 toward the outer side in radial directions. The first supply port 251 supplies the first liquid LQ11 to the second surface 222 such that substantially the entire area of the second surface 222 is wetted with the first liquid LQ11.

In addition, as shown in FIG. 18, the second supply ports 252 are connected to a second liquid supply apparatus 281 via supply passageways 280. Each of the supply passageways 280 comprises an internal passageway 282 of the liquid immersion member 204 and a supply pipe passageway 283, which connects the internal passageway 282 and the second liquid supply apparatus 281. The second liquid supply apparatus 281 can supply the second liquid LQ12, which is clean and temperature adjusted, to the second supply ports 252.

In addition, as shown in FIG. 18, the recovery port 261 is connected to a liquid recovery apparatus 291 via a recovery passageway 290. In the present embodiment, the recovery passageway 290 comprises an internal passageway 292 of the liquid immersion member 204 and a recovery pipe passageway 293, which connects the internal passageway 292 and the liquid recovery apparatus 291. At least part of the internal passageway 292 is formed between the sixth surface 226 and an eighth surface 228, which opposes the sixth surface 226 across a gap G208. The liquid recovery apparatus 291 comprises a vacuum system (such as a valve that controls the connection state between a vacuum source and the recovery port 261) and is capable of recovering the liquid LQ via the recovery port 261 by suctioning the liquid LQ.

The following text explains a method of using the exposure apparatus EX that has the abovementioned configuration to expose the substrate P.

The control apparatus 5 causes the first surface 221, the second surface 222, and the fourth surfaces 224 on one side and the front surface of the substrate P (or the upper surface 17 of the substrate stage 2) on the other side to oppose one another. The first surface 221 and the front surface of the substrate P oppose one another across the gap G201, the second surface 222 and the front surface of the substrate P oppose one another across the gap G202, and the fourth surfaces 224 and the front surface of the substrate P oppose one another across the gap G204.

The control apparatus 5 supplies the second liquid LQ12 from the second liquid supply apparatus 281 in the state wherein the first surface 221, the second surface 222, and the fourth surfaces 224 on one side and the front surface of the substrate P on the other side are caused to oppose one another.

The second liquid LQ12 supplied from the second liquid supply apparatus 281 is supplied via the second supply ports 252 to the space between the emergent surface 11 and the fifth surface 225 and is supplied to the optical path K of the exposure light EL that emerges from the emergent surface 11. Thereby, the optical path K of the exposure light EL is filled with the liquid LQ.

In addition, at least some of the second liquid LQ12 supplied via the second supply ports 252 is supplied via the opening 243 to the space 231 between the first surface 221 and the front surface of the substrate P and is held therebetween. In addition, at least some of the second liquid LQ12 of the space 231 flows to the space 234, which is faced by the fourth surfaces 224, and is held between the second surface 222 and the fourth surfaces 224 on one side and the front surface of the substrate P on the other side. Thereby, the second liquid LQ12 supplied via the second supply ports 252 forms the immersion space LS between the fourth surfaces 224 and at least part of the emergent surface 11, the first surface 221, and the second surface 222 on one side and the front surface of the substrate P on the other side such that the optical path K of the exposure light EL between the emergent surface 11 and the substrate P is filled with the second liquid LQI2.

In addition, the control apparatus 5 supplies the first liquid LQ11 from the first liquid supply apparatus 271. In addition, the control apparatus 5 operates the liquid recovery apparatus 291. The first liquid LQ11 supplied from the first liquid supply apparatus 271 is supplied to the first supply port 251 via the supply passageway 270. The first supply port 251 supplies the first liquid LQ11 to the space 233, which is faced by the third surfaces 223. At least some of the first liquid LQ11 supplied via the first supply port 251 to the space 233 is supplied via the space 233 to the second surface 222. In addition, at least some of the first liquid LQ11 supplied to the space 233 flows via the passageways 235 to the space 234, which is faced by the fourth surfaces 224.

The control apparatus 5 controls the first liquid supply apparatus 271 and the second liquid supply apparatus 281 such that the supplying of the first liquid LQ11 via the first supply port 251 and the supplying of the second liquid LQ12 via the second supply ports 252 are performed in parallel. Namely, the control apparatus 5 supplies the first liquid LQ11 via the first supply port 251 in the state wherein the immersion space LS is formed with the second liquid LQ12 supplied via the second supply ports 252.

When the first liquid LQ11 is supplied via the first supply port 251, the first liquid LQ11 flows from the first supply port 251 onto the second surface 222 and toward the outer side in radial directions; in addition, at least some of the second liquid LQ12 of the immersion space LS flows, together with the first liquid LQ11 supplied via the first supply port 251, on the second surface 222 toward the outer side in radial directions. The control apparatus 5 supplies the first liquid LQ11 via the first supply port 251 such that the gas space is formed between the surface (i.e., the liquid surface LQS) of the liquid LQ that flows on the second surface 222 and the front surface of the substrate P (i.e., the object). Thereby, the liquid surface LQS of the liquid LQ, which flows toward the outer side in radial directions with respect to the optical axis AX, is formed on the outer side of the first surface 221 in radial directions with respect to the optical axis AX (i.e., on the outer side of the interface LG of the immersion space LS). The liquid LQ (i.e., the first and second liquids LQ11, LQ12) that flows on the second surface 222 toward the outer side in radial directions is recovered by the recovery part 260. At least some of the liquid LQ that flows on the second surface 222 is recovered via the recovery port 261.

While flowing the liquid LQ on the second surface 222 by supplying the first liquid LQ11 via the first supply port 251 and the second liquid LQ12 via the second supply ports 252 in parallel with the recovery of the liquid LQ via the recovery part 260 (i.e., the recovery port 261), the control apparatus 5 forms the immersion space LS such that the optical path K of the exposure light EL between the emergent surface 11 and the substrate P is filled with the second liquid LQ12.

While supplying the second liquid LQ12 via the second supply ports 252 in parallel with supplying the first liquid LQ11 via the first supply port 251, the control apparatus 5 starts the exposure of the substrate P in the state wherein the immersion space LS is formed such that part of the front surface of the substrate P is locally covered with the second liquid LQ12.

The control apparatus 5 illuminates the mask M with the exposure light EL by causing the illumination system IL to emit the exposure light EL. The exposure light EL that emerges from the mask M emerges from the emergent surface 11 of the projection optical system PL. The control apparatus 5 exposes the substrate P with the exposure light EL that both emerges from the emergent surface 11 and transits the second liquid LQ12 between the emergent surface 11 and the substrate P. Thereby, the image of the pattern of the mask M is projected to the substrate P, which is thereby exposed with the exposure light EL. Also during the exposure of the substrate P, the supplying of the first liquid LQ11 via the first supply port 251 and the supplying of the second liquid LQ12 via the second supply ports 252 are performed in parallel.

As discussed above, the exposure apparatus EX of the present embodiment is a scanning type exposure apparatus wherein the substrate P is moved in prescribed directions within the XY plane in the state wherein the second liquid LQ12 is held between the emergent surface 11 and the substrate P (i.e., in the state wherein the immersion space LS is formed) during at least part of the exposure of the substrate P. For example, during the radiation of the exposure light EL to the substrate P (i.e., during the scanning exposure), the substrate P moves in the Y axial directions with respect to the last optical element 12 and the liquid immersion member 204. In addition, if multiple shot regions on the substrate P are sequentially exposed, then, when a next shot region is to be exposed after the exposure of a certain shot region, the substrate P is stepped in, for example, one of the X axial directions with respect to the last optical element 12 and the liquid immersion member 204 or in a direction that is inclined with respect to the X axis within the XY plane. In addition, the movement during a scanning exposure is not limited to a stepping motion; for example, it is possible for the substrate P to move under various movement conditions in the state wherein the second liquid LQ12 is held between the substrate P and the emergent surface 11. The movement conditions of the substrate P include either a movement velocity and an acceleration (or a deceleration) in a prescribed direction (e.g., the −Y direction) within the XY plane or a movement distance (i.e., when moving from a first position to a second position within the XY plane), or both.

In the present embodiment, the first liquid LQ11 supplied via the first supply port 251 flows on the second surface 222 toward the outer side in radial directions with respect to the optical axis AX; therefore, even if, for example, the substrate P moves at a high speed or a high acceleration, it is possible to prevent the second liquid LQ12 from leaking out of the space between the liquid immersion member 204 and the substrate P and to prevent the second liquid LQ12 (i.e., a film, a drop, or the like) from remaining on the substrate P.

In addition, in the present embodiment, at least some of the first liquid LQ11 supplied via the first supply port 251 flows via the passageways 235 to the space 234, which makes it possible to effectively prevent the second liquid LQ12 from leaking out, remaining behind, and the like.

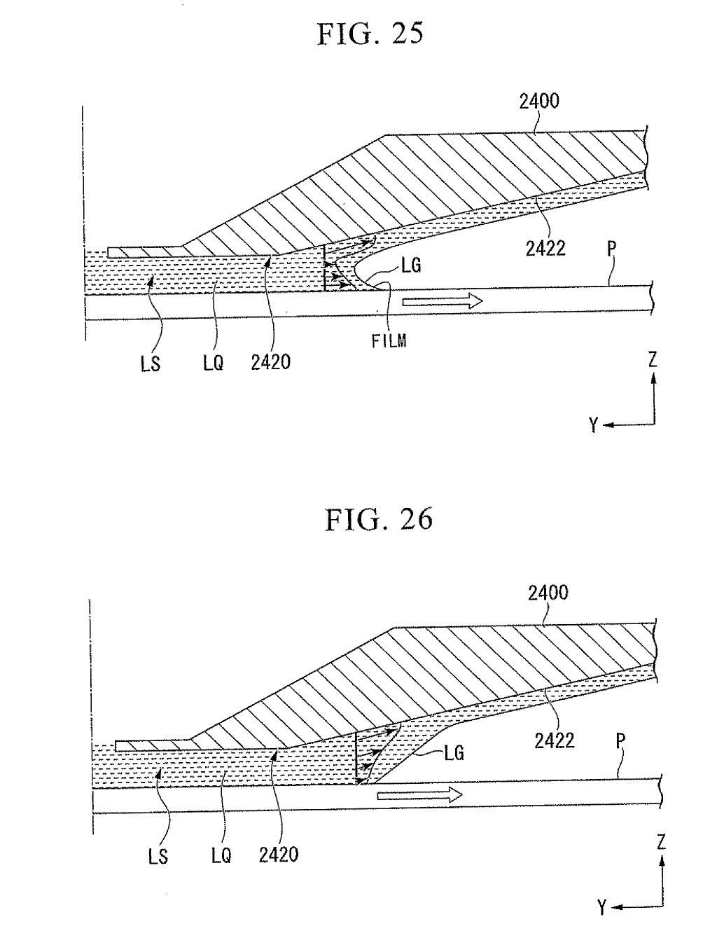

The following text explains the action of the first liquid LQ11 supplied via the first supply port 251. FIG. 25 and FIG. 26 schematically show, for a case wherein the substrate P is moved in the −Y direction in the state wherein the immersion space LS is formed, one example of the shape of the interface LG of the immersion space LS and the flow velocity distribution of the liquid LQ between a lower surface 2420 of a liquid immersion member 2400 and the front surface of the substrate P. In FIG. 25 and FIG. 26, arrows indicate the flow velocity distribution.

FIG. 25 shows the shape of the interface LG and the flow velocity distribution of the liquid LQ for the case wherein the first liquid LQ11, which has a high flow velocity, is supplied to a second surface 2422 and the substrate P is moved at a high speed in the −Y direction. For the case wherein the first liquid LQ11, which has a high flow velocity, is supplied to the second surface 2422 and the substrate P is moved at a high speed in the −Y direction, the flow velocity of the liquid LQ increases in the vicinities of both the lower surface 2420 of the liquid immersion member 2400 and the front surface of the substrate P. Moreover, for example, owing to the effect of the viscosity of the liquid LQ, the flow velocity of the liquid LQ decreases at substantially the center part between the lower surface 2420 of the liquid immersion member 2400 and the front surface of the substrate P. In other words, the flow velocity builds more slowly at this center part than in the vicinities of both the lower surface 2420 and the front surface of the substrate P. As a result, as shown in FIG. 25, a film of the liquid LQ might form on the front surface of the substrate P.

FIG. 26 is a schematic drawing that shows one example of the shape of the interface LG of the immersion space LS, wherefrom the liquid LQ is sufficiently prevented from leaking out or remaining behind, and the flow velocity distribution of the liquid LQ. As shown in FIG. 26, adjusting the flow velocity distribution such that the difference between the flow velocity at the center part and the flow velocity in the vicinities of both the lower surface 2420 of the liquid immersion member 2400 and the front surface of the substrate P becomes small makes it possible to prevent the liquid LQ from leaking out, remaining behind, and the like and a film of the liquid LQ from forming on the front surface of the substrate P. In FIG. 26, the flow velocity of the liquid LQ that flows between the lower surface 2420 of the liquid immersion member 2400 and the front surface of the substrate P is low in the vicinity of the front surface of the substrate P and high in the vicinity of the lower surface 2420 of the liquid immersion member 2400. In the explanation below, the shape of the interface LG shown in FIG. 26 is called an ideal shape where appropriate, and the flow velocity distribution of the liquid LQ shown in FIG. 26 is called an ideal flow velocity distribution where appropriate.

To obtain the ideal velocity distribution shown in FIG. 26, it is conceivable to, for example, reduce the flow velocity of the first liquid LQ11 supplied via the first supply port (251) to the second surface 2422, to reduce the movement velocity of the substrate P, and the like. If the flow velocity of the first liquid LQ11 is reduced, then difficulties such as the first liquid LQ11 supplied via the first supply port (251) falling onto the substrate P, flowing on the second surface 2422 and reaching the recovery part (260), or the like might arise. In addition, if the movement velocity of the substrate P is reduced, then, for example, the exposing process might take more time and thereby reduce throughput.

In the present embodiment, at least some of the first liquid LQ11 supplied via the first supply port 251 flows via the passageways 235 to the space 234 and therefore acts upon the second liquid LQ12 that flows from the space 231 into the space 234, which, in turn, adjusts the flow velocity distribution of the liquid LQ in the space 234. In the present embodiment, the flow velocity distribution is adjusted such that the interface LG achieves the ideal shape shown in FIG. 26.

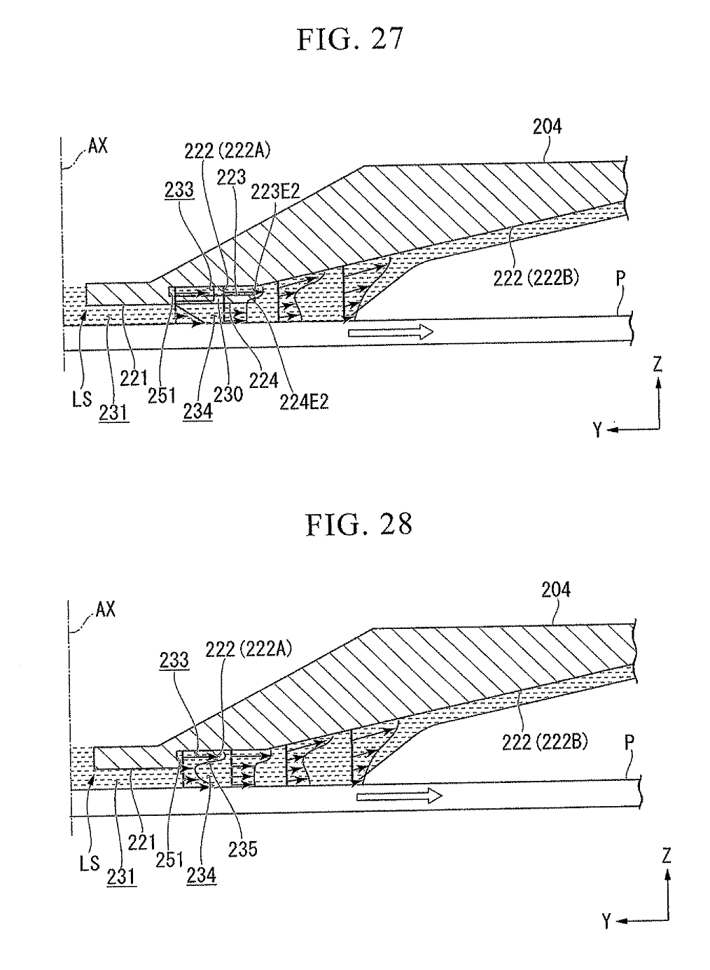

FIG. 27 and FIG. 28 are schematic drawings that show one example of the action of the liquid immersion member 204 according to the present embodiment. FIG. 27 is a cross sectional view that includes the rod members 230, and FIG. 28 is a cross sectional view that includes the passageways 235. FIG. 27 and FIG. 28 show a case wherein the substrate P is moved in the −Y direction in the state wherein the immersion space LS is formed between the liquid immersion member 204 and the substrate P.

The control apparatus 5 supplies the first liquid LQ11 via the first supply port 251 in the state wherein the immersion space LS is formed by supplying the second liquid LQ12 supplied via the second supply ports 252. The second liquid LQ12 supplied via the second supply ports 252 flows via the opening 243 to the space 231. The first supply port 251 supplies the first liquid LQ11 in the state wherein the first supply port 251 is disposed in the immersion space LS. In the present embodiment, if the substrate P moves in a prescribed direction within the XY plane, then the flow velocity of the first liquid LQ11 supplied via the first supply port 251 in that prescribed direction will be higher than the movement velocity of the substrate P in that prescribed direction. Namely, if, for example, the substrate P moves in the −Y direction, then the flow velocity of the first liquid LQ11 supplied via the first supply port 251 in the −Y direction will be higher than the movement velocity of the substrate P in the −Y direction.

As shown in FIG. 27, after at least some of the first liquid LQ11 supplied via the first supply port 251 to the space 233 moves at a high velocity between the second surface 222 and the third surfaces 223, the first liquid LQ11 flows on the second surface 222 (i.e., the second area 222B) and then reaches the recovery part 260 (i.e., the outer side edge 222E2).

In addition, as shown in FIG. 28, at least some of the first liquid LQ11 that flows from the first supply port 251 to the space 233 flows via the passageways 235 to the space 234. The first liquid LQ11 that flows from the passageways 235 into the space 234 acts upon the second liquid LQ12 that flows from the space 231 into the space 234. Thereby, as shown by the arrows in FIG. 27 and FIG. 28, the flow velocity distribution of the liquid LQ in the space 234 between the fourth surfaces 224 and the front surface of the substrate P is adjusted. For example, the action of the first liquid LQ11 upon the second liquid LQ12 adjusts the flow velocity distribution such that the flow velocity of the liquid LQ at outer side edges 224E2 of the fourth surfaces 224 of the space 234 approaches the flow velocity of the liquid LQ at an outer side edges 223E2 of the third surfaces 223 of the space 233.

In the present embodiment, a flow velocity of the first liquid LQ11 supplied via the first supply port 251 is higher than a flow velocity of the second liquid LQ12 supplied via the second supply ports 252. In addition, the first liquid LQ11 is supplied at a high velocity via the first supply port 251, and the flow velocity of the first liquid LQ11 that flows from the passageways 235 to the space 234 is higher than the flow velocity of the second liquid LQ12 that flows from the space 231 to the space 234. The interaction between the first liquid LQ11 that flows from the passageways 235 into the space 234 and the second liquid LQ12 that flows from the space 231 into the space 234 adjusts the flow velocity of the liquid LQ in the space 234. Namely, the flow velocity of the second liquid LQ12 that flows from the space 231 into the space 234 increases as a result of the action of the first liquid LQ11. Specifically, the flow velocity of the second liquid LQ12 at the center part between the fourth surfaces 224 (i.e., the second surface 222) and the front surface of the substrate P increases as a result of the action of the first liquid LQ11. Thereby, the flow velocity of the liquid LQ at the center part between the liquid immersion member 204 and the substrate P is prevented from decreasing. Namely, the interaction between the first liquid LQ11 and the second liquid LQ12 adjusts the flow velocity distribution of the liquid LQ such that the difference between the flow velocity at the center part and the flow velocity in the vicinities of both the lower surface 220 (i.e., the second surface 222) of the liquid immersion member 204 and the front surface of the substrate P becomes small. Accordingly, it is possible to make the flow velocity distribution of the liquid LQ between the liquid immersion member 204 and the substrate P approach the ideal flow velocity distribution, to make the interface LG approach the ideal shape, and to prevent the liquid LQ from leaking out, remaining behind, and the like.

As a result of the action of the first liquid LQ11 flowing at a high velocity between the second surface 222 and the third surfaces 223, the liquid LQ of the space 234 can flow on the second surface 222 (i.e., the second area 2228) together with the first liquid LQ11 and reach the recovery part 260 without falling onto the substrate P.

In the present embodiment, the flow velocity of the liquid LQ that flows on the second surface 222 (i.e., the second area 222B) is higher than the movement velocity of the substrate P (i.e., the object), which opposes the liquid LQ (i.e., the liquid surface LQS).

Accordingly, the liquid LQ that flows on the second surface 222 can reach the recovery part 260 without falling onto the substrate P. Furthermore, the flow velocity of the liquid LQ that flows on the second surface 222 may be lower than the movement velocity of the substrate P (i.e., the object).

In the present embodiment, the fluid action between the first liquid LQ11 that flows from the passageways 235 into the space 234 and the second liquid LQ12 that flows from the space 231 into the space 234 causes the flow velocity of both the liquid LQ that flows through the space 234 and reaches the outer side edges 224E2 of the fourth surfaces 224 and the liquid LQ that flows between the second surface 222 and the third surfaces 223 and reaches the outer side edges 223E2 of the third surfaces 223 to approach one another. In other words, as a result of the action of the first liquid LQ11 that flows from the passageways 235 into the space 234, the flow velocity of the liquid LQ that flows in the space 234 in the −Y direction gradually builds and approaches the flow velocity of the first liquid LQ11 that flows in the −Y direction between the second surface 222 and the third surfaces 223. Accordingly, it is possible both to make the flow velocity distribution of the liquid LQ between the liquid immersion member 204 and the substrate P approach the ideal flow velocity distribution and to prevent the liquid LQ from leaking out, remaining behind, and the like.

Furthermore, the supply conditions of the first liquid LQ11 supplied via the first supply port 251 may be adjusted in accordance with the movement conditions of the substrate P. For example, the flow velocity of the first liquid LQ11 supplied via the first supply port 251 may be adjusted in accordance with the movement velocity of the substrate P in the prescribed direction (e.g., one of the Y axial directions) within the XY plane. For example, if the substrate P is moved at a high speed in the −Y direction, then the flow velocity of the first liquid LQ11 supplied in the −Y direction via the first supply port 251 will be increased. For example, the control apparatus 5 can adjust the flow velocity of the first liquid LQ11 by, for example, adjusting the amount of the first liquid LQ11 supplied per unit of time by the first liquid supply apparatus 271. Adjusting the flow velocity of the first liquid LQ11 in accordance with the movement velocity of the substrate P makes it possible to prevent the liquid LQ from leaking out, remaining behind, and the like.

In addition, the control apparatus 5 can adjust the flow velocity of the first liquid LQ11, which is supplied substantially parallel to the Y axial directions via the first supply port 251, in accordance with the acceleration of the substrate P in the prescribed direction (e.g., one of the Y axial directions) within the XY plane. For example, if the substrate P is moved with a high acceleration in the −Y direction, then the flow velocity of the first liquid LQ11 supplied in the −Y direction via the first supply port 251 will be increased. In so doing, it is possible to prevent the liquid LQ from leaking out, remaining behind, and the like.

In addition, the flow velocity of the first liquid LQ11, which is supplied substantially parallel to the Y axial directions via the first supply port 251, can be adjusted in accordance with the linear movement distance of the substrate P in the prescribed direction (e.g., one of the Y axial directions) within the XY plane.

Thus, by adjusting, in accordance with the movement conditions of the substrate P, the supply conditions of the first liquid LQ11 supplied via the first supply port 251 in the same direction as the movement direction of the substrate P (i.e., the Y direction), it is possible to prevent the liquid LQ from leaking out, remaining behind, and the like.

Furthermore, the above text explained a case wherein the immersion space LS of the second liquid LQ12 is formed on the substrate P, but the same also applies to cases wherein the immersion space LS of the second liquid LQ12 is formed on the substrate stage 2 (i.e., the plate member T) or wherein it spans the substrate stage 2 (i.e., the plate member T) and the substrate P.

According to the present embodiment as explained above, it is possible to prevent the liquid LQ from leaking out, remaining on the front surface of the object (i.e., the substrate P and the like), which opposes the liquid immersion member 204, and the like. According to the present embodiment, even if the substrate P is moved at a high speed, it is possible to prevent the liquid LQ from leaking out, remaining behind, and the like. Accordingly, it is possible to prevent exposure failures from occurring while preventing a decline in throughput.

In addition, according to the present embodiment, the recovery part 260 has the sixth surface 226, which makes it possible to both prevent the liquid LQ from leaking off of the second surface 222 and satisfactorily recover the liquid LQ from the second surface 222 via the recovery port 261. In addition, the seventh surface 227 is provided, which makes it possible to prevent the liquid LQ in the circumferential edge area of the second surface 222 from falling onto the substrate P and the like.

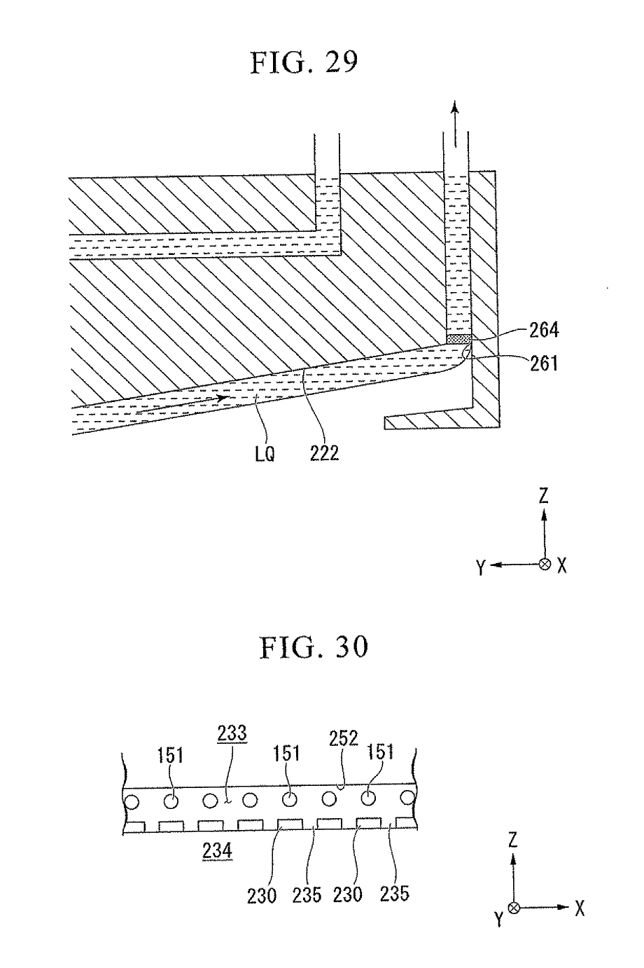

Furthermore, as shown in FIG. 29, a porous member 264, such as a mesh, may be disposed in the recovery port 261.

Furthermore, as shown in FIG. 30, first supply ports 1251 may be disposed at prescribed intervals around the optical axis AX. In the example shown in FIG. 30, each of the first supply ports 1251 are circular, but the first supply ports 1251 may have an arbitrary shape such as a quadrilateral or an elliptical shape.

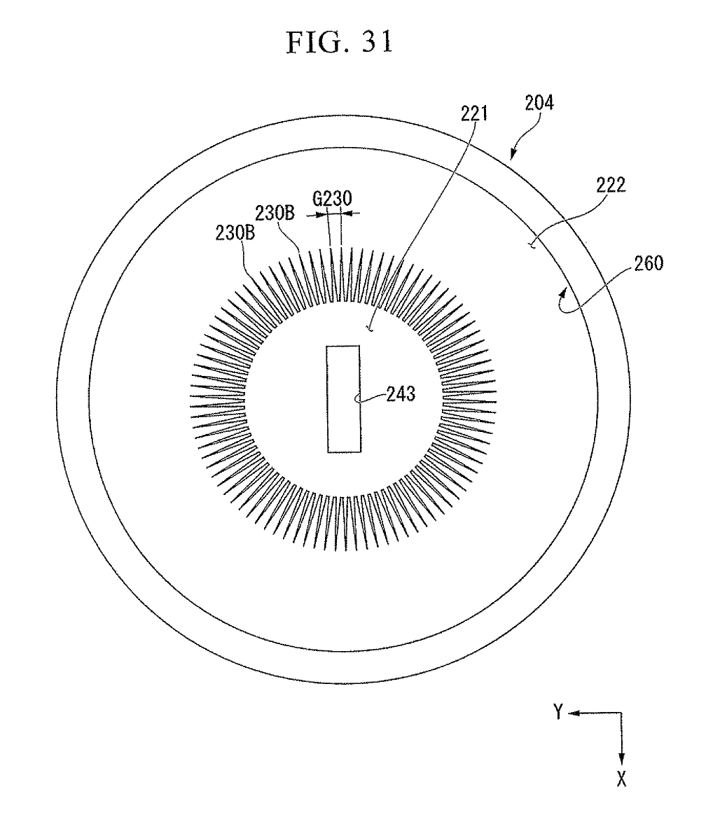

Furthermore, as shown in FIG. 31, the size of each of the gaps G230 may vary in radial directions with respect to the optical axis AX. In the example shown in FIG. 31, the size of each of the gaps G230 increases gradually and the size of each rod member 230B decreases gradually toward the outer side in radial directions with respect to the optical axis AX. Furthermore, the size of each of the gaps G230 may decrease gradually toward the outer side in radial directions with respect to the optical axis AX.

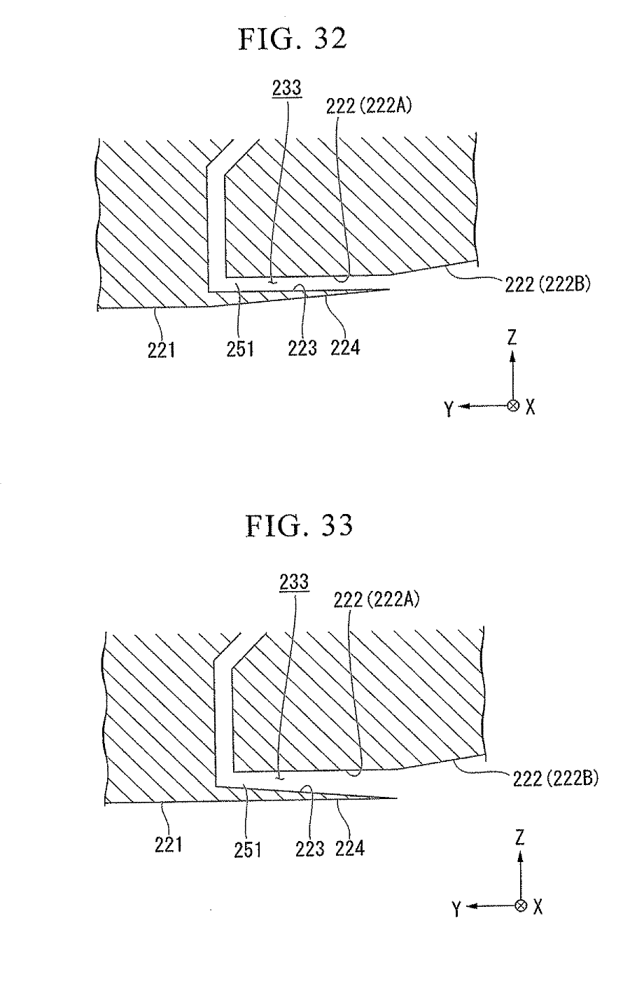

Furthermore, in the embodiment discussed above, the first surface 221 and the fourth surfaces 224 are disposed within substantially the same plane; however, at least part of the fourth surfaces 224 may be disposed in the second direction (i.e., the +Z direction) more than the first surface 221 is. For example, as shown in FIG. 32, the fourth surfaces 224 may be inclined in the second direction (i.e., the +Z direction) toward the outer side in radial directions with respect to the optical axis AX. In addition, there may be a step between the first surface 221 and the fourth surfaces 224.

Furthermore, in the embodiment discussed above, the second surface 222 (i.e., the first area 222A) and the third surfaces 223 are substantially parallel, but they may be nonparallel. For example, as shown in FIG. 33, the third surfaces 223 may be inclined with respect to the second surface 222 such that the size of the space between the second surface 222 and the third surfaces 223 in the Z axial directions increases gradually toward the outer side in radial directions with respect to the optical axis AX.

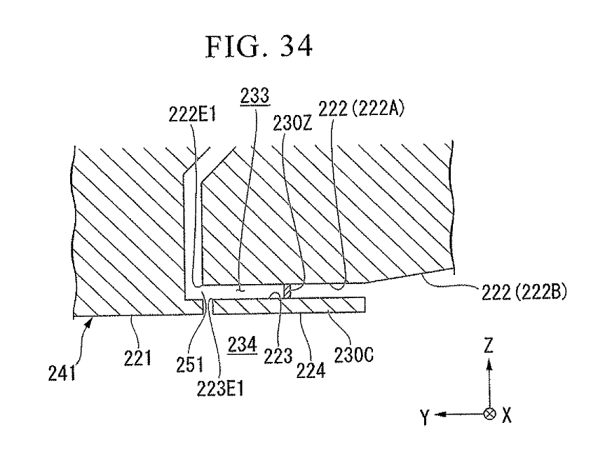

Furthermore, in the embodiment discussed above, the outer side edge 221E2 of the first surface 221 and the inner side edges 224E1 of the fourth surfaces 224 are connected, but they may be spaced apart as shown in FIG. 34. In FIG. 34, rod members 230C are disposed around the first surface 221 (i.e., the plate part 241) across a gap. Each of the rod members 230C is connected to at least part of the second surface 222 via a connecting member 230Z. Furthermore, at least part of the third surfaces 223 of the rod members 230C may oppose the second area 2228 of the second surface 222. In addition, as shown in FIG. 34, the first supply port 251 does not have to be disposed between the inner side edge 222E1 of the second surface 222 and the inner side edge 223E1 of the third surface 223. In addition, at least part of the first supply port 251 may be disposed in at least part of the second surface 222 that faces the space 233, or at least part of the first supply port 251 may be disposed in at least part of the third surfaces 223 that face the space 233.

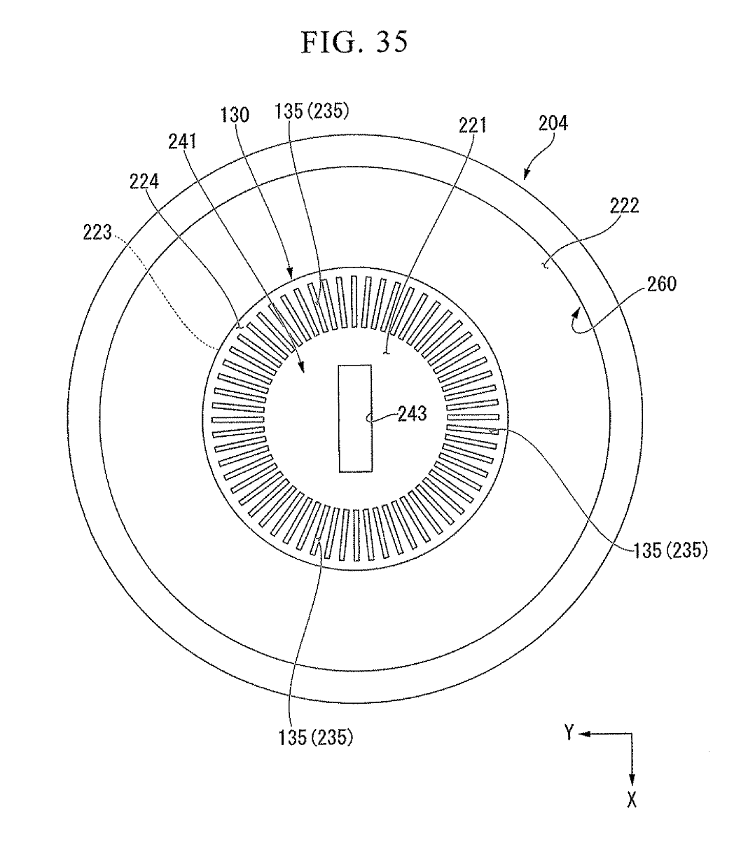

Furthermore, in the embodiment discussed above, the liquid immersion member 204 comprises the comb part 240 that comprises the plurality of rod members 230, which is disposed around the plate part 241; furthermore, the third surfaces 223 and the fourth surfaces 224 are disposed on the rod members 230; however, for example, as shown in FIG. 35, the liquid immersion member 204 may comprise a plate member 130, which is disposed around the plate part 241, and the third surface 223 and the fourth surface 224 may be disposed on the plate member 130. In the example shown in FIG. 35, the passageways 235 that connect the space 233, which is faced by the third surface 223, and the space 234, which is faced by the fourth surface 224, has openings 135, which are formed in the plate member 130 such that they connect the third surface 223 and the fourth surface 224. At least some of the first liquid LQ11 supplied via the first supply port 251 flows via the openings 135 into the space 234. In the example shown in FIG. 35, each of the openings 135 is slit shaped and long in radial directions (or has a longitudinal axis along a radial direction) with respect to the optical axis AX. In addition, the openings 135 are disposed at prescribed intervals around the first surface 221. Also in the example shown in FIG. 35, it is possible to make the flow velocity distribution of the liquid LQ approach the ideal flow velocity distribution and thereby to prevent the liquid LQ from leaking, remaining behind, and the like.

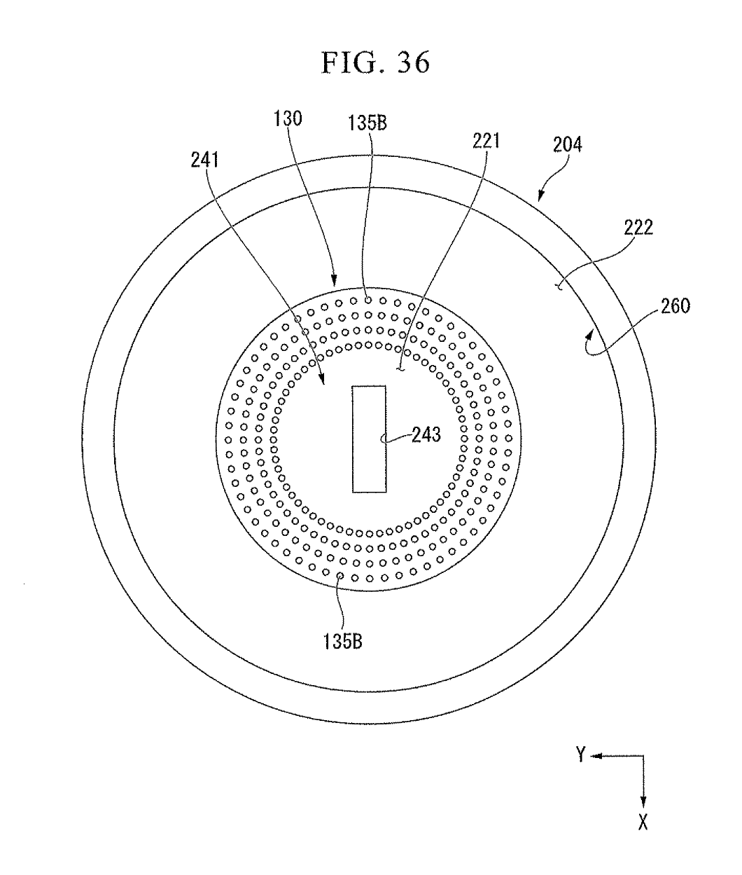

Furthermore, as shown in FIG. 36, openings 135B, which are formed in the plate member 130, may be, for example, circular, but they may also be elliptical. In addition, a plurality of the openings 135B may be disposed in radial directions with respect to the optical axis AX, and they may also be disposed around the first surface 221. In addition, each of the openings 135B may be rectangular. In addition, the size of each of the openings 135B in radial directions with respect to the optical axis AX may be equal to or smaller than the size of each of the openings 135B in circumferential directions with respect to the optical axis AX.

In addition, the plate member 130 may be disposed around the first surface 221 (i.e., the plate part 241) across a gap. In addition, the first supply port 251 may be disposed in at least part of the third surface 223 of the plate member 130, which is faced by the space 233.

Furthermore, in the embodiment discussed above, the size of each of the rod members 230 (i.e., the plate member 130) in radial directions with respect to the optical axis AX is smaller than the size of the second surface 222; however, at least some of the rod members 230 (i.e., the plate member 130) may be the same as the size of the second surface 222. For example, the outer side edges of some of the rod members 230 (i.e., the outer side edges 223E2 of the third surfaces 223) of the plurality of the rod members 230 may oppose the outer side edge 222E2 of the second surface 222.

### Seventh Embodiment

The following text explains a seventh embodiment. In the explanation below, constituent parts that are identical or equivalent to those in the embodiment discussed above are assigned identical symbols, and the explanations thereof are therefore abbreviated or omitted.

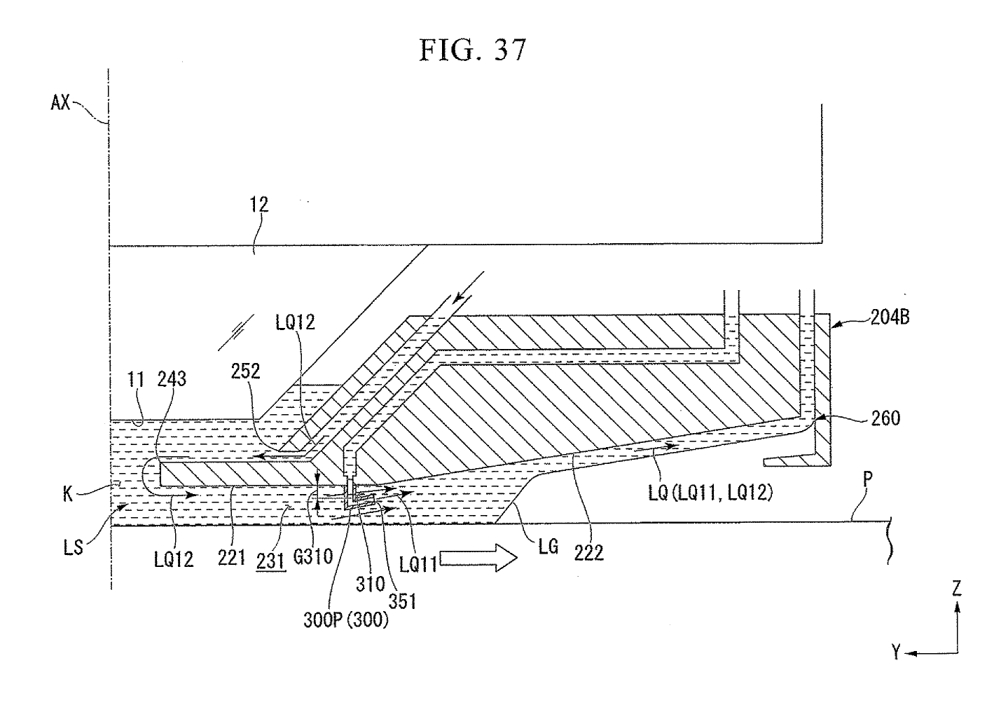

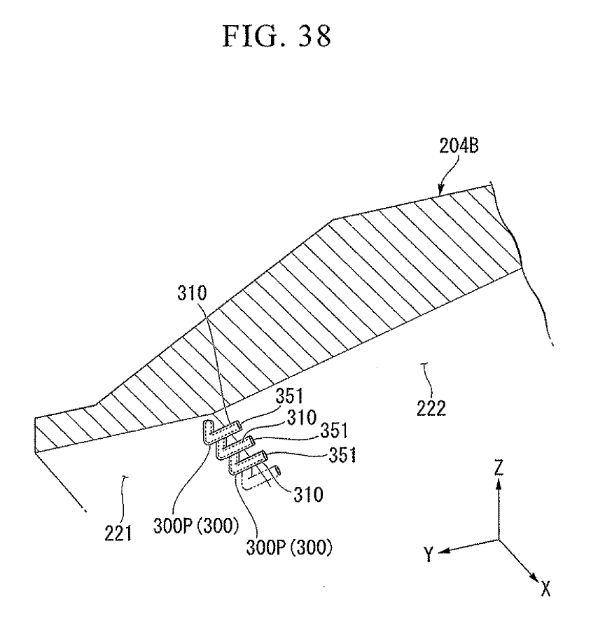

FIG. 37 is a side cross sectional view that shows part of a liquid immersion member 204B according to the seventh embodiment, and FIG. 38 is a view of the same from below.

In FIG. 37 and FIG. 38, the liquid immersion member 204B comprises: the first surface 221, which is disposed at least partly around the optical path K of the exposure light EL that emerges from the emergent surface 11; the second surface 222, which is disposed at least partly around the first surface 221; supply members 300, each of which is disposed in the first surface 221 and has an outer surface 310, at least part of which is oriented in a direction different from that of the first surface 221 and which is disposed along radial directions with respect to the optical axis AX; and first supply ports 351, which supply the first liquid LQ11 to the second surface 222 and are disposed in the supply member 300 such that they face the outer side in radial directions (or is directed in an outward radial direction) with respect to the optical axis AX.

In the present embodiment, each of the supply members 300 comprises a pipe member 300P, at least part of which opposes the first surface 221 across a gap G310. Each of the outer surfaces 310 includes at least part of an outer circumferential surface of the corresponding pipe member 300P. In the present embodiment, the first supply ports 351 are disposed at substantially the center between the first surface 221 and the front surface of the substrate P.

In the present embodiment, the first surface 221 faces the first direction (i.e., the −Z direction) and is substantially parallel to the XY plane. In addition, in the present embodiment, the cross section of the outer circumferential surface of each of the pipe members 300P is circular. In FIG. 37 and FIG. 38, the outer circumferential surface of each of the pipe members 300P includes a first portion that faces the +Z direction, a second portion that faces the +X direction, and a third portion that faces the −X direction. In addition, the outer circumferential surface of each of the pipe members 300P also includes a fourth portion that faces the same direction as that faced by the first surface 221 (i.e., the −Z direction). In the present embodiment, the pipe members 300P are disposed at prescribed intervals around the optical axis AX.

In addition, the liquid immersion member 204B comprises the second supply ports 252, which supply the second liquid LQ12 to the optical path K. In the present embodiment, the supplying of the first liquid LQ11 via the first supply ports 351 and the supplying of the second liquid LQ12 via the second supply ports 252 are performed in parallel. The immersion space LS is formed between at least part of the emergent surface 11, the first surface 221, and the second surface 222 on one side and the front surface of the substrate P on the other side with at least some of the second liquid LQ12 supplied via the second supply ports 252 such that the optical path K of the exposure light EL between the emergent surface 11 and the substrate P is filled with the second liquid LQ12, and furthermore the first supply ports 351 supply the first liquid LQ11 in the state wherein the first supply ports 351 are disposed in the immersion space LS.

In the present embodiment, a flow velocity of the first liquid LQ11 supplied via the first supply ports 351 is higher than a flow velocity of the second liquid LQ12 supplied via the second supply ports 252. In the present embodiment, the flow velocity of the first liquid LQ11 supplied via the first supply ports 351 is higher than the flow velocity of the second liquid LQ12 that flows from the second supply ports 252 via the opening 243 to the space 231.

Furthermore, the flow velocity of the first liquid LQ11 supplied via the first supply ports 351 may be lower than the flow velocity of the second liquid LQ12 supplied via the second supply ports 252. In addition, the flow velocity of the first liquid LQ11 supplied via the first supply ports 351 may be lower than the flow velocity of the second liquid LQ12 that flows from the second supply ports 252 via the opening 243 to the space 231.

At least some of the second liquid LQ12 supplied via the second supply ports 252 flows toward the outer side in radial directions with respect to the optical axis AX while contacting the outer surfaces 310 in the space 231, which is faced by the first surface 221. At least some of the second liquid LQ12 that flows toward the outer side in radial directions with respect to the optical axis AX while contacting the outer surfaces 310 contacts (i.e., merges with), in the vicinity of the first supply ports 351, the first liquid LQ11 supplied via the first supply ports 351. The outer surfaces 310 (i.e., the outer circumferential surfaces) of the pipe members 300P are disposed around the first supply ports 351, and the second liquid LQ12 that flows while contacting the outer surfaces 310 envelops the first liquid LQ11 supplied via the first supply ports 351. For example, the second liquid LQ12 that flows while contacting the first portions of the outer circumferential surfaces of the pipe members 300P, which face the +Z direction, contacts (i.e., merges with)—from above (i.e., the +Z side of) the first supply ports 351—the first liquid LQ11 supplied via the first supply ports 351. In addition, the second liquid LQ12 that flows while contacting the second portions (the third portions) of the outer circumferential surfaces of the pipe members 300P, which face the +X direction (the −X direction), contacts (i.e., merges with)—from the +X side (the −X side) of the first supply ports 351—the first liquid LQ11 supplied via the first supply ports 351. In addition, the second liquid LQ12 that flows while contacting the fourth portions of the outer circumferential surfaces of the pipe members 300P, which face the −Z direction, contacts (i.e., merges with)—from below (i.e., the −Z side of) the first supply ports 351—the first liquid LQ11 supplied via the first supply ports 351. Thereby, the first liquid LQ11 supplied via the first supply ports 351 and the second liquid LQ12 that flows while contacting the outer surfaces 310 interact.

The following text explains a method of using the exposure apparatus EX that has the abovementioned configuration to expose the substrate P.

The control apparatus 5 causes the first surface 221 and the second surface 222 on one side and the front surface of the substrate P (or the upper surface 17 of the substrate stage 2) on the other side to oppose one another. The control apparatus 5 supplies the second liquid LQ12 via the second supply ports 252 in the state wherein the first surface 221 and the second surface 222 on one side and the front surface of the substrate P on the other side are caused to oppose one another. Thereby, the second liquid LQ12 supplied via the second supply ports 252 forms the immersion space LS between at least part of the emergent surface 11, the first surface 221, and the second surface 222 on one side and the front surface of the substrate P on the other side such that the optical path K of the exposure light EL between the emergent surface 11 and the substrate P is filled with the second liquid LQ12.

In addition, the control apparatus 5 supplies the first liquid LQ11 via the first supply ports 351. The first supply ports 351 supply the first liquid LQ11 to the second surface 222.

The control apparatus 5 supplies the first liquid LQ11 via the first supply ports 351 and supplies the second liquid LQ12 via the second supply ports 252 in parallel. The control apparatus 5 supplies the first liquid LQ11 via the first supply ports 351 in the state wherein the immersion space LS is formed with the second liquid LQ12 supplied via the second supply ports 252.

When the first liquid LQ11 is supplied via the first supply ports 351, the first liquid LQ11 supplied via the first supply ports 351 flows on the second surface 222 toward the outer side in the radial directions; in addition, at least some of the second liquid LQ12 of the immersion space LS flows, together with the first liquid LQ11 supplied via the first supply ports 351, on the second surface 222 toward the outer side in the radial directions. The recovery part 260 recovers the liquid LQ (i.e., the first and second liquids LQ11, LQ12) that flows on the second surface 222 toward the outer side in the radial directions.

While supplying the second liquid LQ12 via the second supply ports 252 in parallel with the supply of the first liquid LQ11 via the first supply ports 351, the control apparatus 5 starts the exposure of the substrate P in the state wherein the immersion space LS is formed such that part of the front surface of the substrate P is locally covered with the second liquid LQ12. While moving the substrate P in the Y axial directions in the state wherein the immersion space LS is formed, the control apparatus 5 exposes the substrate P with the exposure light EL that both emerges from the emergent surface 11 and transits the second liquid LQ12 between the emergent surface 11 and the substrate P.

Also in the present embodiment, the first liquid LQ11 supplied via the first supply ports 351 flows on the second surface 222 toward the outer side in radial directions with respect to the optical axis AX; therefore, even if, for example, the substrate P moves at a high speed or a high acceleration, it is possible to prevent the liquid LQ from leaking out of the space between the liquid immersion member 204B and the substrate P and prevents the liquid LQ (i.e., a film, a drop, or the like) from remaining on the substrate P.

In addition, in the present embodiment, the first liquid LQ11 supplied via the first supply ports 351 acts upon the second liquid LQ12 that flows while contacting the outer surfaces 310, and thereby the flow velocity distribution of the liquid LQ in the space between the front surface of the substrate P on one side and the first surface 221 or the second surface 222, or both, on the other side is adjusted. The action of the first liquid LQ11 adjusts the flow velocity distribution such that the interface LG achieves the ideal shape shown in FIG. 26.

Also in the present embodiment, if the substrate P is moved in the prescribed direction within the XY plane, then the flow velocity of the first liquid LQ11 supplied via the first supply ports 351 in the prescribed direction is higher than the movement velocity of the substrate P in that prescribed direction. Namely, for example, if the substrate P is moved in the −Y direction, then the flow velocity of the first liquid LQ11 supplied via the first supply ports 351 in the −Y direction is higher than the movement velocity of the substrate P in the −Y direction.

In the present embodiment, the flow velocity of the first liquid LQ11 supplied via the first supply ports 351 is higher than the flow velocity of the second liquid LQ12 supplied via the second supply ports 252. In addition, the flow velocity of the first liquid LQ11 supplied via the first supply ports 351 at a high speed is higher than the flow velocity of the second liquid LQ12 that flows via the opening 243 to the space 231. The interaction between the first liquid LQ11 supplied via the first supply ports 351 and the second liquid LQ12 that flows via the opening 243 into the space 231 adjusts the flow velocity of the liquid LQ in the space 231. Namely, the flow velocity of the second liquid LQ12 that flows via the opening 243 into the space 231 is increased by the action of the first liquid LQ11. Thereby, the flow velocity of the liquid LQ at the center part between the liquid immersion member 204B and the substrate P is prevented from decreasing. Namely, the interaction between the first liquid LQ11 and the second liquid LQ12 adjusts the flow velocity distribution of the liquid LQ such that the difference between the flow velocity at the center part and the flow velocity in the vicinities of the lower surface 220 (i.e., the first surface 221) of the liquid immersion member 204B and the front surface of the substrate P becomes small. In the present embodiment, the first supply ports 351 are disposed at substantially the center between the first surface 221 of the liquid immersion member 204B and the front surface of the substrate P, which makes it possible to satisfactorily adjust the flow velocity distribution of the liquid LQ. Accordingly, it is possible to make both the flow velocity distribution of the liquid LQ between the liquid immersion member 204B and the substrate P approach the ideal flow velocity distribution and the interface LG achieve the ideal shape, which, in turn, makes it possible to prevent the liquid LQ from leaking out, remaining behind, and the like.

The action of the first liquid LQ11 supplied via the first supply ports 351 makes it possible for the liquid LQ of the space 231 to flow on the second surface 222 (i.e., the second area 222B) together with the first liquid LQ11 and reach the recovery part 260 without falling onto the substrate P.

Also in the present embodiment, the flow velocity of the liquid LQ that flows on the second surface 222 (i.e., the second area 222B) is higher than the movement velocity of the substrate P (i.e., the object), which opposes the liquid LQ (i.e., the liquid surface LQS). Accordingly, the liquid LQ that flows on the second surface 222 can reach the recovery part 260 without falling onto the substrate P. Furthermore, the flow velocity of the liquid LQ that flows on the second surface 222 may be lower than the movement velocity of the substrate P (i.e., the object).

Also in the present embodiment, as explained above, it is possible to prevent the liquid LQ from leaking out, remaining behind, and the like. In addition, even if the substrate P is moved at a high speed or with a high acceleration, it is possible to prevent the liquid LQ from leaking out, remaining behind, and the like. Accordingly, it is possible to prevent exposure failures from occurring while preventing a decline in throughput.

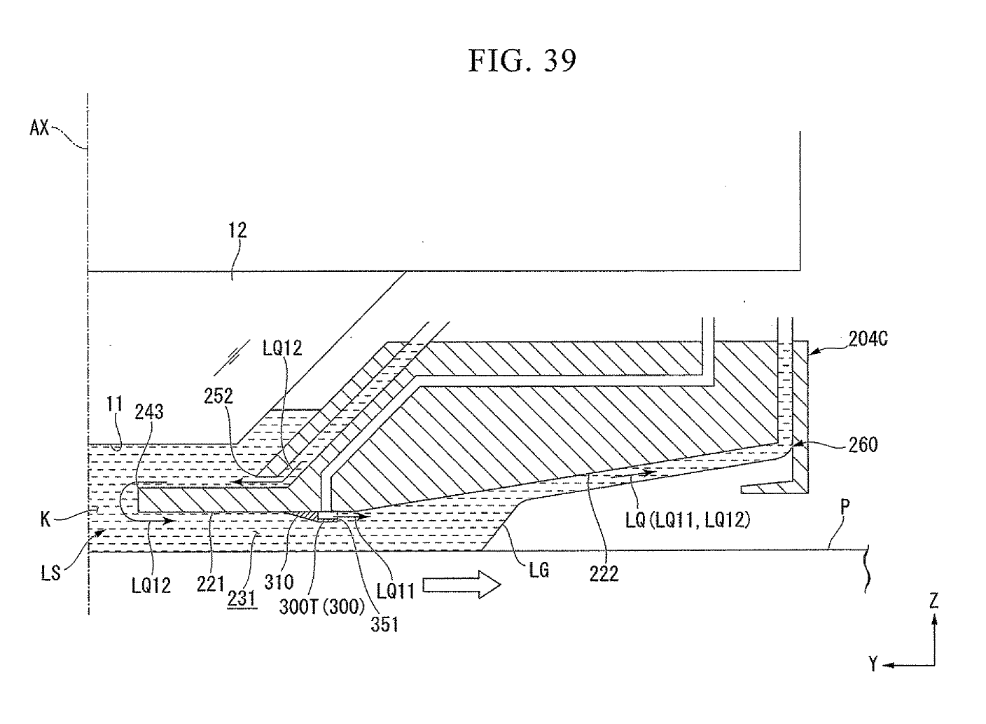

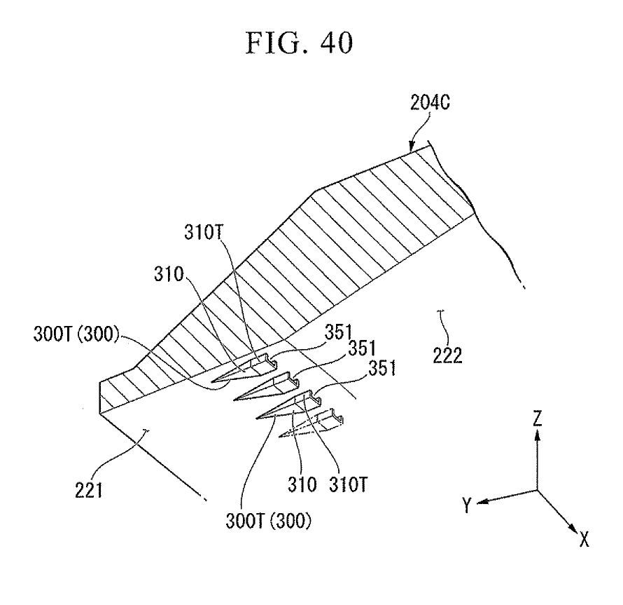

Furthermore, in the example shown in FIG. 37 and FIG. 38, the supply members 300 include the pipe members 300P; however, as shown in FIG. 39 and FIG. 40, for example, protruding members 3001, each of which protrudes from the first surface 221, may be included.

In FIG. 39 and FIG. 40, each of the protruding members 300T is disposed such that it faces toward the outer side in radial directions with respect to the optical axis AX and has one of the first supply ports 351 that supplies the first liquid LQ11 to the second surface 222. The protruding members 300T are disposed at prescribed intervals around the optical axis AX.

Each of the protruding members 300T has an outer surface 310 that is oriented in a different direction from that of the first surface 221 and follows along radial directions with respect to the optical axis AX. Each of the outer surfaces 310 includes a side surface 310T of the protruding member 300T, which intersects the first surface 221.

In FIG. 39 and FIG. 40, the side surface 310T of each of the protruding members 300T includes a first side surface, which faces the +X direction, and a second side surface, which faces the −X direction. In addition, the outer surface 310 of each of the protruding members 300T includes a lower surface that faces the −Z direction.

FIG. 39 is a side cross sectional view that shows part of a liquid immersion member 204C, and FIG. 40 shows part of the liquid immersion member 204C, viewed from below. Also in the example shown in FIG. 39 and FIG. 40, at least some of the second liquid LQ12 that is supplied via the second supply ports 252 and flows via the opening 243 into the space 231 flows in the space 231 toward the outer side in radial directions with respect to the optical axis AX while contacting the outer surfaces 310 of the protruding members 3001, which include the side surfaces 310T. The second liquid LQ12 that flows while contacting the outer surfaces 310 of the protruding members 300T at least partly envelops the first liquid LQ11 supplied via the first supply ports 351. The action of the first liquid LQ11 supplied via the first supply ports 351 upon the second liquid LQ12 adjusts the flow velocity distribution of the liquid LQ between the front surface of the substrate P on one side and the first surface 221 or the second surface 222, or both, on the other side.

Also in the example shown in FIG. 39 and FIG. 40, it is possible to prevent the liquid LQ from leaking out, remaining behind, and the like.

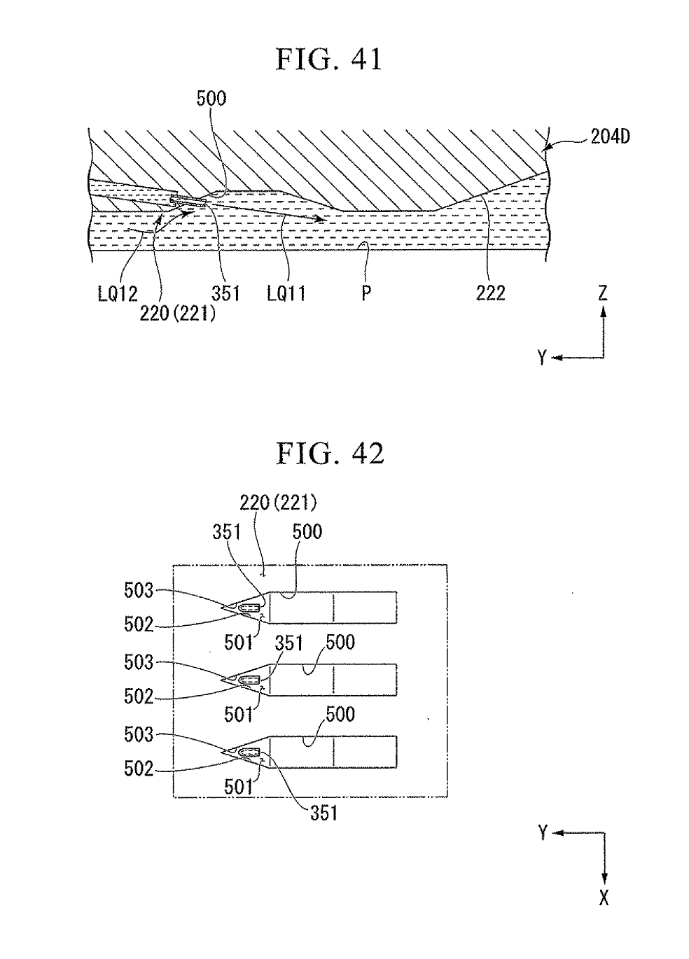

Furthermore, a liquid immersion member 204D shown in FIG. 41 and FIG. 42 also can prevent the liquid LQ from leaking out, remaining behind, and the like. FIG. 41 is a side cross sectional view that shows part of the liquid immersion member 204D, and FIG. 42 shows part of the liquid immersion member 204D, viewed from below. In FIG. 41 and FIG. 42, recessed parts 500 are formed in at least part of the lower surface 220 (i.e., the first surface 221) of the liquid immersion member 204D. Each of the recessed parts 500 has a lower surface 501, which faces substantially the same direction as that of the first surface 221, and first and second inner side surfaces 502, 503, each of which faces a different direction from that of the first surface 221. In the example shown in FIG. 41 and FIG. 42, each of the first inner side surfaces 502 faces substantially the −X direction, and each of the second inner side surfaces 503 faces substantially the +X direction. The first and second inner side surfaces 502, 503 are disposed along radial directions with respect to the optical axis AX.

The first supply ports 351 are disposed on the inner side of the recessed part 500. The first supply ports 351 supply the first liquid LQ11 toward the outer side in radial directions with respect to the optical axis AX. The first supply ports 351 supply the first liquid LQ11 to the second surface 222.

At least some of the second liquid LQ12 supplied via the second supply ports 252 flows to the inner sides of the recessed parts 500. At least some of the second liquid LQ12 flows toward the outer side in radial directions with respect to the optical axis AX while contacting the first and second inner side surfaces 502, 503. The first liquid LQ11 supplied via the first supply ports 351 acts upon the second liquid LQ12. The action of the first liquid LQ11 upon the second liquid LQ12 adjusts the flow velocity distribution of the liquid LQ in the space between the lower surface 220 of the liquid immersion member 204 and the front surface of the substrate P.

Furthermore, in the second embodiment, at least part of each of the supply members 300 (i.e., the recessed parts 500) may be disposed in the second surface 222.

Furthermore, in each of the embodiments discussed above, the immersion space LS is formed with the second liquid LQ12, but the immersion space LS may be formed with the first liquid LQ11 and the second liquid LQ12 by mixing some of the first liquid LQ11 into the second liquid LQ12. In each of the embodiments discussed above, the first liquid LQ11 and the second liquid LQ12 are the same liquid and therefore it does not matter whether the first liquid LQ11 is present in the optical path K of the exposure light EL.

Furthermore, each of the embodiments discussed above explained exemplary cases wherein the first liquid LQ11 and the second liquid LQ12 are the same liquid, but they may be different liquids. For example, a liquid that has prescribed physical properties suited to the exposure of the substrate P may be used as the second liquid LQ12, and a liquid that is more lyophilic than the second liquid LQ12 with respect to the second surface 222 may be used as the first liquid LQ11.

In addition, the quality (i.e., the cleanliness level, the degree of transparency, and the like) of the first liquid LQ11 may be lower than that of the second liquid LQ12. In such a case, it would be preferable to dispose the first supply port (251 and the like) and set the supply conditions of the first liquid LQ11 supplied via the first supply port (251 and the like) such that the first liquid LQ11 supplied via the first supply port (251 and the like) does not mix with the second liquid LQ12 along the optical path K of the exposure light EL.

Furthermore, in each of the embodiments discussed above, an adjustment is made such that the temperature of the first liquid LQ11 supplied via the first supply port (251 and the like) and the temperature of the second liquid LQ12 supplied via the second supply ports 252 are substantially the same, but they may be different. In addition, the temperature of the liquid immersion member 204 may be adjusted using the first liquid LQ11 that flows through the internal passageway 272.

Furthermore, in each of the embodiments discussed above, a gas supply port that supplies gas to the vicinity of the air-liquid interface LG of the second liquid LQ12 of the immersion space LS may be provided. For example, the gas may be supplied to the vicinity of the air-liquid interface LG via the gas supply port such that a gas seal is formed between the front surface of the substrate P and the second surface 222. The force of the gas supplied via the gas supply port prevents the immersion space LS from enlarging. Thereby, the force of the gas supplied via the gas supply port also prevents the second liquid LQ12 from leaking out, remaining behind, and the like.

Furthermore, in each of the embodiments discussed above, the optical path K on the emergent (i.e., the image plane) side of the last optical element 12 of the projection optical system PL is filled with the second liquid LQ12; however, it is possible to use a projection optical system wherein the optical path K on the incident (i.e., the object plane) side of the last optical element 12 is also filled with a liquid, as disclosed in, for example, PCT International Publication No. WO2004/019128. Furthermore, the liquid that fills the optical path K on the incident side of the last optical element 12 may be the same type of liquid as the second liquid LQ12 or it may be a different type.

Furthermore, in each of the embodiments discussed above, the first and second liquids LQ11, LQ12 are not limited to water (i.e., pure water); for example, it is also possible to use hydro-fluoro-ether (HFE), perfluorinated polyether (PFPE), Fomblin® oil, and the like.

Furthermore, the substrate P in each of the embodiments discussed above is not limited to a semiconductor wafer for fabricating semiconductor devices, but can also be adapted to, for example, a glass substrate for display devices, a ceramic wafer for thin film magnetic heads, or the original plate of a mask or a reticle (i.e., synthetic quartz or a silicon wafer) used by an exposure apparatus.

The exposure apparatus EX can also be adapted to a step-and-scan type scanning exposure apparatus (i.e., a scanning stepper) that scans and exposes the pattern of the mask M by synchronously moving the mask M and the substrate P, as well as to a step-and-repeat type projection exposure apparatus (i.e., a stepper) that successively steps the substrate P and performs a full-field exposure of the pattern of the mask M with the mask M and the substrate P in a stationary state.

Furthermore, when performing an exposure with a step-and-repeat system, the projection optical system PL is used to transfer a reduced image of a first pattern to the substrate P in a state wherein the first pattern and the substrate P are substantially stationary, after which the projection optical system PL may be used to perform a full-field exposure of the substrate P, wherein a reduced image of a second pattern partially superposes the transferred first pattern in a state wherein the second pattern and the substrate P are substantially stationary (i.e., as in a stitching type full-field exposure apparatus). In addition, the stitching type exposure apparatus can also be adapted to a step-and-stitch type exposure apparatus that successively steps the substrate P and transfers at least two patterns onto the substrate P such that they are partially superposed.

In addition, the exposure apparatus EX can also be, for example, an exposure apparatus that combines the patterns of two masks onto a substrate through a projection optical system and double exposes, substantially simultaneously, a single shot region on the substrate using a single scanning exposure, as disclosed in, for example, U.S. Pat. No. 6,611,316. In addition, the exposure apparatus EX can also be, for example, a proximity type exposure apparatus and a mirror projection aligner.

In addition, the exposure apparatus EX can also be a twin stage type exposure apparatus, which comprises a plurality of substrate stages, as disclosed in, for example, U.S. Pat. Nos. 6,341,007, 6,208,407, and 6,262,796. In this case, the liquid immersion space LS can be formed either on each of the substrate stages or such that it spans the plurality of the substrate stages.

Furthermore, as disclosed in, for example, U.S. Pat. No. 6,897,963 and U.S. Patent Application Publication No. 2007/0127006, the exposure apparatus EX can also be an exposure apparatus that is provided with: a substrate stage, which holds the substrate; and a measurement stage that does not hold the substrate to be exposed and whereon a fiducial member (wherein a fiducial mark is formed), a measuring member that measures the exposure light EL, or a measuring instrument (i.e., a photoelectric sensor) that measures the exposure light EL, or any combination thereof, is mounted. The liquid immersion member (4 and the like) in each of the embodiments discussed above is capable of forming the immersion space by holding the second liquid LQ12 between the liquid immersion member (4 and the like) and the measurement stage such that the optical path K of the exposure light EL is filled with the second liquid LQ12 during at least part of the radiation of the exposure light EL to the measurement stage.

In addition, the exposure apparatus EX can also be an exposure apparatus that comprises a plurality of the substrate stages and the measurement stages. In this case, the liquid immersion space LS can be formed either on the measurement stages or such that it spans the plurality of the substrate stages and the measurement stages.

The type of exposure apparatus EX is not limited to a semiconductor device fabrication exposure apparatus that exposes the substrate P with the pattern of a semiconductor device, but can also be widely adapted to exposure apparatuses used to fabricate, for example, liquid crystal devices or displays, and to exposure apparatuses used to fabricate thin film magnetic heads, image capturing devices (CCDs), micromachines, MEMS devices, DNA chips, or reticles and masks.

In addition, in each of the embodiments discussed above, an ArF excimer laser may be used as a light source apparatus that generates ArF excimer laser light, which serves as the exposure light EL; however, as disclosed in, for example, U.S. Pat. No. 7,023,610, a harmonic generation apparatus that outputs pulsed light with a wavelength of 193 nm and that comprises an optical amplifier part—which has a solid state laser light source (such as a DFB semiconductor laser or a fiber laser), a fiber amplifier, and the like—and a wavelength converting part may be used. Furthermore, in the abovementioned embodiments, both the illumination area IR and the projection area PR discussed above are rectangular, but they may be some other shape, for example, arcuate.

Furthermore, in each of the embodiments discussed above, an optically transmissive mask wherein a prescribed shielding pattern (or phase pattern or dimming pattern) is formed on an optically transmissive substrate is used; however, instead of such a mask, a variable shaped mask (also called an electronic mask, an active mask, or an image generator), wherein a transmissive pattern, a reflective pattern, or a light emitting pattern is formed based on electronic data of the pattern to be exposed, may be used as disclosed in, for example, U.S. Pat. No. 6,778,257. The variable shaped mask comprises, for example, a digital micromirror device (DMD), which is one kind of non-emissive type image display device (e.g., a spatial light modulator). In addition, instead of a variable shaped mask that comprises a non-emissive type image display device, a pattern forming apparatus that comprises a self-luminous type image display device may be provided. Examples of a self-luminous type image display device include a cathode ray tube (CRT), an inorganic electroluminescence display, an organic electroluminescence display (OLED: organic light emitting diode), an LED display, a laser diode (LD) display, a field emission display (FED), and a plasma display panel (PDP).

Each of the embodiments discussed above explained an exemplary case of an exposure apparatus that comprises the projection optical system PL, but it can be adapted to an exposure apparatus and an exposing method that do not use the projection optical system PL. Thus, even if the projection optical system PL is not used, the exposure light can be radiated to the substrate through optical members, such as lenses, and the immersion space can be formed in a prescribed space between the substrate and those optical members.

In addition, by forming interference fringes on the substrate P as disclosed in, for example, PCT International Publication No. WO2001/035168, the exposure apparatus Ex can also be an exposure apparatus (i.e., a lithographic system) that exposes the substrate F with a line-and-space pattern.

As described above, the exposure apparatus EX in the present embodiment is manufactured by assembling various subsystems, as well as each constituent element, such that prescribed mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus EX from the various subsystems includes, for example, the mechanical interconnection, the wiring and connection of electrical circuits, and the piping and connection of the pneumatic circuits among the various subsystems. Naturally, prior to performing the process of assembling the exposure apparatus EX from these various subsystems, there are also the processes of assembling each individual subsystem. When the process of assembling the exposure apparatus EX from the various subsystems is complete, a comprehensive adjustment is performed to ensure the various accuracies of the exposure apparatus EX as a whole. Furthermore, it is preferable to manufacture the exposure apparatus EX in a clean room, wherein the temperature, the cleanliness level, and the like are controlled.

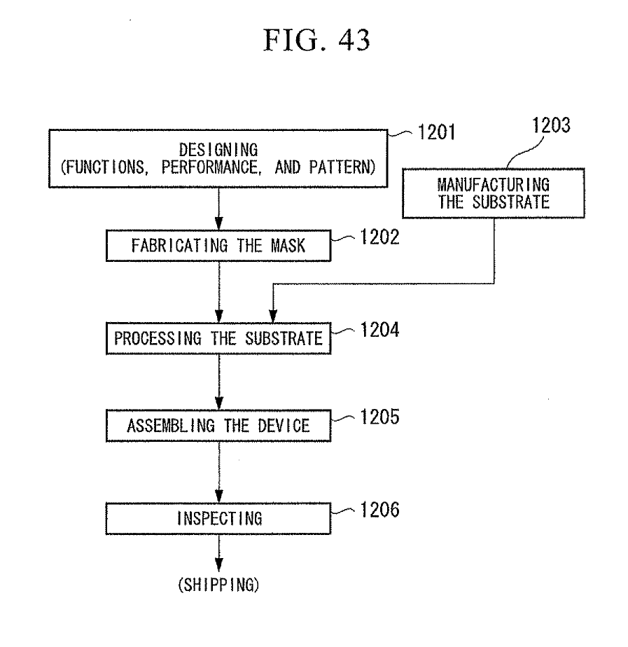

As shown in FIG. 43, a micro-device, such as a semiconductor device, is manufactured by: a step 1201 that designs the functions and performance of the micro-device; a step 1202 that fabricates the mask (i.e., a reticle) based on this designing step; a step 1203 that manufactures the substrate, which is the base material of the device; a substrate processing step 1204 that includes, in accordance with the embodiments discussed above, exposing the substrate with the exposure light using the pattern of the mask and developing the exposed substrate; a device assembling step 1205 (which includes fabrication processes, such as dicing, bonding, and packaging); an inspecting step 1206; and the like.

Furthermore, the features of each of the embodiments discussed above can be combined as appropriate. In addition, there may be cases wherein some of the constituent elements are not used. In addition, each disclosure of every Japanese published patent application and U.S. patent related to the exposure apparatus recited in each of the embodiments, modified examples, and the like discussed above is hereby incorporated by reference in its entirety to the extent permitted by national laws and regulations.

1. An exposure apparatus, comprising:
an optical system, which has an emergent surface wherefrom exposure light emerges;
a first surface, which is disposed at least partly around an optical path of the exposure light from the emergent surface;
a second surface, which is disposed at least partly around the first surface;
a third surface, which is disposed at least partly around the second surface;
a first supply port, which is disposed at least partly around the first surface such that the first supply port is directed in an outward radial direction with respect to an optical axis of the optical system, that supplies a first liquid to the second surface; and
a second supply port, which is disposed at least partly around the second surface such that the second supply port is directed in an outward radial direction with respect to the optical axis, that supplies a second liquid to the third surface;
wherein,
during at least part of an exposure of the substrate, a front surface of the substrate opposes the emergent surface, the first surface, the second surface, and the third surface; and
the substrate is exposed with the exposure light that emerges from the emergent surface and transits a third liquid between the emergent surface and the front surface of the substrate.

2. An exposure apparatus according to claim 1, wherein
a flow velocity of the first liquid supplied via the first supply port is lower than a flow velocity of the second liquid supplied via the second supply port.

3. An exposure apparatus, according to claim 1, wherein
the first liquid supplied via the first supply port is supplied at a first angle with respect to a surface that is perpendicular to the optical axis; and
the second liquid supplied via the second supply port is supplied at a second angle with respect to a surface that is perpendicular to the optical axis.

4. An exposure apparatus according to claim 3, wherein
the first angle is different from the second angle.

5. An exposure apparatus according to claim 4, wherein
the first supply port and the second supply port supply the first liquid and the second liquid, respectively, upward and in an outward radial direction with respect to the optical axis.

6. An exposure apparatus according to claim 5, wherein
the first angle is smaller than the second angle.

7. An exposure apparatus according to claim 4, wherein
the first liquid supplied via the first supply port is supplied parallel to the surface that is perpendicular to the optical axis; and
the second supply port supplies the second liquid upward and toward the outer side in a radial direction with respect to the optical axis.

8. An exposure apparatus according to claim 3, wherein
the first angle is equal to the second angle.

9. An exposure apparatus according to claim 1, wherein
the second supply port is more spaced apart from the optical axis than the first supply port is; and
at least part of the first supply port and at least part of the second supply port are disposed at the same position in a circumferential direction with respect to the optical axis.

10. An exposure apparatus according to claim 1, wherein
at least part of the first supply port and at least part of the second supply port supply the first liquid and the second liquid, respectively, along a first radial direction with respect to the optical axis.

11. An exposure apparatus according to claim 1, wherein
the second supply port is more spaced apart from the optical axis than the first supply port is; and
the position of the first supply port is different from the position of the second supply port in a circumferential direction with respect to the optical axis.

12. An exposure apparatus according to claim 1, wherein
the first supply port supplies the first liquid such that the first liquid flows over the second surface in the outward radial direction.

13. An exposure apparatus according to claim 1, wherein
the first supply port supplies the first liquid such that the first liquid contacts the second liquid that is supplied via the second supply port onto the second surface.

14. An exposure apparatus according to claim 1, wherein
the second supply port supplies the second liquid such that the second liquid flows on the third surface toward the outer side with respect to the radial direction.

15. An exposure apparatus according to claim 1, wherein
the first supply port supplies the first liquid in accordance with movement conditions of an object that opposes the emergent surface.

16. An exposure apparatus according to claim 15, comprising:
a first adjustment apparatus, which adjusts—in accordance with the movement conditions of the object—supply conditions of the first liquid supplied via the first supply port.

17. An exposure apparatus according to claim 15, wherein
the movement conditions include a movement velocity of the object; and the supply conditions of the first liquid include the flow velocity of the first liquid supplied via the first supply port.

18. An exposure apparatus according to claim 15, wherein
the second supply port supplies the second liquid in accordance with the supply conditions of the first liquid supplied via the first supply port.

19. An exposure apparatus according to claim 18, comprising:
a second adjusting apparatus that adjusts supply conditions of the second liquid supplied via the second supply port in accordance with the supply conditions of the first liquid.

20. An exposure apparatus according to claim 1, wherein
the second supply port is disposed above the first supply port.

21. An exposure apparatus according to claim 1, wherein
at least part of the second surface is disposed above the first surface.

22. An exposure apparatus according to claim 1, wherein at least part of the third surface is disposed above the second surface.

23. An exposure apparatus according to claim 1, wherein
at least part of the third surface is inclined in an upward and outward radial direction.

24. An exposure apparatus according to claim 1, wherein
at least part of the second surface is inclined in an upward and outward radial direction.

25. An exposure apparatus according to claim 1, wherein
at least part of the second surface is substantially horizontal.

26. An exposure apparatus according to claim 1, wherein
the first surface and the second surface are substantially parallel.

27. An exposure apparatus according to claim 1, wherein
the second surface and the third surface are substantially parallel.

28. An exposure apparatus according to claim 1, wherein
the third surface is lyophilic with respect to the second liquid.

29. An exposure apparatus according to claim 1, wherein
third supply ports supply the third liquid to the optical path.

30. An exposure apparatus according to claim 29, comprising:
a fourth surface that is disposed around the optical path such that the fourth surface faces a direction that is opposite that of the first surface and at least part of it opposes the emergent surface;
wherein
the third supply ports supply the third liquid to the space between the emergent surface and the fourth surface.

31. An exposure apparatus according to claim 1, wherein
the first liquid or the second liquid, or both, is the same type of liquid as the third liquid.

32. An exposure apparatus according to claim 1, wherein
the first supply port or the second supply port, or both, includes a slit opening, which is formed such that it surrounds the optical path.

33. An exposure apparatus according to claim 1, wherein
a plurality of the first supply ports or a plurality of the second supply ports, or both, is disposed at prescribed intervals around the optical path.

34. An exposure apparatus according to claim 1, comprising:
a recovery part, which is disposed on the outer side of the third surface in the radial direction with respect to the optical axis and recovers at least some of the liquid on the third surface.

35. An exposure apparatus according to claim 34, wherein
the recovery part comprises a recovery port, which is capable of recovering at least some of the liquid on the third surface, and a porous member, which is disposed in the recovery port.

36. An exposure apparatus according to claim 34, wherein
the recovery part has a fifth surface, which is disposed such that it intersects the third surface.

37. An exposure apparatus according to claim 36, wherein
a first gap is formed between an edge on the outer side of the third surface and the fifth surface; and
the recovery part recovers at least some of the liquid that flows in from the third surface to the first gap.

38. An exposure apparatus according to claim 36, wherein
at least part of the fifth surface is disposed below an edge on the outer side of the third surface such that the fifth surface faces the optical axis.

39. An exposure apparatus according to claim 34, wherein
the recovery part has a recessed part, which is disposed such that it faces upward below the circumferential edge area of the third surface.

40. An exposure apparatus according to claim 39, wherein
the recovery part recovers at least some of the liquid that flows into the recessed part.

41. A device fabricating method, comprising:
exposing a substrate using an exposure apparatus according to claim 1; and
developing the exposed substrate.

42. An exposing method, comprising:
causing a substrate to oppose a first surface, which is disposed at least partly around an optical path of exposure light from an emergent surface of an optical system, a second surface, which is disposed at least partly around the first surface, and a third surface, which is disposed at least partly around the second surface;
supplying, at least partly around the first surface, a first liquid via a first supply port, which is disposed such that it is directed in an outward radial direction with respect to the optical axis of the optical system, to the second surface;
supplying, at least partly around the second surface, a second liquid via a second supply port, which is disposed such that it is directed in an outward radial direction with respect to the optical axis, to the third surface;
forming an immersion space with a third liquid between at least part of the emergent surface, the first surface, the second surface, and the third surface and a front surface of the substrate such that the third liquid is supplied via third supply ports, which are different than the first supply port and the second supply port, and the optical path of the exposure light between the emergent surface and the substrate is filled with the third liquid; and
exposing the substrate with the exposure light that emerges from the emergent surface and transits the third liquid between the emergent surface and the substrate.

43. An exposing method according to claim 42, wherein
the first liquid supplied via the first supply port is supplied such that the first liquid contacts the second liquid supplied via the second supply port onto the second surface.

44. An exposing method according to claim 42, comprising:
setting a first velocity of the first liquid supplied via the first supply port such that the first velocity is slower than a second flow velocity of the second liquid supplied via the second supply port.

45. An exposing method according to claim 42, wherein
the first supply port supplies the first liquid substantially parallel to a surface that is perpendicular to the optical axis; and
the second supply port supplies the second liquid diagonally upward.

46. An exposing method according to claim 42, wherein
the first supply port supplies the first liquid diagonally upward at a first angle with respect to a surface that is perpendicular to the optical axis;
the second supply port supplies the second liquid diagonally upward at a second angle with respect to a surface that is perpendicular to the optical axis; and
the first angle is smaller than the second angle.

47. A device fabricating method, comprising:
exposing a substrate using an exposing method according to claim 42; and
developing the exposed substrate.

48. A liquid immersion member, comprising:
a first surface, which is disposed at least partly around an optical path of exposure light radiated to an object and is capable of opposing the object;
a second surface, which is disposed at least partly around the first surface;
a prescribed member that has a third surface and a fourth surface, which faces a direction opposite that faced by the third surface, and that is disposed such that the third surface opposes the second surface;
a first supply port, which is disposed at least partly around the first surface such that it is directed in an outward radial direction with respect to the optical path, that supplies a first liquid; and
a passageway that is provided such that it connects a first space, which is faced by the third surface, and a second space, which is faced by the fourth surface, and such that at least some of the first liquid supplied via the first supply port to the first space flows to the second space;
wherein,
during at least part of the radiation of the exposure light to the object, an immersion space is formed by holding a second liquid between the liquid immersion member and the object such that the optical path is filled with the second liquid.

49. A liquid immersion member according to claim 48, wherein
a plurality of the prescribed members are disposed such that the prescribed members are disposed at prescribed intervals at least partly around the first surface; and
the passageway is a first gap, which is disposed between any two of the prescribed members that are adjacent.

50. A liquid immersion member according to claim 49, wherein
the first gap has a longitudinal axis along a radial direction.

51. A liquid immersion member according to claim 48, wherein
the passageway is an opening, which is formed in the prescribed member such that it connects the third surface and the fourth surface.

52. A liquid immersion member according to claim 51, wherein
the opening has a longitudinal axis along a radial direction.

53. A liquid immersion member according to claim 48, wherein
the size of the prescribed member in the radial direction is smaller than the size of the second surface.

54. A liquid immersion member according to claim 53, wherein
the second surface includes a first area, which surrounds the optical axis, and a second area, which surrounds the first area; and
the third surface opposes the first area.

55. A liquid immersion member according to claim 54, wherein
the first area and the third surface are substantially parallel.

56. A liquid immersion member according to claim 54, wherein
at least part of the first supply port is disposed between an inner side edge of the second surface and an inner side edge of the third surface.

57. A liquid immersion member according to claim 48, comprising:
second supply ports, which supply the second liquid to the optical path; wherein,
at least some of the second liquid supplied via the second supply ports flows to the second space via a prescribed space, which is faced by the first surface.

58. A liquid immersion member according to claim 57, comprising:
a fifth surface, which faces a direction opposite that faced by the first surface and is disposed at least partly around the optical path such that at least part of the fifth surface opposes an emergent surface;
wherein,
the second supply ports supply the second liquid to a space between the emergent surface and the fifth surface.

59. A liquid immersion member according to claim 58, wherein
the supplying of the first liquid via the first supply port and the supplying of the second liquid via the second supply ports are performed in parallel.

60. A liquid immersion member according to claim 57, wherein
the immersion space is formed between a front surface of the object on one side and at least part of the first surface and the second surface on the other side by at least some of the second liquid supplied via the second supply ports; and
the passageway, the first space, and the second space are disposed in the immersion space.

61. A liquid immersion member according to claim 60, wherein
the first supply port supplies the first liquid in the state wherein the first supply port is disposed in the immersion space.

62. A liquid immersion member according to claim 60, wherein
a flow velocity of the first liquid, which flows from the passageway to the second space, is higher than a flow velocity of the second liquid, which flows from the prescribed space to the second space.

63. A liquid immersion member according to claim 62, wherein
the object moves in a prescribed direction within a plane that is substantially parallel to the first surface in the state wherein the immersion space is formed; and
the action of the first liquid, which flows from the passageway into the second space, upon the second liquid adjusts a flow velocity distribution of a liquid in the second space between the fourth surface and the front surface of the object.

64. A liquid immersion member according to claim 63, wherein
the action causes the flow velocity of the liquid at an outer side edge of the fourth surface of the second space to approach the flow velocity of the liquid at an outer side edge of the third surface of the first space.

65. A liquid immersion member according to claim 64, wherein
the flow velocity of the first liquid supplied via the first supply port substantially parallel to the prescribed direction is higher than a movement velocity of the object in the prescribed direction.

66. A liquid immersion member according to claim 57, wherein
the flow velocity of the first liquid supplied via the first supply port is higher than the flow velocity of the second liquid supplied via the second supply ports.

67. A liquid immersion member according to claim 48, wherein
the outer side edge of the first surface and the inner side edge of the fourth surface are connected.

68. A liquid immersion member according to claim 48, wherein
the first surface and the fourth surface are disposed within substantially the same plane.

69. A liquid immersion member according to claim 48, wherein
at least part of the fourth surface is disposed in a second direction, which is the reverse of a first direction in which the exposure light advances, more than the first surface is.

70. A liquid immersion member according to claim 48, wherein
the first supply port supplies the first liquid such that the first liquid flows on the second surface tin an outward radial direction.

71. A liquid immersion member according to claim 48, wherein
the first supply port is a slit opening, which is formed such that it surrounds the optical axis.

72. A liquid immersion member according to claim 48, wherein
a plurality of the first supply ports are disposed such that the first supply ports are disposed at prescribed intervals around the optical axis.

73. A liquid immersion member, comprising:
a first surface, which is disposed at least partly around an optical path of exposure light radiated to an object and is capable of opposing the object;
a second surface, which is disposed at least partly around the first surface;
a prescribed member, which is disposed in the first surface and has an outer surface at least part of which faces a different direction from that faced by the first surface and follows along a radial direction with respect to the optical path; and
a first supply port, which is disposed in the prescribed member such that the first supply port is directed in an outward radial direction, that supplies a first liquid to the second surface;
wherein,
during at least part of the radiation of the exposure light to the object, an immersion space is formed by holding a second liquid between the liquid immersion member and the object such that the optical path is filled with the second liquid.

74. A liquid immersion member according to claim 73, comprising:
second supply ports, which supply the second liquid to the optical path; wherein,
at least some of the second liquid supplied via the second supply ports flows in a prescribed space, which is faced by the first surface, and in an outward radial direction while contacting the outer surface.

75. A liquid immersion member according to claim 74, wherein
the supplying of the first liquid via the first supply port and the supplying of the second liquid via the second supply ports is performed in parallel.

76. A liquid immersion member according to claim 75, wherein
the immersion space is formed between at least part of the first surface and the second surface on one side and the front surface of the object on the other side by at least some of the second liquid supplied via the second supply ports; and
the first supply port supplies the first liquid in the state wherein the first supply port is disposed in the immersion space.

77. A liquid immersion member according to claim 76,
a flow velocity of the first liquid supplied via the first supply port is higher than a flow velocity of the second liquid that flows via the second supply ports to the prescribed space.

78. A liquid immersion member according to claim 76, wherein
the object moves in a prescribed direction within a plane substantially parallel to the first surface in the state wherein the immersion space is formed; and
the action of the first liquid supplied via the first supply port upon the second liquid adjusts a flow velocity distribution of a liquid in a space between at least part of the first surface and the second surface on one side and the front surface of the object on the other side.

79. A liquid immersion member according to claim 78, wherein
the first supply port is disposed at substantially the center between the first surface and the front surface of the object.

80. A liquid immersion member according to claim 78, wherein
the flow velocity of the first liquid supplied via the first supply port substantially parallel to the prescribed direction is higher than a movement velocity of the object in the prescribed direction.

81. A liquid immersion member according to claim 74, wherein
the flow velocity of the first liquid supplied via the first supply port is higher than the flow velocity of the second liquid supplied via the second supply ports.

82. A liquid immersion member according to claim 73, wherein
the prescribed member comprises a protruding member, which protrudes from the first surface; and
the outer surface includes a side surface of the protruding member intersecting the first surface.

83. A liquid immersion member according to claim 73, wherein
the prescribed member comprises a pipe member, at least part of which opposes the first surface across a second gap; and
the outer surface includes at least part of an outer circumferential surface of the pipe member.

84. A liquid immersion member according to claim 73, wherein
a plurality of the prescribed members is disposed such that the prescribed members are disposed at prescribed intervals around the optical axis.

85. A liquid immersion member according to claim 48, wherein
at least part of the second surface is disposed in the second direction, which is the reverse of the first direction in which the exposure light advances, more than the first surface is.

86. A liquid immersion member according to claim 48, wherein
at least part of the second surface is inclined in the second direction, which is the reverse of the first direction in which the exposure light advances, toward an outward radial direction.

87. A liquid immersion member according to claim 48, wherein
the second surface is lyophilic with respect to the first liquid.

88. A liquid immersion member according to claim 48, wherein
the first liquid and the second liquid are the same type of liquid.

89. A liquid immersion member according to claim 48, comprising:
a recovery part, which is disposed on the outer side of the second surface in the radial directions and recovers at least some of the liquid on the second surface.

90. A liquid immersion member according to claim 89, wherein
the recovery part has a recovery port, which is capable of recovering at least some of the liquid on the second surface, and comprises a porous member, which is disposed in the recovery port.

91. A liquid immersion member according to claim 89, wherein
the recovery part has a sixth surface, which is disposed such that it intersects the second surface.

92. A liquid immersion member according to claim 91, wherein
a third gap is formed between an edge on the outer side of the second surface and the sixth surface; and
the recovery part recovers at least some of the liquid that flows from the second surface into the third gap.

93. A liquid immersion member according to claim 91, wherein
at least part of the sixth surface is disposed in the first direction, in which the exposure light travels, more than the outer side edge of the second surface is, such that the sixth surface faces the optical axis.

94. An exposure apparatus, comprising:
an optical system, which has an emergent surface wherefrom exposure light emerges; and
a liquid immersion member according to claim 48 that, during at least part of an exposure of a substrate, forms an immersion space by holding a second liquid between the liquid immersion member and the substrate such that an optical path of the exposure light between the emergent surface and the substrate is filled with the second liquid.

95. A device fabricating method, comprising:
exposing a substrate using a liquid immersion member according to claim 48; and
developing the exposed substrate.

96. An exposing method, comprising:
supplying a first liquid via a first supply port, which is disposed at least partly around a first surface disposed at least partly around an optical path of exposure light from an emergent surface of an optical system such that the first supply port is directed in an outward radial direction with respect to an optical axis of the optical system, to a first space, which is faced by a third surface of a prescribed member opposing a second surface that is disposed at least partly around the first surface;
flowing at least some of the first liquid, which is supplied via the first supply port to the first space, to a second space via a passageway, which connects the first space and the second space, which is faced by a fourth surface of the prescribed member that faces a direction opposite that faced by the third surface;
causing the first surface, the second surface, and the fourth surface on one side and the substrate on the other side to oppose one another; and
exposing the substrate with the exposure light that emerges from the emergent surface and transits a second liquid between the emergent surface and a front surface of the substrate.

97. An exposing method, comprising:
causing a first surface, which is disposed at least partly around an optical path of exposure light from an emergent surface of an optical system, and a second surface, which is disposed at least partly around the first surface, to oppose one another; supplying a first liquid, which is supplied to the second surface via a first supply port disposed such that the first supply port is directed in an outward radial direction, to a prescribed member, which has an outer surface disposed such that at least part of the outer surface faces a direction different from that faced by the first surface and such that the outer surface follows along a radial direction with respect to an optical axis of the optical system; and
exposing the substrate with the exposure light that emerges from the emergent surface and transits a second liquid between the emergent surface and the substrate.

98. A device fabricating method, comprising:
exposing a substrate using an exposing method according to claim 96; and
developing the exposed substrate.
